(19) United States
(12) Patent Application Publication
(10) Pub. No.: US 2025/0268013 A1
(43) Pub. Date: Aug. 21, 2025

(54) Light-Emitting Device

(71) Applicant: Semiconductor Energy Laboratory Co., Ltd., Kanagawa-ken (JP)

(72) Inventors: Nobuharu OHSAWA, Zama (JP); Toshiki SASAKI, Kawasaki (JP); Hiromi SEO, Sagamihara (JP); Shinya FUKUZAKI, Atsugi (JP)

(73) Assignee: Semiconductor Energy Laboratory Co., Ltd., Kanagawa-ken (JP)

(21) Appl. No.: 19/051,731

(22) Filed: Feb. 12, 2025

(30) Foreign Application Priority Data
Feb. 16, 2024 (JP) 2024-022291

(51) Int. Cl. H10K 50/11; H10K 50/15; H10K 50/17; H10K 85/30; H10K 85/60

(52) U.S. Cl. CPC H10K 50/11; H10K 50/15; H10K 50/171; H10K 85/342; H10K 85/371; H10K 85/615; H10K 85/633; H10K 85/654; H10K 85/656; H10K 85/6572; H10K 85/6574; H10K 85/6576

(57) ABSTRACT

A light-emitting device includes a first electrode, a second electrode, and an organic compound layer over a first insulating layer. The organic compound layer is between the first electrode and the second electrode. The second electrode and the organic compound layer are separated from a second electrode and an organic compound layer of at least one of a plurality of light-emitting devices adjacent to the light-emitting device. An outline of the second electrode and an outline of the organic compound layer are substantially aligned with each other when seen from a direction substantially perpendicular to a surface of the first insulating layer on which the first electrode is formed. The organic compound layer includes a light-emitting layer and an electron-injection layer. The electron-injection layer includes metal or a metal compound, a first organic compound, and a second organic compound. The first organic compound includes a π-electron deficient heteroaromatic ring. The second organic compound includes two or more heteroaromatic rings. The two or more heteroaromatic rings are bonded or condensed to each other and include three or more heteroatoms in total. The second organic compound interacts with the metal or the metal compound by two or more of the three or more heteroatoms as a multidentate ligand.

### BACKGROUND OF THE INVENTION

### 1. Field of the Invention

One embodiment of the present invention relates to a light-emitting device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), driving methods thereof, and manufacturing methods thereof.

### 2. Description of the Related Art

Display devices are being developed into a variety of applications these days. For example, a television device for home use (also referred to as TV or television receiver), digital signage, and a public information display (PID) are being developed as large-sized display devices, and a smartphone and a tablet terminal each provided with a touch panel are being developed as small-sized display devices.

At the same time, an increase in the resolution of display devices is also required. For example, devices for virtual reality (VR), augmented reality (AR), substitutional reality (SR), or mixed reality (MR) are given as devices requiring high-resolution display devices and are being developed actively.

Development is actively conducted on light-emitting devices (also referred to as light-emitting elements) as display elements used in display devices. Light-emitting devices utilizing electroluminescence (hereinafter referred to as EL; such devices are also referred to as EL devices or EL elements), particularly organic EL devices that mainly use organic compounds, are suitable for display devices because of having features such as ease of reduction in thickness and weight, high-speed response to input signals, and driving with a constant DC voltage power source.

In order to obtain a higher-resolution light-emitting apparatus using an organic EL device, patterning an organic layer by a photolithography method using a photoresist or the like, instead of an evaporation method using a metal mask, has been studied. By using the photolithography method, a high-resolution display device in which the distance between organic compound layers is several micrometers can be obtained (see Patent Document 1, for example).

### REFERENCE

### Patent Document

[Patent Document 1] Japanese Translation of PCT International Application No. 2018-521459

### SUMMARY OF THE INVENTION

It has been known that a cathode and an organic compound layer in an organic EL device exposed to atmospheric components such as water and oxygen have affected initial characteristics and reliability, and thus it has been common knowledge that the cathode and the organic compound layer are treated in an inert gas atmosphere or a near-vacuum atmosphere. In particular, for an electron-injection layer, an alkali metal, an alkaline earth metal, or a compound thereof is used in many cases; however, these metals and compounds are highly reactive with water or oxygen, and rapidly deteriorate and lose the function as the electron-injection layer when the surface of the organic compound layer is exposed to the air.

However, processing steps by the aforementioned photolithography method inevitably exposes the surface of the organic EL device to the air.

An object of one embodiment of the present invention is to provide a novel light-emitting device. An object of another embodiment of the present invention is to provide a highly efficient light-emitting device. An object of another embodiment of the present invention is to provide a highly reliable light-emitting device. An object of another embodiment of the present invention is to provide a highly efficient light-emitting device.

An object of another embodiment of the present invention is to provide a novel light-emitting device manufactured through a photolithography process. An object of another embodiment of the present invention is to provide a highly efficient light-emitting device manufactured through a photolithography process. An object of another embodiment of the present invention is to provide a light-emitting device manufactured through a photolithography process. An object of another embodiment of the present invention is to provide a high-emission-efficiency light-emitting device manufactured through a photolithography process.

An object of another embodiment of the present invention is to provide a novel light-emitting device capable of being used in a high-resolution display device. An object of another embodiment of the present invention is to provide a highly efficient light-emitting device capable of being used in a high-resolution display device. An object of another embodiment of the present invention is to provide a light-emitting device capable of being used in a high-resolution display device. An object of another embodiment of the present invention is to provide a high-emission-efficiency light-emitting device capable of being used in a high-resolution display device.

An object of another embodiment of the present invention is to provide a highly reliable display device. An object of another embodiment of the present invention is to provide a high-resolution display device. An object of another embodiment of the present invention is to provide a high-resolution display device.

Note that the description of these objects does not preclude the presence of other objects. One embodiment of the present invention does not necessarily achieve all of these objects. Other objects can be derived from the description of the specification, the drawings, and the claims.

One embodiment of the present invention is a light-emitting device including a first electrode over a first insulating layer, a second electrode over the first insulating layer, and an organic compound layer over the first insulating layer. The first electrode is in contact with the first insulating layer. The organic compound layer is between the first electrode and the second electrode. The second electrode and the organic compound layer are separated from a second electrode and an organic compound layer of at least one of a plurality of light-emitting devices adjacent to the light-emitting device. An outline of the second electrode and an outline of the organic compound layer are substantially aligned with each other when seen from a direction substantially perpendicular to a surface of the first insulating layer on which the first electrode is formed. The organic compound layer includes a light-emitting layer and an electron-injection layer. The electron-injection layer includes metal or a metal compound, a first organic compound, and a second organic compound. The first organic compound includes a π-electron deficient heteroaromatic ring. The second organic compound includes two or more heteroaromatic rings. The two or more heteroaromatic rings are bonded or condensed to each other and include three or more heteroatoms in total. The second organic compound interacts with the metal or the metal compound by two or more of the three or more heteroatoms as a multidentate ligand.

In one embodiment of the above invention, the organic compound layer includes a p-type layer between the electron-injection layer and the second electrode, and the p-type layer includes a third organic compound having a hole-transport property and a metal oxide or a fourth organic compound including at least one of a halogen group and a cyano group.

In any of the light-emitting devices of the above embodiments of the invention, the second organic compound interacts with the metal or the metal compound by two or more of the three or more heteroatoms as a bidentate or a tridentate ligand.

One embodiment of the present invention is a light-emitting device in which the light-emitting device is one of a plurality of light-emitting devices included in a group of light-emitting devices. The group of light-emitting devices including a group of first electrodes over the same insulating surface; a group of second electrodes facing the group of first electrodes; and a group of first layers between the group of first electrodes and the group of second electrodes. The light-emitting device includes a first electrode, a second electrode, and a first layer. The first electrode is one of the group of first electrodes. The first electrode is independent of first electrodes of the plurality of light-emitting devices. The first layer is one of the group of first layers. The first layer is independent of first layers of the plurality of light-emitting devices. The second electrode is one of the group of second electrodes. The second electrode is independent of second electrodes of the plurality of light-emitting devices. The second electrode and the first layer overlap with the first electrode. The first layer includes a light-emitting layer and an electron-injection layer. The electron-injection layer includes metal or a metal compound, a first organic compound, and a second organic compound. The first organic compound includes a π-electron deficient heteroaromatic ring. The second organic compound includes two or more heteroaromatic rings. The two or more heteroaromatic rings are bonded or condensed to each other and include three or more heteroatoms in total. The second organic compound interacts with the metal or the metal compound by two or more of the three or more heteroatoms as a multidentate ligand. A distance between the first layer included in the light-emitting device and a first layer included in another light-emitting device adjacent to the light-emitting device is greater than or equal to 0.5 μm and less than or equal to 5 μm.

In one embodiment of the above invention, the first layer includes a p-type layer between the electron-injection layer and the second electrode, and the p-type layer includes a third organic compound having a hole-transport property and a metal oxide or a fourth organic compound including at least one of a halogen group and a cyano group.

In the light-emitting device of the above embodiments of the invention, the second organic compound interacts with the metal or the metal compound by two or more of the three or more heteroatoms as a bidentate or a tridentate ligand.

In any of the light-emitting devices of the above embodiments of the invention, an outline of the second electrode and an outline of the first layer are substantially aligned with each other when seen from a direction substantially perpendicular to the insulating surface.

In any of the light-emitting devices of the above embodiments of the invention, in a cross-sectional view, an end portion of the second electrode and an end portion of the first layer in a cross section are aligned with each other in a direction substantially perpendicular to the insulating surface.

One embodiment of the present invention is a light-emitting device including a first electrode over a first insulating layer, a second electrode over the first insulating layer, and an organic compound layer over the first insulating layer. The first electrode is in contact with the first insulating layer. The organic compound layer is between the first electrode and the second electrode. The second electrode and the organic compound layer are separated from a second electrode and an organic compound layer of at least one of a plurality of light-emitting devices adjacent to the light-emitting device. An outline of the second electrode and an outline of the organic compound layer are substantially aligned with each other when seen from a direction substantially perpendicular to a surface of the first insulating layer on which the first electrode is formed. The organic compound layer includes a light-emitting layer and an electron-injection layer. The electron-injection layer includes metal or a metal compound, a first organic compound, and a second organic compound. The first organic compound includes a π-electron deficient heteroaromatic ring. The second organic compound is represented by General Formula (G1-1).

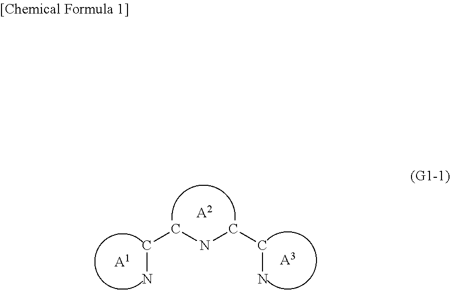

In General Formula (G1-1), A¹, A², and A³ independently represent a substituted or unsubstituted heteroaromatic ring having 1 to 30 carbon atoms, and A¹, A², and A³ may form a condensed ring with each other.

In one embodiment of the above invention, the organic compound layer includes a p-type layer between the electron-injection layer and the second electrode, and the p-type layer includes a third organic compound having a hole-transport property and a metal oxide or a fourth organic compound including at least one of a halogen group and a cyano group.

One embodiment of the present invention is a light-emitting device including a first electrode over a first insulating layer, a second electrode over the first insulating layer, and an organic compound layer over the first insulating layer. The first electrode is in contact with the first insulating layer. The organic compound layer is between the first electrode and the second electrode. The second electrode and the organic compound layer are separated from those of at least one of a plurality of light-emitting devices adjacent to the light-emitting device. An outline of the second electrode and an outline of the organic compound layer are substantially aligned with each other when seen from a direction substantially perpendicular to a surface of the first insulating layer on which the first electrode is formed. The organic compound layer includes a light-emitting layer and an electron-injection layer. The electron-injection layer includes metal or a metal compound, a first organic compound, and a second organic compound. The first organic compound includes a π-electron deficient heteroaromatic ring. The second organic compound is represented by General Formula (G1-2).

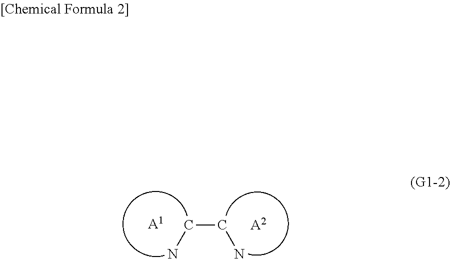

In General Formula (G1-2), A¹ and A² independently represent a substituted or unsubstituted heteroaromatic ring having 1 to 30 carbon atoms, A¹ and A² may form a condensed ring with each other, and A¹ includes two or more nitrogen atoms.

In one embodiment of the above invention, the organic compound layer includes a p-type layer between the electron-injection layer and the second electrode, and the p-type layer includes a third organic compound having a hole-transport property and a metal oxide or a fourth organic compound including at least one of a halogen group and a cyano group.

In the light-emitting device of any of the above embodiments of the invention, the heteroaromatic ring is a π-electron deficient heteroaromatic ring.

In the light-emitting device of any of the above embodiments of the invention, the heteroaromatic ring includes at least one of a pyridine ring, a diazine ring (a pyrazine ring, a pyrimidine ring, or a pyridazine ring), a triazine ring, an azole ring (an imidazole ring, a pyrazole ring, an oxazole ring, or a thiazole ring), and a triazole ring.

In the light-emitting device of any of the above embodiments of the invention, at least one of the heteroaromatic rings included in the second organic compound includes a diazine ring (a pyrazine ring, a pyrimidine ring, or a pyridazine ring) or a triazine ring. Alternatively, in the light-emitting device of any of the above embodiments of the invention, the heteroaromatic rings included in the second organic compound include three or more pyridine rings in total.

In the light-emitting device of any of the above embodiments of the invention, the first organic compound includes an electron-donating group. The electron-donating group includes at least one of an alkyl group, an alkoxy group, an aryloxy group, an alkylamino group, an arylamino group, and a heterocyclic amino group.

In the light-emitting device of any of the above embodiments of the invention, the first organic compound has an acid dissociation constant pKₐ of 8 or more. The first organic compound includes a phenanthroline ring.

In the light-emitting device of any of the above embodiments of the invention, the second organic compound has a glass transition temperature T_{g} of 100° C. or higher. The lowest unoccupied molecular orbital (LUMO) level of the second organic compound is lower than the LUMO level of the first organic compound.

In the light-emitting device of any of the above embodiments of the invention, the metal belongs to Group 1, 3, 11, or 13 of the periodic table.

In the light-emitting device of any of the above embodiments of the invention, the electron-injection layer is a mixture of the metal, the second organic compound, and the first organic compound. The electron-injection layer has a stacked-layer structure of a layer containing the metal and a layer containing the second organic compound or the first organic compound.

Another embodiment of the present invention is a light-emitting apparatus including a plurality of light-emitting devices, each of which is any of the light-emitting devices described above. Each of the plurality of light-emitting devices includes an organic compound layer including a light-emitting layer and an electron-injection layer between the first electrode and the second electrode. The second electrode and the organic compound layer included in each of the plurality of light-emitting devices are independent between the plurality of light-emitting devices.

Another embodiment of the present invention is a display module including any of the above-described light-emitting devices and at least one of a connector and an integrated circuit.

Another embodiment of the present invention is an electronic device including any of the above-described light-emitting devices and at least one of a housing, a battery, a camera, a speaker, and a microphone.

With one embodiment of the present invention, a novel light-emitting device can be provided. With another embodiment of the present invention, a highly efficient light-emitting device can be provided. With another embodiment of the present invention, a highly reliable light-emitting device can be provided. With another embodiment of the present invention, a highly efficient and highly reliable light-emitting device can be provided.

With another embodiment of the present invention, a novel light-emitting device manufactured through a photolithography process can be provided. With another embodiment of the present invention, a highly efficient light-emitting device manufactured through a photolithography process can be provided. With another embodiment of the present invention, a highly reliable light-emitting device manufactured through a photolithography process can be provided. With another embodiment of the present invention, a high-emission-efficiency and highly reliable light-emitting device manufactured through a photolithography process can be provided.

With another embodiment of the present invention, a novel light-emitting device capable of being used in a high-resolution display device can be provided. With another embodiment of the present invention, a highly efficient light-emitting device capable of being used in a high-resolution display device can be provided. With another embodiment of the present invention, a highly reliable light-emitting device capable of being used in a high-resolution display device can be provided. With another embodiment of the present invention, a high-emission-efficiency and highly reliable light-emitting device capable of being used in a high-resolution display device can be provided.

With another embodiment of the present invention, a highly reliable display device can be provided. With another embodiment of the present invention, a high-resolution display device can be provided. With another embodiment of the present invention, a highly reliable and high-resolution display device can be provided.

With another embodiment of the present invention, a novel organic compound, a novel light-emitting device, a novel display device, a novel display module, and a novel electronic device can be provided.

Note that the description of these effects does not preclude the presence of other effects. One embodiment of the present invention does not necessarily have all of these effects. Other effects can be derived from the description of the specification, the drawings, and the claims.

### BRIEF DESCRIPTION OF THE DRAWINGS

FIGS. 1A to 1C illustrate light-emitting devices.

FIG. 2 shows an analysis result of spin density distribution of a composite material in a ground state.

FIG. 3 shows a result of analyzing an electrostatic potential map of a composite material in a ground state.

FIGS. 4A and 4B illustrate light-emitting devices.

FIGS. 5A and 5B are a top view and a cross-sectional view of a light-emitting apparatus.

FIGS. 6A to 6E are cross-sectional views illustrating an example of a method for manufacturing a display device.

FIGS. 7A and 7B are cross-sectional views illustrating the example of a method for manufacturing a display device.

FIGS. 8A to 8D are cross-sectional views illustrating the example of a method for manufacturing a display device.

FIGS. 9A to 9C are cross-sectional views illustrating the example of a method for manufacturing a display device.

FIGS. 10A to 10C are cross-sectional views illustrating the example of a method for manufacturing a display device.

FIGS. 11A and 11B are cross-sectional views illustrating the example of a method for manufacturing a display device.

FIGS. 12A and 12B are perspective views illustrating a structure example of a display module.

FIGS. 13A and 13B are cross-sectional views each illustrating a structure example of a display device.

FIG. 14 is a perspective view illustrating a structure example of a display device.

FIG. 15 is a cross-sectional view illustrating a structure example of a display device.

FIG. 16 is a cross-sectional view illustrating a structure example of a display device.

FIG. 17A is a cross-sectional view illustrating a structure example of a display device, and FIGS. 17B and 17C are top views each illustrating a structure example of the display device.

FIG. 18 is a cross-sectional view illustrating a structure example of a display device.

FIG. 19A is a cross-sectional view illustrating a structure example of a display device, and FIGS. 19B and 19C are top views each illustrating a structure example of the display device.

FIGS. 20A to 20D illustrate examples of electronic devices.

FIGS. 21A to 21F illustrate examples of electronic devices.

FIGS. 22A to 22G illustrate examples of electronic devices.

FIGS. 23A to 23G illustrate pixel layout examples.

FIG. 24 illustrates a structure of a light-emitting device.

FIG. 25 shows luminance-current density characteristics of light-emitting devices.

FIG. 26 shows luminance-voltage characteristics of the light-emitting devices.

FIG. 27 shows current efficiency-current density characteristics of the light-emitting devices.

FIG. 28 shows current density-voltage characteristics of the light-emitting devices.

FIG. 29 shows electroluminescence spectra of the light-emitting devices.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

In this specification and the like, a device formed using a metal mask or a fine metal mask (FMM, a high-resolution metal mask) is sometimes referred to as a device having a metal mask (MM) structure. In this specification and the like, a device formed without using a metal mask or an FMM is sometimes referred to as a device having a metal maskless (MML) structure.

### Embodiment 1

As a method for forming an organic semiconductor film in a predetermined shape, a vacuum evaporation method with a metal mask (mask vapor deposition) is widely used. However, in these days of higher density and higher resolution, mask vapor deposition has come close to the limit of increasing the resolution for various reasons such as the alignment accuracy and the distance between the mask and the substrate. An organic semiconductor device having a finer pattern is expected to be achieved by shape processing of an organic semiconductor film by a photolithography method. Moreover, since a photolithography method achieves large-area processing more easily than mask vapor deposition, processing of an organic semiconductor film by the photolithography method is being researched.

It has been known that organic compound layers and a cathode in an organic EL device exposed to atmospheric components such as water and oxygen have affected initial characteristics or reliability, and thus it has been common knowledge that the organic compound layers and the cathode are treated in an inert gas atmosphere or a near-vacuum atmosphere.

In particular, an electron-injection layer in a light-emitting device, which sometimes includes an alkali metal, an alkaline earth metal, or a compound thereof (hereinafter also referred to as a Li compound or the like) is highly reactive with water or oxygen and rapidly deteriorates just by being exposed to the air. This significantly decreases the electron-injection property thereof. In addition, also in the case where another metal or the like having a low work function is used in the cathode, the electron-injection property of the electron-injection layer might be decreased and the driving voltage of the light-emitting device might be significantly increased when the electron-injection layer is exposed to water, oxygen, or the like.

However, processing steps with the aforementioned photolithography method inevitably expose the light-emitting device that is being manufactured to the air. Furthermore, a photolithography process uses a variety of chemical solutions and includes a cleaning step, which is a strict condition where deterioration is further promoted.

The processing with the photolithography method performed for the cathode and the organic compound layer therefore causes a significant degradation of the electron-injection properties of the cathode and the electron-injection layer. Thus, an organic EL device being processed by a photolithography method has significantly increased driving voltage and is hard to obtain favorable characteristics.

In order to avoid the degradation of the characteristics, there is a method in which processing by a photolithography method is performed before the formation of the electron-injection layer and the cathode. However, when processing is performed after both electrodes are formed, an increase in the number of steps in the photolithography process can be minimized, in which case the cost advantage is large. Furthermore, the possibility of exposure of the organic compound layer to the chemical solution and the air can be significantly reduced, so that performance similar to that of the light-emitting device manufactured without exposure to the air can be achieved.

In view of the above, one embodiment of the present invention provides a light-emitting device having favorable characteristics that includes a first electrode, an organic compound layer, and a second electrode from the substrate side and is manufactured by performing a photolithography process after the formation of the second electrode.

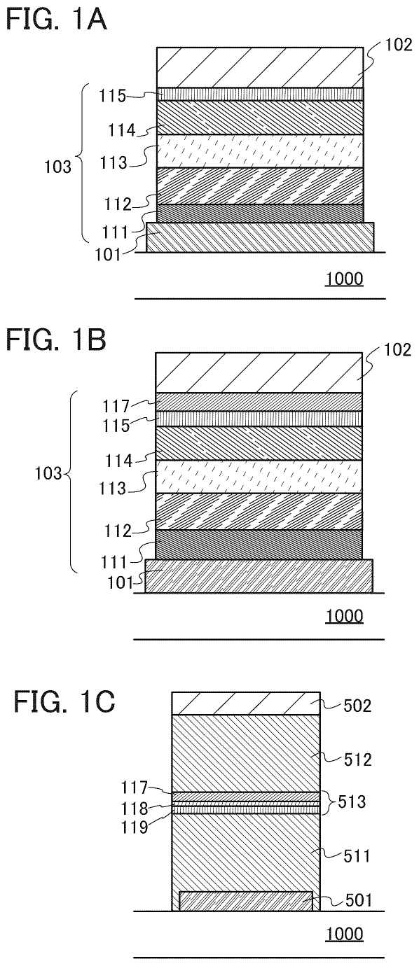

Specifically, FIG. 1A is a schematic diagram of a light-emitting device of one embodiment of the present invention. The light-emitting device includes a first electrode 101 over an insulator 1000, and an organic compound layer (also referred to as EL layer) 103 between the first electrode 101 and a second electrode 102. The organic compound layer 103 includes at least a light-emitting layer 113 and an electron-injection layer 115. The light-emitting layer 113 contains a light-emitting substance and emits light when voltage is applied between the first electrode 101 and the second electrode 102.

The organic compound layer 103 preferably includes, besides the light-emitting layer 113 and the electron-injection layer 115, functional layers such as a hole-injection layer 111, a hole-transport layer 112, and an electron-transport layer 114, as illustrated in FIG. 1A. The organic compound layer 103 may include functional layers other than the above functional layers, such as a hole-blocking layer, an exciton-blocking layer, and an intermediate layer. Alternatively, any of the above-described layers may be omitted.

As described above, if high reactivity of an alkali metal compound or the like used for an electron-injection layer is a factor of deterioration due to high reaction in an exposure step, an etching step, a washing step, or the like, the use of a substance with low reactivity instead of the alkali metal compound or the like may probably inhibit an increase in driving voltage even through processing by a photolithography method.

Among metal compounds, many of metal oxides (excluding an oxide of an alkali metal) are more stable than an alkali metal compound or the like and thus can be easily treated. In addition, the stable metal oxides relatively hardly deteriorate even when exposed to the air. However, even when the metal oxide is used instead of the alkali metal compound or the like in an electron-injection layer of a conventional light-emitting device, characteristics comparable to those offered by the alkali metal compound or the like are hard to obtain because of the stability of the metal oxide. Accordingly, an organic EL device with practical characteristics cannot be obtained.

In view of the above, the electron-injection layer 115 of one embodiment of the present invention includes a metal or metal compound, a first organic compound having a π-electron deficient heteroaromatic ring, and a second organic compound having two or more heteroaromatic rings that are bonded or condensed to each other and include three or more heteroatoms in total. Accordingly, an organic EL device with favorable characteristics can be provided even through a photolithography process involving exposure of the organic compound layer to the air.

With this structure, the first organic compound functions as an electron donor (donating electrons) to the second organic compound, and the first organic compound, the metal, and the second organic compound interact with each other to form a donor level (a singly occupied molecular orbital (SOMO) level or a highest occupied molecular orbital (HOMO) level). When the first organic compound, the metal, and the second organic compound interact with each other, the donor level (SOMO level or HOMO level) becomes high and a barrier against electron injection from the electron-injection layer to the electron-transport layer can be lowered. The interaction enables electrons to be injected and transported smoothly from the electron-injection layer 115 to the electron-transport layer 114. Accordingly, a light-emitting device with a low driving voltage can be manufactured.

Note that the LUMO level and the HOMO level of an organic compound are generally estimated by cyclic voltammetry (CV), photoelectron spectroscopy, optical absorption spectroscopy, inverse photoelectron spectroscopy, or the like. When values of different compounds are compared with each other, it is preferable that values estimated by the same measurement be used.

The SOMO level is an orbital derived from an unpaired electron of a metal, and when the metal, the first organic compound, and the second organic compound interact with each other, the SOMO level can also be distributed on the orbitals of the first organic compound and the second organic compound. In other words, the electron orbital of the metal and the electron orbitals of the organic compounds interact with each other.

Note that an organic compound containing a large number of atoms that enable an interaction can interact more stably with a metal. Thus, the second organic compound used in one embodiment of the present invention is preferably a material that interacts with a metal as a multidentate ligand of a bi-, tri- or higher dentate ligand. An organic compound interacting with a metal as a multidentate ligand is stabilized when interacting with the metal; thus, an electron-injection layer having resistance to oxygen and water in the air and water and a chemical solution used in the process by a photolithography method can be formed.

Examples of the atom that enables an interaction include a heteroatom having an unshared electron pair in an organic compound. For example, oxygen (O), nitrogen (N), sulfur(S), and phosphorus (P) are given, and nitrogen is preferable. Nitrogen has high electronegativity and thus easily interacts with a metal. Here, since nitrogen can form a conjugated bond in an organic compound, nitrogen enables the organic compound to have a high carrier-transport property when used in the molecule, particularly in a heteroaromatic ring. It is further preferable that the heteroaromatic ring be an even-numbered ring such as a six-membered ring or an eight-membered ring. Since the unshared electron pair of nitrogen does not contribute to the conjugation in this structure, nitrogen is likely to interact with a metal.

By the interaction between a metal or a metal compound, the first organic compound, and the second organic compound, a donor level (SOMO level or HOMO level) can be formed, a barrier against electron injection to the electron-transport layer can be lowered, and electrons can be injected and transported smoothly from the electron-injection layer to the electron-transport layer. The heteroaromatic ring included in the second organic compound is preferably a T-electron deficient heteroaromatic ring. With this structure, the second organic compound can have an electron-transport property, and electrons can be injected and transported smoothly from the electron-injection layer to the electron-transport layer. When the second organic compound includes two or more heteroaromatic rings that are bonded or condensed to each other and include three or more nitrogen atoms in total, the LUMO level of the second organic compound can be lower than that of the first organic compound. When a material whose LUMO level is lower than that of the first organic compound is used for the second organic compound, interaction between the metal or the metal compound, the first organic compound, and the second organic compound brings about stabilization.

The second organic compound preferably includes a π-electron deficient heteroaromatic ring having an unshared electron pair. This structure enables a stable interaction with the metal or the metal compound. The second organic compound is preferably a material that includes two or more π-electron deficient heteroaromatic rings each having an unshared electron pair and interacts with a metal as a multidentate ligand such as a bi- or higher dentate ligand. An organic compound that interacts with a metal as a multidentate ligand such as a bi- or higher dentate ligand is stabilized when interacting with the metal.

The first organic compound preferably includes an electron-donating substituent. With this structure, the first organic compound can have a high HOMO level and a high LUMO level; thus, the difference between the LUMO level of the first organic compound and the LUMO level of the second organic compound can be increased. Thus, further stabilization is achieved when the metal or the metal compound, the first organic compound, and the second organic compound interact with each other.

As described above, the first organic compound and the second organic compound can be stabilized when interacting with each other; thus, electrons can be injected and transported smoothly from the electron-injection layer to the adjacent electron-transport layer even through a photolithography process involving exposure of the EL layer to the air. Accordingly, the light-emitting device with a suppressed increase in driving voltage, high emission efficiency, and high reliability can be manufactured by a photolithography process.

Since a metal with a low work function typified by an alkali metal and an alkaline earth metal and a compound of such a metal have high reactivity with oxygen or water, using the metal or the compound for a light-emitting device manufactured through processing by a lithography method may cause a reduction in emission efficiency, an increase in driving voltage, a reduction in driving lifetime, generation of shrinkage (a non-emission region at an end portion of a light-emitting portion), or the like, leading to deterioration in the characteristics or a reduction in the reliability of the light-emitting device.

Meanwhile, in one embodiment of the present invention, even when an alkali metal, an alkaline earth metal, or a compound thereof is used, the alkali metal, the alkaline earth metal, or the compound thereof interacts with the first organic compound having a π-electron deficient heteroaromatic ring and the second organic compound having two or more heteroaromatic rings that are bonded or condensed to each other and include three or more heteroatoms in total, resulting in stabilization; thus, an electron-injection layer having resistance to oxygen and water in the air and water and a chemical solution used in a lithography process can be formed.

When an alkali metal, an alkaline earth metal, or a compound thereof is used as the metal in one embodiment of the present invention, the donor level (SOMO level or HOMO level) that is formed by interaction between the metal, the first organic compound having a π-electron deficient heteroaromatic ring, and the second organic compound having two or more heteroaromatic rings that are bonded or condensed to each other and include three or more heteroatoms in total can be a high energy level. This structure is preferable because it lowers a barrier against electron injection from the electron-injection layer to the electron-transport layer and enables electrons to be injected and transported smoothly from the electron-injection layer to the electron-transport layer.

Furthermore, since transition metals (metal elements belonging to Group 3 to Group 11) and metal elements belonging to Group 12 to Group 14 of the typical metal elements have low reactivity with oxygen and water in the air and water and a chemical solution used in a lithography process, the use of such a metal in a light-emitting device hardly causes deterioration due to water and oxygen, which might occur when a metal having a low work function is used. By contrast, such metals are stable and have a low electron-injection property, which may cause a reduction in emission efficiency, an increase in driving voltage, a reduction in driving lifetime, and the like of the light-emitting device.

In the electron-injection layer of one embodiment of the present invention, even when any of transition metals (metal elements belonging to Group 3 to Group 11) and metal elements belonging to Group 12 to Group 14 of the typical metals is used, the first organic compound having a π-electron deficient heteroaromatic ring interacts with the second organic compound having two or more heteroaromatic rings that are bonded or condensed to each other and include three or more heteroatoms in total, so that a donor level (SOMO level or HOMO level) is formed. That is, this structure lowers a barrier against electron injection from the electron-injection layer to the electron-transport layer and enables electrons to be injected and transported smoothly from the electron-injection layer to the electron-transport layer. In addition, the structure is resistant to oxygen and water in the air and water and a chemical solution used in a lithography process; as a result, one embodiment of the present invention can provide a light-emitting device that has high moisture resistance, high water resistance, high oxygen resistance, high chemical resistance, a low driving voltage, and high emission efficiency.

### <Quantum Chemical Calculation Analysis of Interaction Between Metal and Organic Compound>

Here, quantum chemical calculation analysis is performed on the case where the metal, the first organic compound having an electron-donating property and an unshared electron pair, and the second organic compound having an electron-transport property interact with each other.

### [Estimation of Interaction Between Metal and Organic Compound]

Here, quantum chemical calculation analysis is performed on the spin density and electrostatic potential (ESP) obtained at the time when the metal, the first organic compound having a π-electron deficient heteroaromatic ring, and the second organic compound having two or more heteroaromatic rings that are bonded or condensed to each other and include three or more heteroatoms in total interact with each other. Note that in the calculation, 4,7-di-1-pyrrolidinyl-1,10-phenanthroline (abbreviation: Pyrrd-Phen) is used as the first organic compound, 2,2′-(2,2′-bipyridine-6,6′-diyl)bis(4-phenylbenzo[h]quinazoline (abbreviation: 6,6′(P-Bqn)₂BPy) is used as the second organic compound, and lithium (Li) is used as the metal.

As the quantum chemistry computational program, Gaussian 09 is used. The calculation is performed using SGI 8600 (manufactured by Hewlett Packard Enterprise (HPE)). The most stable structures of the first organic compound alone in a ground state, the second organic compound alone in a ground state, and a composite material in a ground state of the first organic compound, the second organic compound, and the metal are calculated by the density functional theory (DFT). As a basis function, 6-311G (d,p) is used, and as a functional, B3LYP is used. In the DFT, the total energy is represented as the sum of potential energy, electrostatic energy between electrons, electronic kinetic energy, and exchange-correlation energy including all the complicated interactions between electrons. Also in the DFT, exchange-correlation interaction is approximated by a functional (a function of another function) of one electron potential represented in terms of electron density to enable highly accurate calculations.

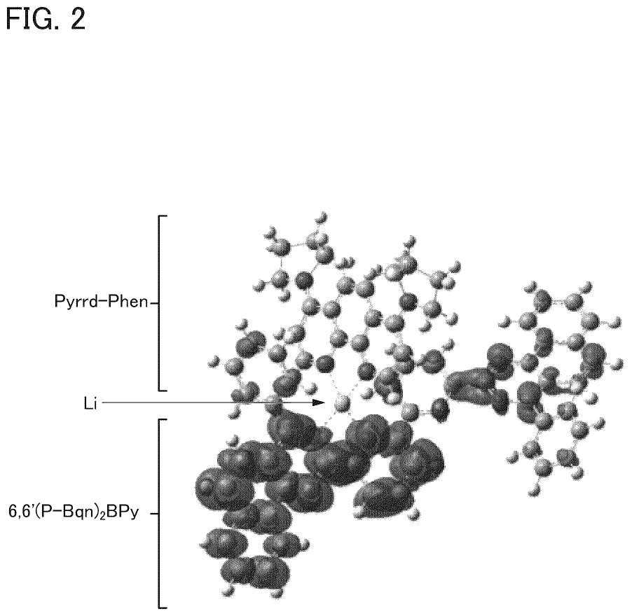

FIG. 2 shows an analysis result of the spin density distribution of the composite material in the ground state of the first organic compound (Pyrrd-Phen), the second organic compound (6,6′(P-Bqn)₂BPy), and the metal (Li). In the diagrams, spheres represent atoms included in the compounds, and clouds around some of the atoms represent spin density distribution at the time when the density value in atomic units is 0.0004 e/a₀³ (where e represents elementary charge (1 e=1.60218×10⁻¹⁹ C) and a₀ represents a Bohr radius (1 a₀=5.29177×10⁻¹¹ m)). The clouds represent localization of the doublet ground state of the compounds. Note that no spin density distribution is observed in the first organic compound (Pyrrd-Phen) in a ground state and the second organic compound (6,6′(P-Bqn)₂BPy) in a ground state because the ground states of the first organic compound and the second organic compound are singlet ground states.

Meanwhile, in the composite material of the first organic compound (Pyrrd-Phen), the second organic compound (6,6′(P-Bqn)₂BPy), and the metal (Li), which is one embodiment of the present invention, in the doublet ground state, the first organic compound (Pyrrd-Phen), the second organic compound (6,6′(P-Bqn)₂BPy), and the metal (Li) interact with one another, and the metal (Li) is coordinated to nitrogen atoms (N atoms at 1- and 10-positions) having unshared electron pairs in the 1,10-phenanthroline ring of the first organic compound (Pyrrd-Phen) and nitrogen atoms having unshared electron pairs in the pyridine ring and benzo[h]quinazoline ring of the second organic compound (6,6′(P-Bqn)₂BPy), which leads to stabilization of the formed composite material. Thus, as shown in FIG. 2, spins derived from unpaired electrons included in the metal (Li) are localized in the second organic compound (6,6′(P-Bqn)₂BPy). Furthermore, a spin density distribution is not observed in the metal (Li). This indicates that the second organic compound (6,6′(P-Bqn)₂BPy) is in a radical anion state owing to the interaction between the first organic compound (Pyrrd-Phen), the second organic compound (6,6′(P-Bqn)₂BPy), and the metal (Li).

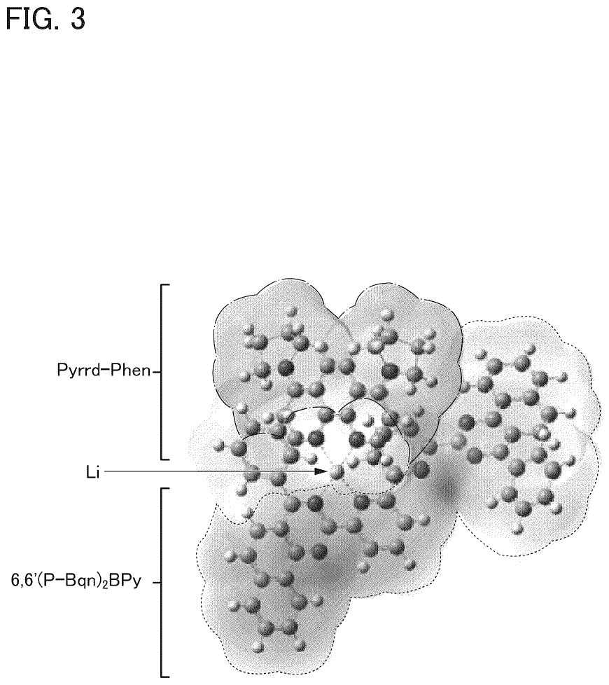

Next, FIG. 3 shows an analysis result of the electrostatic potential map of the composite material in the ground state of the first organic compound (Pyrrd-Phen), the second organic compound (6,6′(P-Bqn)₂BPy), and the metal (Li). In the diagram, spheres represent atoms included in the compounds, and clouds around some of the atoms represent electrostatic potentials in electron density distribution at the time when the density value in atomic units is 0.0004 e/a₀³. An electrostatic potential is the energy of interaction between positive point charge with unit quantity of electricity and electron distribution of a molecule. An electrostatic potential map denotes an electrostatic potential on an electron density isosurface in colors; in the map, a region with a negative electrostatic potential is denoted in red, a region with a positive electrostatic potential is denoted in blue, an atom in the region with a negative electrostatic potential has negative charge, and an atom in the region with a positive electrostatic potential has positive charge. FIG. 3 is a grayscale diagram converted from a colored image, and the region with a negative electrostatic potential corresponds to a region surrounded by a dotted line, and the region with a positive electrostatic potential corresponds to a region surrounded by a dashed-dotted line.

Meanwhile, in the composite material of the first organic compound (Pyrrd-Phen), the second organic compound (6,6′(P-Bqn)₂BPy), and the metal (Li), which is one embodiment of the present invention, in the doublet ground state, the first organic compound (Pyrrd-Phen), the second organic compound (6,6′(P-Bqn)₂BPy), and the metal (Li) interact with one another, and the metal (Li) is coordinated to nitrogen atoms (N atoms at 1- and 10-positions) having unshared electron pairs in the 1,10-phenanthroline ring of the first organic compound (Pyrrd-Phen) and nitrogen atoms having unshared electron pairs in the pyridine ring and benzo[h]quinazoline ring of the second organic compound (6,6′(P-Bqn)₂BPy), which leads to stabilization of the formed composite material. Accordingly, as shown in FIG. 3, a positive electrostatic potential is mainly distributed in the metal (Li) and the first organic compound (Pyrrd-Phen), and a negative electrostatic potential is mainly distributed in the second organic compound (6,6′(P-Bqn)₂BPy). It is also shown that the electrostatic potential of the nitrogen atoms having unshared electron pairs in the pyridine ring and the benzo[h]quinazoline ring of the second organic compound (6,6′(P-Bqn)₂BPy) is negative whereas the electrostatic potential of the metal (Li) is positive. The Li atom has a Mulliken partial charge of +0.691 e in atomic units.

### [Estimation of SOMO Level or Stabilization Energy]

Next, a quantum chemical calculation is performed for estimation of the stabilization energy when the metal, the first organic compound having a π-electron deficient heteroaromatic ring, and the second organic compound having two or more heteroaromatic rings that are bonded or condensed to each other and include three or more heteroatoms in total interact with each other, and the SOMO level formed at this time.

As the quantum chemistry computational program, Gaussian 09 is used. The calculation is performed using HPE SGI 8600. First, the most stable structures of the first organic compound in a ground state, the second organic compound in a ground state, the metal in a ground state, the composite material in a ground state of the first organic compound and the metal, the composite material in a ground state of the second organic compound and the metal, and the composite material in a ground state of the first organic compound, the second organic compound, and the metal are calculated by DFT. As basis functions, 6-311G (d,p) and LanL2DZ are used, and as a functional, B3LYP is used. Next, the stabilization energy is calculated by subtracting the sum of the total energy of the organic compound(s) alone and the total energy of the metal alone from the total energy of the composite material of the organic compound(s) and the metal. That is, (stabilization energy)=(the total energy of the composite material of the organic compound(s) and the metal)−(the total energy of the organic compound(s) alone)−(the total energy of the metal alone).

The calculation result of a composite material including lithium (Li) as the metal, 4,7-di-1-pyrrolidinyl-1,10-phenanthroline (abbreviation: Pyrrd-Phen) as the first organic compound, and 2,2′-(2,2′-bipyridine-6,6′-diyl)bis(4-phenylbenzo[h]quinazoline) (abbreviation: 6,6′(P-Bqn)₂BPy) as the second organic compound is shown below. For comparison, the following also shows the calculation result of a composite material including lithium (Li) as the metal, Pyrrd-Phen as the first organic compound, and 2,9-di(naphthalen-2-yl)-4,7-diphenyl-1,10-phenanthroline (abbreviation: NBPhen) in place of 6,6′(P-Bqn)₂BPy as the second organic compound; the calculation result of a composite material including lithium (Li) and Pyrrd-Phen; the calculation result of a composite material including lithium (Li) and 6,6′(P-Bqn)₂BPy; and the calculation result of a composite material including lithium (Li) and NBPhen. Note that 6,6′(P-Bqn)₂BPy is the second organic compound having two or more heteroaromatic rings that are bonded or condensed to each other and include three or more heteroatoms in total. NBPhen is an organic compound having two or more heteroaromatic rings that are bonded or condensed to each other and include less than three heteroatoms in total.

TABLE 1

| | Stabilization | |
|---|---|---|
| | energy (eV) | SOMO (eV) |
| Pyrrd-Phen + 6,6′(P-Bqn)₂BPy + Li | −3.79 | −2.32 |
| Pyrrd-Phen + NBPhen + Li | −3.67 | −2.35 |
| Pyrrd-Phen + Li | −2.17 | −2.46 |
| 6,6′(P-Bqn)₂BPy + Li | −3.07 | −2.88 |
| NBPhen + Li | −2.31 | −2.96 |

TABLE 2

| | LUMO (eV) | HOMO (eV) |
|---|---|---|
| Pyrrd-Phen | −1.35 | −5.65 |
| 6,6′(P-Bqn)₂BPy | −2.07 | −5.99 |
| tPy2P | −1.65 | −6.37 |
| 2Py3Tzn | −2.20 | −6.89 |
| NBPhen | −2.04 | −5.74 |

As shown in Tables, the stabilization energy of the composite material of lithium (Li), the first organic compound (Pyrrd-Phen), and the second organic compound (6,6′(P-Bqn)₂BPy) of one embodiment of the present invention has a negative value having a larger absolute value. This indicates that energy is more stable in the case where the organic compounds and the metal interact with each other than in the case where the organic compounds and the metal do not interact with each other. The SOMO level formed at this time is preferable because it is higher than the HOMO level of each of the first organic compound (Pyrrd-Phen) and the second organic compound (6,6′(P-Bqn)₂BPy) and has a small difference from the LUMO level of each of the first organic compound (Pyrrd-Phen) and the second organic compound (6,6′(P-Bqn)₂BPy), offering a high electron-injection property. Note that the values of the energy levels of the SOMO, HOMO, and LUMO levels in Tables are calculated values and might have absolute values different from those of the measured values.

Although not as much as the composite material of lithium (Li), the first organic compound (Pyrrd-Phen), and the second organic compound (6,6′(P-Bqn)₂BPy), the composite material of lithium (Li), the first organic compound (Pyrrd-Phen), and NBPhen has a negative value of the stabilization energy, and the energy is more stable in the case where the organic compounds and the metal interact with each other than in the case where the organic compounds and the metal do not interact with each other.

The composite material of lithium (Li) and the first organic compound (Pyrrd-Phen) has a negative value of the stabilization energy, and will be further stabilized when further including the second organic compound.

In Table 1, the composite material of lithium (Li) and the second organic compound (6,6′(P-Bqn)₂BPy) has a low SOMO level of −2.88 eV. On the other hand, the composite material including the first organic compound (Pyrrd-Phen) in addition to lithium (Li) and the second organic compound (6,6′(P-Bqn)₂BPy) has a SOMO level of −2.32 eV, which is higher than that of the composite material of lithium (Li) and the second organic compound (6,6′(P-Bqn)₂BPy), and has an excellent electron-injection property. The composite material of lithium (Li) and the second organic compound (6,6′(P-Bqn)₂BPy) has stabilization energy of −3.07 eV, whereas the composite material including the first organic compound (Pyrrd-Phen) in addition to lithium (Li) and the second organic compound (6,6′(P-Bqn)₂BPy) has stabilization energy of −3.79 eV and is more stable.

In Table 1, the composite material of lithium (Li) and NBphen has a low SOMO level of −2.96 eV. On the other hand, the composite material including the first organic compound (Pyrrd-Phen) in addition to lithium (Li) and NBphen has a SOMO level of −2.35 eV, which is higher than that of the composite material of lithium (Li) and NBphen, and thus has an excellent electron-injection property. The composite material of lithium (Li) and NBphen has stabilization energy of −2.31 eV, whereas the composite material including the first organic compound (Pyrrd-Phen) in addition to lithium (Li) and NBphen has stabilization energy of −3.67 eV and is more stable.

That is to say, the composite material of one embodiment of the present invention, which includes the metal, the first organic compound having a π-electron deficient heteroaromatic ring, and the second organic compound having two or more heteroaromatic rings that are bonded or condensed to each other and include three or more heteroatoms in total, is stable and has a high electron-injection property, and thus is suitable for an electron-injection layer.

Next, the following tables show calculation results of composite materials including a metal belonging to Group 11 or Group 13, specifically silver (Ag) or indium (In), as the metal; Pyrrd-Phen as the first organic compound; and 4′,4″-(1,4-phenylene)bis(2,2′: 6′,2″-terpyridine) (abbreviation: tPy2P) or 2,4,6-tris(2-pyridyl)-1,3,5-triazine (abbreviation: 2Py3Tzn) as the second organic compound. For comparison, the tables also show calculation results of composite materials including silver (Ag) or indium (In) as the metal, Pyrrd-Phen as the first organic compound, and NBPhen in place of the second organic compound. Note that tPy2P and 2Py3Tzn are each the second organic compound having two or more heteroaromatic rings that are bonded or condensed to each other and include three or more heteroatoms in total. NBPhen is the organic compound having two or more heteroaromatic rings that are bonded or condensed to each other and include less than three heteroatoms in total.

TABLE 3

| | Stabilization | |
|---|---|---|
| | energy (eV) | SOMO (eV) |
| Pyrrd-Phen + tPy2P + In | −2.15 | −3.03 |
| Pyrrd-Phen + NBPhen + In | −1.25 | −3.02 |

TABLE 4

| | Stabilization | |
|---|---|---|
| | energy (eV) | SOMO (eV) |
| Pyrrd-Phen + 2Py3Tzn + Ag | −1.79 | −2.56 |
| Pyrrd-Phen + NBPhen + Ag | −1.26 | −2.50 |

As shown in the above tables, the composite materials of one embodiment of the present invention, each of which includes the metal belonging to Group 11 or Group 13, the first organic compound, and the second organic compound, are preferable because of having a high stabilization energy and having a stable structure. The SOMO level formed at this time is high to offer a high electron-injection property, which is preferable.

In a general fabrication process of a light-emitting device, an EL layer, particularly an electron-injection layer, of the light-emitting device is mostly formed by a vacuum evaporation method. Thus, it is preferable to use a material that can be easily deposited by vacuum evaporation, i.e., a material with a low melting point. The metal elements belonging to Group 11 and Group 13 have low melting points and thus, they can be suitably used for vacuum evaporation. The metal elements belonging to Group 11 and Group 13 are preferable because they are stable with respect to oxygen and water in the air. A vacuum evaporation method is preferably used, in which case a metal atom and an organic compound can be easily mixed.

Furthermore, Ag and In can be used also as a cathode material. Using the same material for an electron-injection layer and a cathode is preferable, in which case the fabrication of the light-emitting device can become easier. Moreover, the fabrication cost of the light-emitting device can be reduced.

The above indicates that owing to the interaction between the first organic compound having a π-electron deficient heteroaromatic ring, the metal, and the second organic compound having two or more heteroaromatic rings that are bonded or condensed to each other and include three or more heteroatoms in total, the combination of the first organic compound and the metal functions as an electron donor to the second organic compound. In one embodiment of the present invention, the electron-injection layer formed using this combined materials can have a high electron-injection property and resistance to oxygen and water in the air and water and a chemical solution used in a lithography process; thus, the light-emitting device can have a reduced driving voltage and high emission efficiency.

### <<Electron-Injection Layer>>

The electron-injection layer 115 is provided between the second electrode 102 as a cathode and the light-emitting layer 113 as illustrated in FIG. 1A, and includes the metal or the metal compound, the first organic compound having π-electron deficient heteroaromatic ring, and the second organic compound having two or more heteroaromatic rings that are bonded or condensed to each other and include three or more heteroatoms in total.

### <Metal or Metal Compound>

As the metal or metal compound, a typical metal, a transition metal, or a compound thereof can be used. Examples of the metal compound include a metal oxide, a metal nitride, a metal oxynitride in which nitrogen is added to a metal oxide, and a metal nitride oxide in which oxygen is added to a metal nitride.

As the typical metal, an alkali metal (Group 1 element) such as Li, Na, K, or Cs, an alkaline earth metal (Group 2 element) such as Mg, Ca, or Ba, a Group 12 element such as Zn, an earth metal (Group 13 element) such as Al or In, a Group 14 element such as Sn, or a compound of a Group 1, 2, 13, or 14 element can be used.

An alkali metal, an alkaline earth metal, or a compound thereof is preferably used as the metal, in which case the donor level formed by interaction with the first organic compound and the second organic compound can be a high energy level, electrons can be injected and transported smoothly from the electron-injection layer to the electron-transport layer, and a light-emitting device having a low driving voltage and high emission efficiency can be provided.

As the transition metal, any of Group 3 elements, including Y and lanthanoids such as Eu and Yb, Group 7 elements such as Mn, Group 8 elements such as Fe, Group 9 elements such as Co, Group 10 elements such as Ni and Pt, Group 11 elements such as Cu, Ag, and Au, and a compound of a Group 3, 7, 8, 9, 10, or 11 element can be used. The transition metal is preferable because it has low reactivity with components of the air such as water and oxygen.

Among the above-described examples, it is further preferable to use a metal belonging to an odd-numbered group (Group 1, Group 3, Group 5, Group 7, Group 9, Group 11, or Group 13). It is particularly preferable to use a metal having one electron (an unpaired electron) in the orbital of the outermost shell among transition metals belonging to the odd-numbered groups, in which case the metal is likely to form SOMO with the first organic compound.

A metal that has a low melting point and that can be deposited by a vacuum evaporation method is preferably used because a mixed layer of this metal and an organic compound is easy to form. Specifically, for example, the metals belonging to Group 11 and Group 13 have low melting points and thus, they can be suitably used for vacuum evaporation. The metals belonging to Group 11 and Group 13 are preferable because they are stable with respect to oxygen and water in the air.

### <First Organic Compound>

As the first organic compound, an organic compound having a π-electron deficient heteroaromatic ring can be used. In order that the first organic compound and the metal interact with each other to function as an electron donor (donating electrons) to the second organic compound, the π-electron deficient heteroaromatic ring preferably includes an unshared electron pair, and the unshared electron pair preferably has an electron-donating property. In other words, the first organic compound preferably includes a basic π-electron deficient heteroaromatic ring. Moreover, nitrogen has high electronegativity and thus easily interacts with a metal. In addition, since nitrogen can form a conjugated bond in an organic compound, nitrogen enables the organic compound to have a high carrier-transport property when used in the molecule, particularly in a heteroaromatic ring. Accordingly, the first organic compound preferably includes a heteroaromatic ring containing nitrogen. It is further preferable that the heteroaromatic ring be an even-numbered ring such as a six-membered ring or an eight-membered ring. Since the unshared electron pair of nitrogen does not contribute to the conjugation in this structure, nitrogen is likely to interact with the metal. To inject and transport electrons smoothly from the electron-injection layer to the electron-transport layer, the first organic compound preferably has an electron-transport property. Specifically, for example, the first organic compound preferably includes a pyridine ring.

It is preferable that the first organic compound include two or more π-electron deficient heteroaromatic rings each having an unshared electron pair, and the two or more π-electron deficient heteroaromatic rings be bonded or condensed to each other. Thus, the electron-injection layer is stabilized when the metal or the metal compound interacts with the first organic compound and the second organic compound each serving as a bidentate or multidentate ligand such as a bi-or higher dentate ligand; thus, the electron-injection layer that is less likely to deteriorate even through a photolithography process involving exposure to the air can be formed. Specifically, for example, the first organic compound preferably includes a heteroaromatic ring having two or more pyridine rings. In particular, an organic compound having a bipyridine skeleton is preferable because its nitrogen atoms are likely to coordinate with a metal and thus the organic compound easily interacts with the metal or the metal compound.

Furthermore, a phenanthroline ring is preferable because of its rigidity and high stability. Among organic compounds having a phenanthroline ring, an organic compound having a 1,10-phenanthroline ring, the two nitrogen atoms of which can be coordinated to a metal, is particularly preferably used to facilitate interaction with the metal or the metal compound.

The first organic compound may have a structure in which a plurality of phenanthroline rings are bonded to each other via a single bond or a divalent group. Specific examples of the divalent group include an alkylene group and an arylene group.

An alkylene group refers to a divalent group obtained by eliminating two hydrogen atoms from an alkane. Specific examples of an alkylene group include a divalent group having a structure obtained by eliminating one hydrogen atom from any of the below specific examples of an alkyl group.

An arylene group refers to a divalent group obtained by eliminating two hydrogen atoms from an aromatic hydrocarbon. Specific examples of an arylene group include a divalent group having a structure obtained by eliminating one hydrogen atom from any of the below specific examples of an aryl group. Note that the arylene group may further have a substituent, and specific examples of the substituent include an alkyl group, an alkoxy group, and a phenyl group.

The first organic compound preferably has an electron-donating group. Accordingly, the first organic compound can have a high HOMO level and a high LUMO level; thus, the difference between the LUMO level of the first organic compound and the LUMO level of the second organic compound can be increased, in which case the electron-injection layer can be stabilized by interaction between the metal or the metal compound, the first organic compound, and the second organic compound and is less likely to deteriorate even through a photolithography process involving exposure to the air.

As the first organic compound, an organic compound having a phenanthroline ring with an electron-donating group is further preferably used. Specifically, introducing an electron-donating group to a 1,10-phenanthroline ring can increase the electron density of the phenanthroline ring and the efficiency of the interaction with the metal. Furthermore, an electron-donating group is preferably bonded to at least one of the 4- and 7-positions of the 1,10-phenanthroline ring. Introducing electron-donating groups to the 4- and 7-positions can increase the electron density of the nitrogen atoms at the 1- and 10-positions, which are the para-positions with respect to the 4- and 7-positions. In addition, steric congestion around the nitrogen atoms at the 1- and 10-positions can be inhibited, and the electron density around the nitrogen atoms can be increased. This structure facilitates the interaction with the metal and is thus preferable.

Specific examples of the electron-donating group include an alkyl group, an alkoxy group, an aryloxy group, an alkylamino group, an arylamino group, and a heterocyclic amino group. Note that the electron-donating group that is preferably introduced to the π-electron deficient heteroaromatic ring such as a phenanthroline ring is not limited to the above examples. As long as a group that is introduced to a π-electron deficient heteroaromatic ring such as a phenanthroline ring can increase the electron density of the π-electron deficient heteroaromatic ring, the group can be used as the electron-donating group. The electron-donating group may be introduced to a π-electron deficient heteroaromatic ring such as a phenanthroline ring via an arylene group such as a phenylene group, and the arylene group is preferably a p-phenylene group.

An alkyl group refers to a monovalent group obtained by eliminating one hydrogen atom from an alkane (CₙH₂ₙ₊₂). Specific examples of an alkyl group include a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a 3-methylpentyl group, a 2-methylpentyl group, a 2-ethylbutyl group, a 1,2-dimethylbutyl group, and a 2,3-dimethylbutyl group.

An alkoxy group refers to a monovalent group with a structure in which an alkyl group is bonded to an oxygen atom. Specific examples of an alkoxy group include a methoxy group, an ethoxy group, an n-propoxy group, an isopropoxy group, an n-butoxy group, a sec-butoxy group, an isobutoxy group, a tert-butoxy group, an n-pentyloxy group, an isopentyloxy group, a sec-pentyloxy group, a tert-pentyloxy group, a neopentyloxy group, an n-hexyloxy group, an isohexyloxy group, a sec-hexyloxy group, a tert-hexyloxy group, and a neohexyloxy group.

An aryloxy group refers to a monovalent group with a structure in which an aryl group is bonded to an oxygen atom. An aryl group refers to a monovalent group obtained by eliminating one hydrogen atom from one of carbon atoms forming the ring(s) of a monocyclic or polycyclic aromatic compound. Specific examples of an aryloxy group include a phenoxy group, an o-tolyloxy group, a m-tolyloxy group, a p-tolyloxy group, a mesityloxy group, an o-biphenyloxy group, a m-biphenyloxy group, a p-biphenyoxyl group, a 1-naphthyloxy group, a 2-naphthyloxy group, and a 2-fluorenyloxy group. Note that the aryloxy group may further have a substituent, and specific examples of the substituent include an alkyl group, an alkoxy group, and a phenyl group.

An alkylamino group refers to a monovalent group obtained by eliminating one hydrogen atom from the nitrogen atom of a primary amine in which one alkyl group is bonded to the nitrogen atom, or from the nitrogen atom of a secondary amine in which two alkyl groups are bonded to the nitrogen atom. Specific examples of an alkylamino group include a dimethylamino group and a diethylamino group.

An arylamino group refers to a monovalent group obtained by eliminating one hydrogen atom from the nitrogen atom of a primary amine in which one aryl group is bonded to the nitrogen atom, or from the nitrogen atom of a secondary amine in which two aryl groups are bonded to the nitrogen atom. Specific examples of an arylamino group include a diphenylamino group, a bis(α-naphthyl)amino group, and a bis(m-tolyl) amino group. Note that the arylamino group may further have a substituent, and specific examples of the substituent include an alkyl group, an alkoxy group, and a phenyl group.

Note that an amino group having a structure in which both an alkyl group and an aryl group are bonded to the nitrogen atom can be regarded as an alkylamino group or an arylamino group. Specific examples of such an amino group include an N-methyl-N-phenylamino group.

A heterocyclic amino group refers to a monovalent group obtained by eliminating one hydrogen atom from one of the nitrogen atoms forming a ring of a heterocyclic amine. Here, the heterocyclic amine refers to a monocyclic or polycyclic heterocyclic compound in which at least one of the atoms forming the ring(s) is a nitrogen atom bonded to a hydrogen atom. Specific examples of a heterocyclic amino group include groups represented by Structural Formulae (R-1) to (R-26) below. Note that the heterocyclic amino group may further have a substituent, and specific examples of the substituent include an alkyl group, an alkoxy group, and a phenyl group.

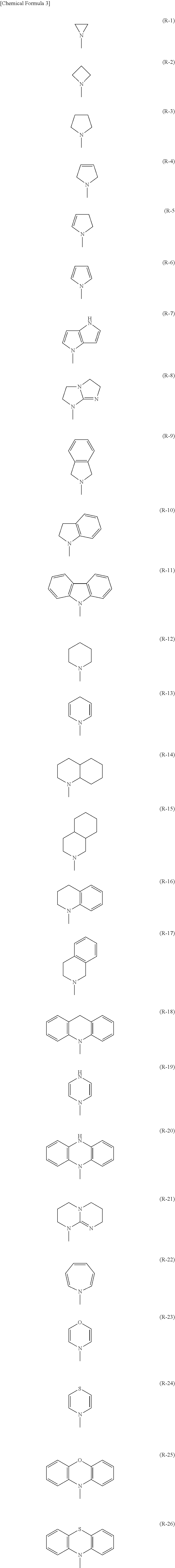

In some cases, the property of donating electrons to the phenanthroline ring is lower in a heterocyclic amino group which has aromaticity and in which an unshared electron pair of the nitrogen atom contributes to the aromaticity than in a heterocyclic amino group which has aromaticity and in which an unshared electron pair of the nitrogen atom does not contribute to the aromaticity. Therefore, among the above heterocyclic amino groups, a heterocyclic amino group which has aromaticity and in which an unshared electron pair of the nitrogen atom does not contribute to the aromaticity is further preferable. Specifically, the group represented by Structural Formula (R-1), (R-2), (R-3), (R-4), (R-5), (R-8), (R-9), (R-10), (R-12), (R-14), (R-15), (R-16), (R-17), or (R-21) is further preferably used as the electron-donating group. Among these groups, the group represented by Structural Formula (R-3), (R-4), (R-8), or (R-21) is preferably used because the group has a high electron-donating property and can further increase the electron density of the phenanthroline ring.

Specific examples of the electron-donating group include groups represented by Structural Formulae (R-27) and (R-28) below.

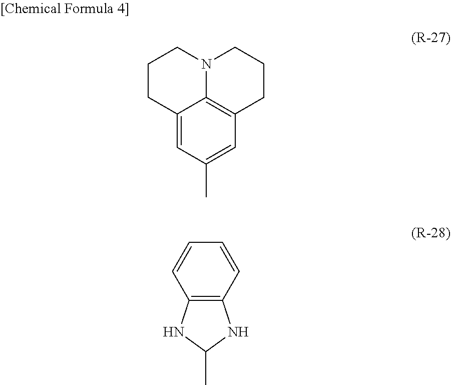

Note that an organic compound with a π-electron deficient heteroaromatic ring that can be used as the first organic compound may have both the above-described electron-donating group and another substituent. Specific examples of the substituent that can be introduced to the π-electron deficient heteroaromatic ring together with the above electron-donating group include an aryl group. Specific examples of the aryl group include a phenyl group, an o-tolyl group, a m-tolyl group, a p-tolyl group, a mesityl group, an o-biphenyl group, a m-biphenyl group, a p-biphenyl group, a 1-naphthyl group, a 2-naphthyl group, and a 2-fluorenyl group. Note that the aryl group may further have a substituent, and specific examples of the substituent include an alkyl group, an alkoxy group, and a phenyl group.

The first organic compound may have a structure in which a plurality of phenanthroline rings are bonded to each other via a single bond or a divalent group. Specific examples of the divalent group include an alkylene group and an arylene group.

Specific examples of an organic compound with a π-electron deficient heteroaromatic ring that can be used as the first organic compound are represented by Structural Formulae (100) to (112). Note that the organic compound that can be used as the first organic compound is not limited to those examples.

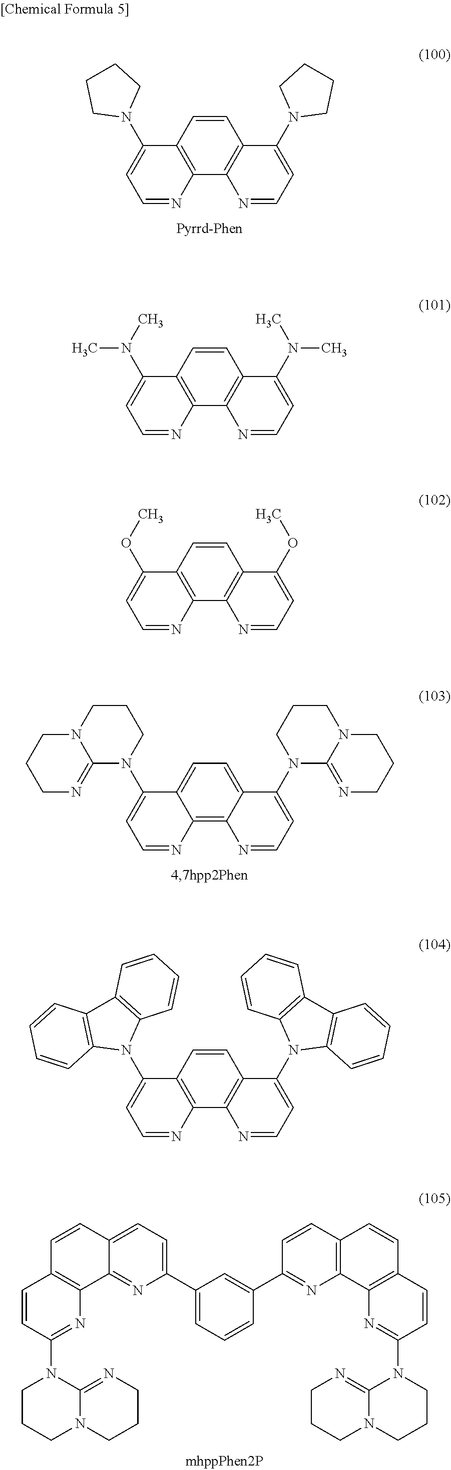

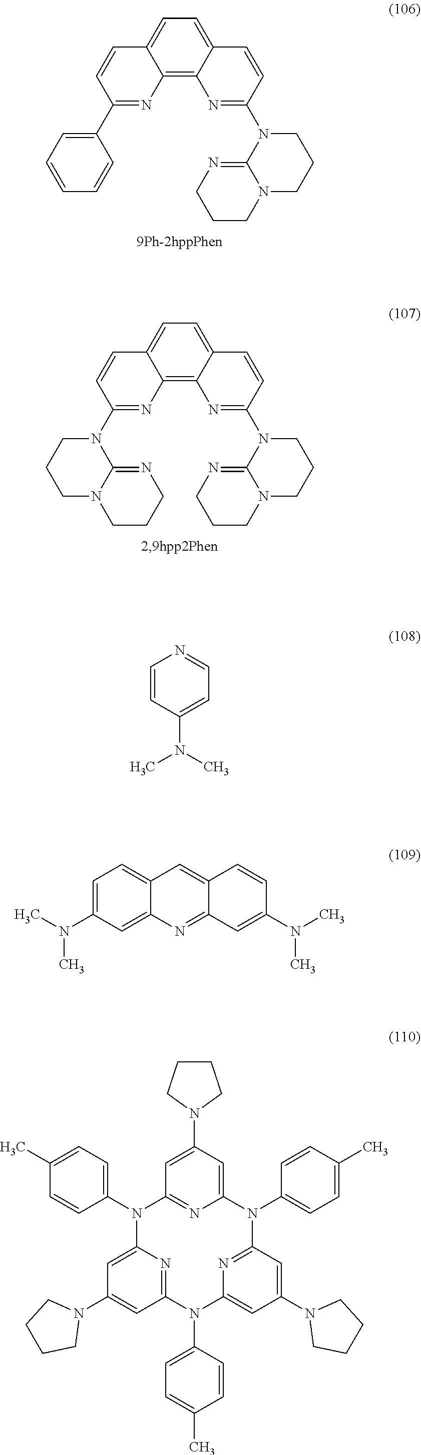

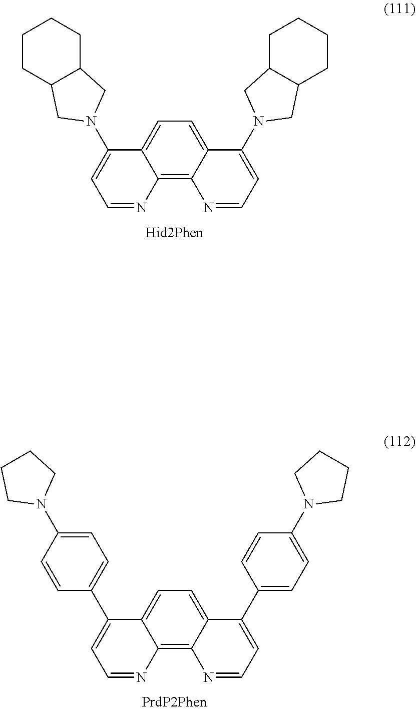 [SMILES: c1cc(N2CC3CCCCC3C2)c2ccc3c(N4CC5CCCCC5C4)ccnc3c2n1 ; c1cc(-c2ccc(N3CCCC3)cc2)c2ccc3c(-c4ccc(N5CCCC5)cc4)ccnc3c2n1]

Structural Formula (100) shows 4,7-di-1-pyrrolidinyl-1,10-phenanthroline (abbreviation: Pyrrd-Phen). Structural Formula (103) shows 4,7-bis(1,3,4,6,7,8-hexahydro-2H-pyrimido[1,2-a]pyrimidin-1-yl)-1,10-phenanthroline (abbreviation: 4,7hpp2Phen). Structural Formula (105) shows 2,2′-(1,3-phenylene)bis[9-(1,3,4,6,7,8-hexahydro-2H-pyrimido[1,2-a]pyrimidin-1-yl)-1,10-phenanthroline] (abbreviation: mhppPhen2P). Structural Formula (106) shows 2-(1,3,4,6,7,8-hexahydro-2H-pyrimido[1,2-a]pyrimidin-1-yl)-9-phenyl-1,10-phenanthroline (abbreviation: 9Ph-2hppPhen). Structural Formula (107) shows 2,9-bis(1,3,4,6,7,8-hexahydro-2H-pyrimido[1,2-a]pyrimidin-1-yl)-1,10-phenanthroline (abbreviation: 2,9hpp2Phen). Structural Formula (111) shows 4,7-di(2,3,3a,4,5,6,7,7a-octahydro-1H-isoindol-2-yl)-1,10-phenanthroline (abbreviation: Hid2Phen). Structural Formula (112) shows 4,7-bis[4-(1-pyrrolidinyl)phenyl]-1,10-phenanthroline (abbreviation: PrdP2Phen).

The negative minimum value of the electrostatic potential (ESP) of the first organic compound is preferably small (i.e., the negative minimum value preferably has a large absolute value), in which case the stability of the interaction with the metal is high. In an organic compound including a π-electron deficient heteroaromatic ring, the electrostatic potential around nitrogen atoms of the π-electron deficient heteroaromatic ring, which is likely to be negative, can be further lowered (i.e., the absolute value of the negative value can be increased) by introduction of an electron-donating group to the π-electron deficient heteroaromatic ring. Note that an electrostatic potential is the energy of interaction between positive point charge with unit quantity of electricity and electron distribution of a molecule. An electrostatic potential value also depends on the threshold value of electron density distribution. To increase the efficiency of the interaction with the metal, the minimum value of the electrostatic potential of the first organic compound is preferably smaller (has a larger absolute value) than the minimum value of the electrostatic potential of a phenanthroline ring having no substituent. Specifically, when the threshold value of electron density distribution in atomic units is 0.0004 e/a₀³, the minimum value of the electrostatic potential is preferably smaller than or equal to −0.085 Eₕ (Eₕ is the Hartree energy (1 Eₕ=27.211 eV)), further preferably smaller than or equal to −0.090 Eₕ. When the threshold value of electron density distribution is 0.003 e/a₀³, the minimum value of the electrostatic potential is preferably smaller than or equal to −0.12 Eₕ, further preferably smaller than or equal to −0.13 Eₕ.

### <<Characteristic Estimation of First Organic Compound by Quantum Chemical Calculation>>

The minimum values of the electrostatic potentials (ESP) of the above organic compounds that can be used as the first organic compound are estimated by quantum chemical calculation.

As the quantum chemistry computational program, Gaussian 09 is used. The calculation is performed using HPE SGI 8600. The most stable structure of the first organic compound in a ground state is calculated by DFT. As a basis function, 6-311G (d,p) is used, and as a functional, B3LYP is used.

The following table shows the analysis results of the electrostatic potentials of the first organic compound in a ground state. Note that an electrostatic potential is the energy of interaction between positive point charge with unit quantity of electricity and electron distribution of a molecule. An electrostatic potential value also depends on the threshold value of electron density distribution. The following table shows electrostatic potentials in electron density distribution at the time when the threshold value of electron density distribution in atomic units is 0.0004 e/a₀³ or 0.003 e/a₀³.

TABLE 5

| | | Minimum | Minimum |
|---|---|---|---|
| | | value of ESP | value of ESP |
| | | (threshold value of | (threshold value of |
| | | electron density | electron density |
| | | distribution = 0.0004) | distribution = 0.003) |
| Pyrrd-Phen | (100) | −0.091 | −0.12 |
| DMeAPhen | (101) | −0.089 | −0.12 |
| p-MeO-Phen | (102) | −0.089 | −0.12 |
| 4,7hpp2Phen | (103) | −0.096 | −0.13 |
| CzPhen | (104) | −0.072 | −0.10 |
| mhppPhen2P | (105) | −0.057 | −0.096 |
| 9Ph2hppPhen | (106) | −0.057 | −0.096 |
| 2,9hpp2Phen | (107) | −0.061 | −0.097 |
| Hid2Phen | (111) | −0.094 | −0.13 |
| PrdP2Phen | (112) | −0.094 | −0.13 |
| Bphen | | −0.083 | −0.11 |
| mPPhen2P | | −0.057 | −0.094 |
| NBphen | | −0.053 | −0.093 |
| Phen | | −0.081 | −0.11 |

Note that the organic compounds represented by Structural Formulae (101) to (107), (111), and (112) shown as the organic compounds that can be used as the first organic compound, BPhen, mPPhen2P, NBPhen, and Phen in Table 5 are shown below.

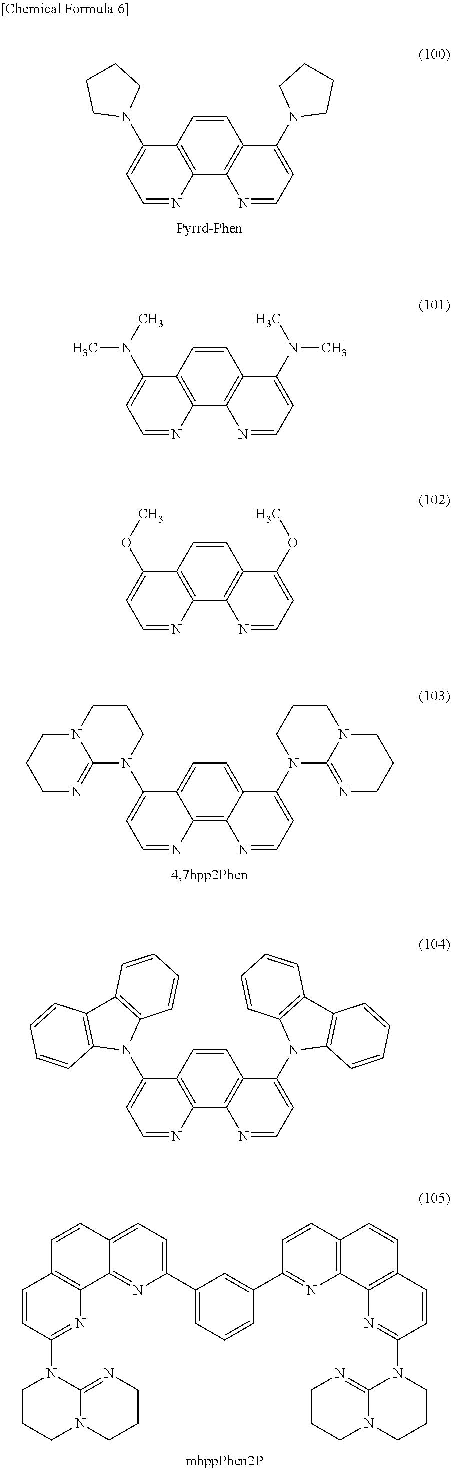

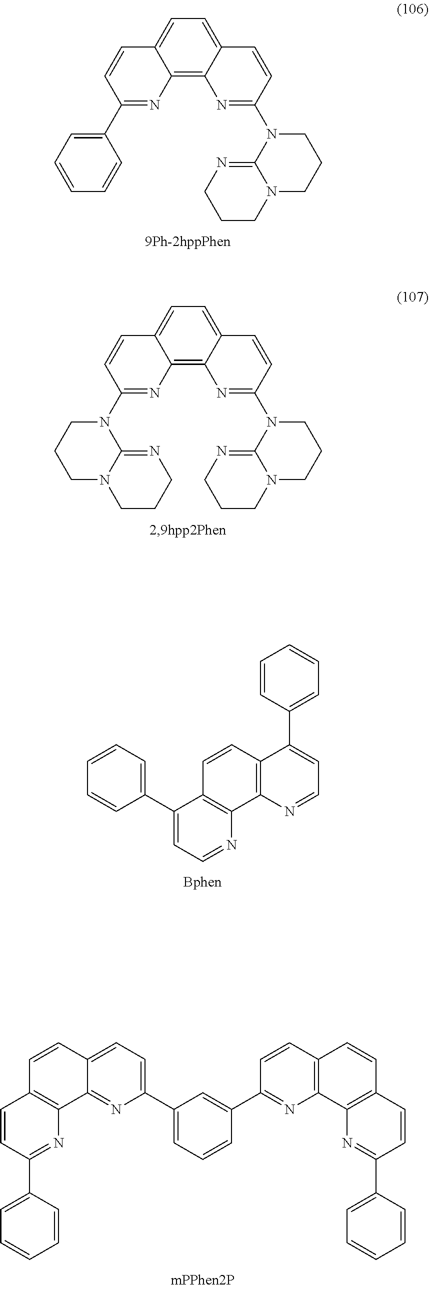 [SMILES: c1ccc(-c2ccc3ccc4ccc(N5CCCN6CCCN=C65)nc4c3n2)cc1 ; c1cc2ccc3ccc(N4CCCN5CCCN=C54)nc3c2nc1N1CCCN2CCCN=C21 ; c1ccc(-c2ccnc3c2ccc2c(-c4ccccc4)ccnc23)cc1 ; c1ccc(-c2ccc3ccc4ccc(-c5cccc(-c6ccc7ccc8ccc(-c9ccccc9)nc8c7n6)c5)nc4c3n2)cc1]

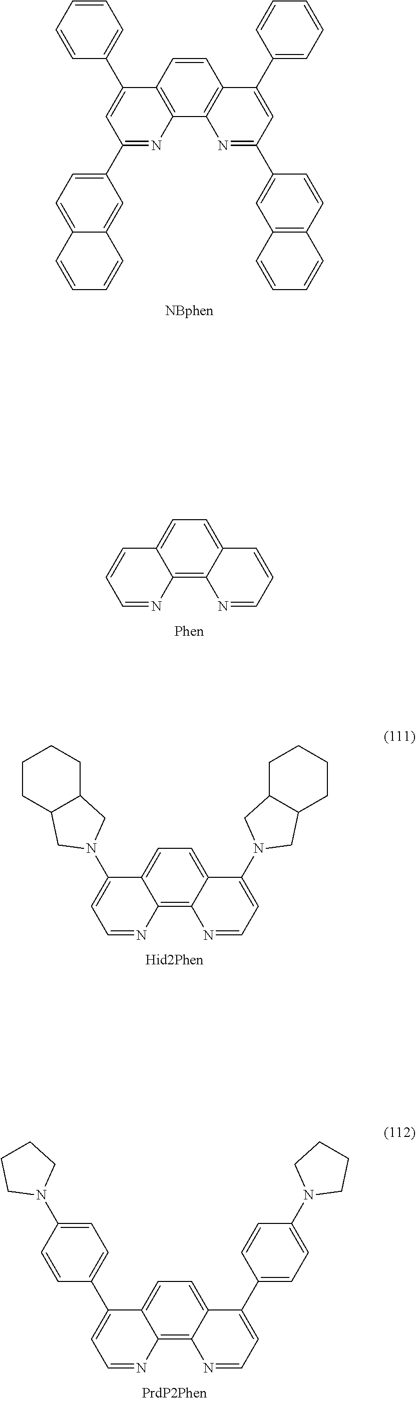 [SMILES: c1ccc(-c2cc(-c3ccc4ccccc4c3)nc3c2ccc2c(-c4ccccc4)cc(-c4ccc5ccccc5c4)nc23)cc1 ; c1cnc2c(c1)ccc1cccnc12 ; c1cc(N2CC3CCCCC3C2)c2ccc3c(N4CC5CCCCC5C4)ccnc3c2n1 ; c1cc(-c2ccc(N3CCCC3)cc2)c2ccc3c(-c4ccc(N5CCCC5)cc4)ccnc3c2n1]

The above table indicates that the minimum values of ESP of the organic compounds represented by Structural Formulae (100) to (103), (111), and (112) are each smaller than or equal to −0.085 Eₕ when the threshold value of electron density distribution in atomic units is 0.0004 e/a₀³ and that using any of these organic compounds as the first organic compound is the most preferable. On the other hand, the minimum values of ESP of the organic compounds represented by Structural Formulae (104) to (107) are each larger than −0.085 Eₕ.

It is shown that the organic compounds represented by Structural Formulae (100) to (103), (111), and (112) have the most favorable values because of having an electron-donating group at each of the 4- and 7-positions of the 1,10-phenanthroline ring.

The organic compound represented by Structural Formula (104) has N-carbazolyl groups as electron-donating groups at the 4- and 7-positions of the 1,10-phenanthroline ring. In the N-carbazolyl group, in which an unshared electron pair of the nitrogen atom contributes to aromaticity, the property of donating electrons to the phenanthroline ring is lower than that in a group in which an unshared electron pair of a nitrogen atom does not contribute to aromaticity, inhibiting a reduction in the minimum value of ESP of the organic compound represented by Structural Formula (104).

The organic compounds represented by Structural Formulae (105) to (107) each have electron-donating groups at the 2- and 9-positions of the 1,10-phenanthroline ring. The electron-donating groups introduced to the 2- and 9-positions have a low property of donating electrons to the nitrogen atoms at the 1- and 10-positions of the phenanthroline ring. It is thus preferable that electron-donating groups be at the 4- and 7-positions of a 1,10-phenanthroline ring.

Note that the LUMO level of the second organic compound is further preferably lower than that of the first organic compound. In that case, electrons can be easily donated from the donor level formed by the first organic compound and the metal to the second organic compound. The LUMO level of the second organic compound is preferably lower than that of the first organic compound so that the second organic compound can have an electron-transport property.

For example, the LUMO level of the first organic compound is preferably higher than or equal to −3.0 eV and lower than or equal to −2.0 eV, further preferably higher than or equal to −2.7 eV and lower than or equal to −2.0 eV. The LUMO level of the second organic compound is preferably higher than or equal to −3.0 eV and lower than or equal to −2.0 eV, further preferably higher than or equal to −3.0 eV and lower than or equal to −2.5 eV. In the above case, electrons can be easily donated from the donor level formed by the first organic compound and the metal to the second organic compound. This facilitates electron transport in the second organic compound.

Note that the HOMO level and the LUMO level of an organic compound are generally estimated by cyclic voltammetry (CV), photoelectron spectroscopy, optical absorption spectroscopy, inverse photoemission spectroscopy, or the like. When values of different compounds are compared with each other, it is preferable that values estimated by the same measurement be used.

The first organic compound is preferably strongly basic, in which case the first organic compound interacts with holes to significantly reduce the hole-transport property in the electron-injection layer and prevent hole transport from the electron-injection layer to the electron-transport layer, enabling high efficiency of the light-emitting device. Specifically, the acid dissociation constant pKₐ of the first organic compound is preferably higher than or equal to 8, further preferably higher than or equal to 10, still further preferably higher than or equal to 12.

In the case where the acid dissociation constant pKₐ of an organic compound is unknown, the acid dissociation constants pKₐ of skeletons in the organic compound are calculated and the largest acid dissociation constant pKₐ can be regarded as the acid dissociation constant pKₐ of the organic compound.

The acid dissociation constant may be obtained by calculation. For example, the acid dissociation constant pKₐ can be obtained by the following calculation method.

The initial structure of a molecule serving as a calculation model is the most stable structure (the singlet ground state) obtained by first-principles calculation.

For the first-principles calculation, Jaguar, which is the quantum chemical computational software (Schrödinger, Inc.) is used, and the most stable structure in the singlet ground state is calculated by DFT. As a basis function, 6-31G** is used, and as a functional, B3LYP-D3 is used. The structure subjected to quantum chemical calculation is sampled by conformational analysis in mixed torsional/low-mode sampling with Maestro GUI (Schrödinger, Inc.)

In the calculation of pKₐ, one or more atoms in each molecule are designated as basic sites, MacroModel is used to search for the stable structure of the protonated molecule in water, conformational search is performed with OPLS2005 force field, and a conformational isomer having the lowest energy is used. Jaguar's pKₐ calculation module is used. After structure optimization is performed by B3LYP/6-31G*, single point calculation is performed by cc-pVTZ (+) and the pKₐ value is calculated using empirical correction for functional group(s). In the case where one or more atoms are designated as basic sites in a molecule, the largest of obtained values is used as a pKₐ value. The obtained pKₐ values are shown below.

The acid dissociation constant pKₐ of 2,9hpp2Phen is 13.35, pKₐ of 4,7hpp2Phen is 13.42, pKₐ of Pyrrd-Phen is 11.23, pKₐ of mPPhen2P is 5.16, pKₐ of NBPhen is 5.59, and pKₐ of BPhen is 5.62.

### <Second Organic Compound>

The electron-injection layer includes the second organic compound having two or more heteroaromatic rings that are bonded or condensed to each other and include three or more heteroatoms in total, in addition to the metal or the metal compound and the first organic compound. The second organic compound has a function of interacting with the metal or the metal compound by two or more of the three or more heteroatoms as a multidentate ligand.

The second organic compound can improve heat resistance, electron-transport properties, and the like. In the case where the π-electron deficient heteroaromatic ring of the first organic compound is referred to as a first π-electron deficient heteroaromatic ring and the π-electron deficient heteroaromatic ring of the second organic compound is referred to as a second π-electron deficient heteroaromatic ring in one embodiment of the present invention, the first π-electron deficient heteroaromatic ring and the second π-electron deficient heteroaromatic ring preferably include different rings.

As the second π-electron deficient heteroaromatic ring, a heteroaromatic ring having an azole skeleton (an imidazole ring, a pyrazole ring, an oxazole ring, a thiazole ring, a triazole ring, an oxadiazole ring, or a thiadiazole ring), a heteroaromatic ring having a pyridine skeleton, a heteroaromatic ring having a diazine skeleton, a heteroaromatic ring having a triazine skeleton, or the like is preferable, and a diazine ring (a pyrazine ring, a pyrimidine ring, or a pyridazine ring) and a triazine ring are particularly preferable because they are electrochemically stable and have a high electron-transport property.

For example, an organic compound represented by General Formula (G1-1) below can be used as the organic compound used for the second organic compound.

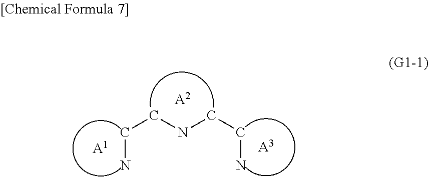

In General Formula (G1-1) above, A¹, A², and A³ each independently represent a substituted or unsubstituted heteroaromatic ring having 1 to 30 carbon atoms, and A¹, A², and A³ may form a condensed ring with each other.

The organic compound represented by General Formula (G1-1) includes a conjugated double bond in which N in the heteroaromatic ring are arranged in the order of N—C—C—N, and have a function of interacting with a metal as a tri- or higher dentate ligand. An organic compound having such a structure is likely to interact with a metal and thus can be suitably used for an electron-injection layer.

In General Formula (G1-1), examples of the substituted or unsubstituted heteroaromatic rings having 1 to 30 carbon atoms, which are represented by A¹, A², and A³, include a heteroaromatic ring having a pyridine skeleton (a pyridine ring, a quinoline ring, an isoquinoline ring, a naphthyridine ring, a bipyridine ring, a phenanthridine ring, a phenanthroline ring, an anthyridine ring, or an azafluoranthene ring), a heteroaromatic ring having a diazine skeleton (a pyrazine ring, a pyrimidine ring, a pyridazine ring, a quinoxaline ring, a benzoquinoxaline ring, a dibenzoquinoxaline ring, a quinazoline ring, a benzoquinazoline ring, a phthalazine ring, a cinnoline ring, a pteridine ring, or a phenazine ring), a heteroaromatic ring having a triazine skeleton, and a heteroaromatic ring having an azole skeleton (an imidazole ring, a benzimidazole ring, a pyrazole ring, an oxazole ring, a thiazole ring, a triazole ring, an oxadiazole ring, or a thiadiazole ring). Note that the substituted or unsubstituted heteroaromatic rings having 1 to 30 carbon atoms represented by A¹, A², and A³ are not limited to these. A¹, A², and A³ may form a condensed ring with each other. For example, A¹ and A² may be bonded to each other to form a phenanthroline ring.

As the second organic compound, an organic compound represented by General Formula (G2-1) can be used.

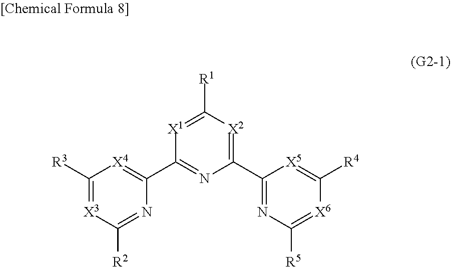

In General Formula (G2-1), X¹ to X⁶ each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to carbon atoms; and R¹ to R⁴ each independently represent hydrogen, an alkyl group having 1 to carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms. Alternatively, in General Formula (G2-1), X¹ to X⁶ may be directly bonded to each other or bonded to each other via carbon to form a condensed ring.

As in the organic compound represented by General Formula (G2-1), it is further preferable that the organic compound having a function of interacting with the metal as a tri- or higher dentate ligand include at least one of a heteroaromatic ring having a pyridine skeleton, a heteroaromatic ring having a diazine skeleton, and a heteroaromatic ring having a triazine skeleton. A light-emitting device including any of these rings can have high reliability because these rings have high electrochemical stability. Moreover, the driving voltage of the light-emitting device can be reduced because these rings have high electron-transport properties.

As the second organic compound, an organic compound represented by General Formula (G3-1) can be used.

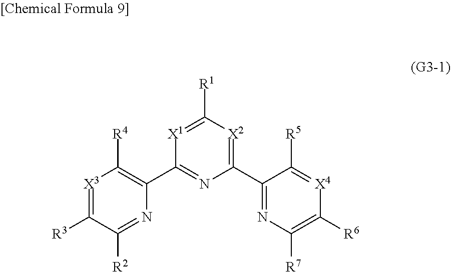

In General Formula (G3-1), X¹ to X⁴ each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to carbon atoms; and R¹ to R⁶ each independently represent hydrogen, an alkyl group having 1 to carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms.

As the second organic compound, an organic compound represented by General Formula (G4-1) below can also be used.

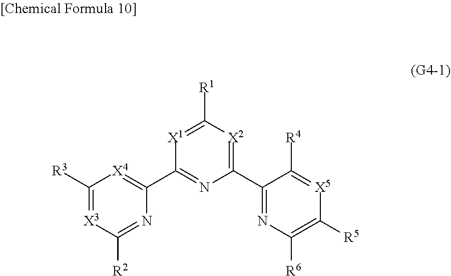

In General Formula (G4-1), X¹ to X⁵ each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to carbon atoms; and R¹ to R⁵ each independently represent hydrogen, an alkyl group having 1 to carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms.

An organic compound having a pyridine skeleton has a high LUMO level, which is preferable. Thus, when X¹ and X² in each of General Formulae (G2-1) to (G4-1) represent carbon, the organic compound represented by each of General Formulae (G2-1) to (G4-1), which has a pyridine skeleton, can form a composite material with a high SOMO level when interacting with a metal. That is, when such an organic compound having a pyridine ring and a function of interacting with a metal as a tri- or higher dentate ligand interacts with a metal, an electron-injection layer having a high electron-injection property can be formed.

An organic compound having a diazine skeleton or a triazine skeleton is preferable because it is electrochemically stable and has a high electron-transport property. Thus, when at least one of X¹ and X² in each of General Formulae (G2-1) to (G4-1) represents nitrogen, the organic compound represented by each of General Formulae (G2-1) to (G4-1), which has a diazine skeleton or a triazine skeleton, can form a stable composite material with a high electron-transport property when interacting with a metal. That is, when such an organic compound having a diazine ring or a triazine ring and a function of interacting with a metal as a tri- or higher dentate ligand interacts with a metal, an electron-injection layer having high reliability can be formed.

As the second organic compound, an organic compound represented by General Formula (G1-2) below can also be used, for example.

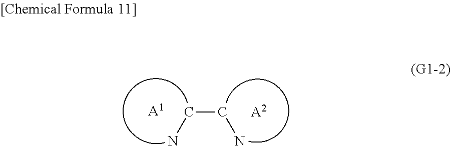

In General Formula (G1-2) above, A¹ and A² independently represent a substituted or unsubstituted heteroaromatic ring having 1 to 30 carbon atoms, Aland A² may form a condensed ring with each other, and A¹ contains two or more nitrogen atoms.

The organic compound represented by General Formula (G1-2) includes a conjugated double bond in which N in the heteroaromatic ring are arranged in the order of N—C—C—N and has a function of interacting with a metal as a bi- or higher dentate ligand. An organic compound having such a structure is likely to interact with a metal and thus can be suitably used for an electron-injection layer.

In General Formula (G1-2), examples of the substituted or unsubstituted heteroaromatic ring having 1 to 30 carbon atoms, which is represented by A¹, include a heteroaromatic ring having a diazine skeleton (a pyrazine ring, a pyrimidine ring, a pyridazine ring, a quinoxaline ring, a benzoquinoxaline ring, a dibenzoquinoxaline ring, a quinazoline ring, a benzoquinazoline ring, a phthalazine ring, a cinnoline ring, a pteridine ring, or a phenazine ring), a heteroaromatic ring having a triazine skeleton, and a heteroaromatic ring having an azole skeleton (an imidazole ring, a benzimidazole ring, a pyrazole ring, an oxazole ring, a thiazole ring, a triazole ring, an oxadiazole ring, or a thiadiazole ring). Examples of the substituted or unsubstituted heteroaromatic ring having 1 to 30 carbon atoms, which is represented by A², include a heteroaromatic ring having a pyridine skeleton (a pyridine ring, a quinoline ring, an isoquinoline ring, a naphthridine ring, a bipyridine ring, a phenanthridine ring, a phenanthroline ring, an anthyridine ring, or an azafluoranthene ring), a heteroaromatic ring having a diazine skeleton (a pyrazine ring, a pyrimidine ring, a pyridazine ring, a quinoxaline ring, a benzoquinoxaline ring, a dibenzoquinoxaline ring, a quinazoline ring, a benzoquinazoline ring, a phthalazine ring, a cinnoline ring, a pteridine ring, or a phenazine ring), a heteroaromatic ring having a triazine skeleton, and a heteroaromatic ring having an azole skeleton (an imidazole ring, a benzimidazole ring, a pyrazole ring, an oxazole ring, a thiazole ring, a triazole ring, an oxadiazole ring, or a thiadiazole ring). Note that the substituted or unsubstituted heteroaromatic rings having 1 to 30 carbon atoms represented by A¹ and A² are not limited to these. A¹ and A² may form a condensed ring with each other. For example, A¹ and A² may be bonded to each other to form a pyrazinoquinoxaline ring.

As the second organic compound, an organic compound represented by General Formula (G2-2) below can also be used.

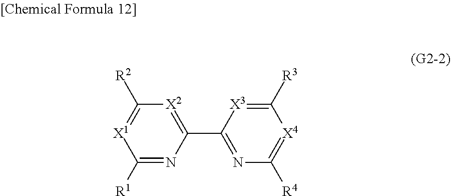

In General Formula (G2-2), at least one of X¹ to X⁴ represents nitrogen (N); the others each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms; and R¹ to R⁴ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to carbon atoms. Alternatively, in General Formula (G2-2), X¹ to X⁴ may be directly bonded to each other or bonded via carbon to form a condensed ring.

As in the organic compound represented by General Formula (G2-2), it is further preferable that the organic compound having a function of interacting with the metal as a bi-or higher dentate ligand include a heteroaromatic ring having a diazine skeleton or a heteroaromatic ring having a triazine skeleton. A light-emitting device including any of these rings can have high reliability because these rings have high electrochemical stability. Moreover, the driving voltage of the light-emitting device can be reduced because these rings have high electron-transport properties.

As the second organic compound, an organic compound represented by General Formula (G3-2) below can also be used.

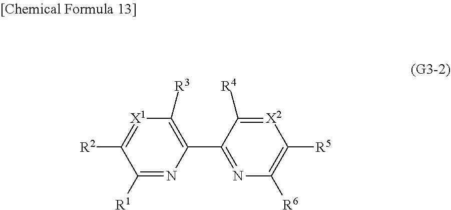

In General Formula (G3-2), one of X¹ and X² represents nitrogen (N); the other represents carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms; and R¹ to R⁶ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms.

As the second organic compound, an organic compound represented by General Formula (G4-2) below can also be used.

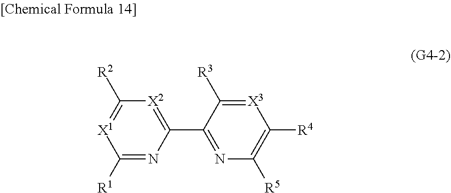

In General Formula (G4-2), at least one of X¹ to X³ represents nitrogen (N); the others each independently represent carbon (C) or nitrogen (N); carbon (C) is bonded to hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to 30 carbon atoms; and R¹ to R⁵ each independently represent hydrogen, an alkyl group having 1 to 10 carbon atoms, a substituted or unsubstituted cycloalkyl group having 3 to 10 carbon atoms, a substituted or unsubstituted aryl group having 6 to 30 carbon atoms, or a substituted or unsubstituted heteroaryl group having 1 to carbon atoms.

An organic compound having a pyridine skeleton is preferable because it has a high LUMO level. Thus, when X¹ and X² represented in General Formulae (G2-2) and (G4-2) and X¹ represented in General Formula (G3-2) represent carbon, each of the organic compounds represented by General Formulae (G2-2), (G3-2), and (G4-2), which has a pyridine skeleton, can form a composite material having a high SOMO level when interacting with a metal. That is, such an organic compound having a pyridine ring and a function of interacting with a metal as a bi- or higher dentate ligand interacts with a metal, whereby an electron-injection layer having a high electron-injection property can be formed.

An organic compound having a diazine skeleton or a triazine skeleton is preferable because it is electrochemically stable and has a high electron-transport property. Thus, when at least one of X¹ and X² represented in General Formulae (G2-2) and (G4-2) and X¹ represented in General Formula (G3-2) represent nitrogen, each of the organic compounds represented by General Formulae (G2-2), (G3-2), and (G4-2), which has a diazine skeleton or a triazine skeleton, can form a stable composite material with a high electron-transport property when interacting with a metal. That is, such an organic compound having a diazine ring or a triazine ring and a function of interacting with a metal as a bi- or higher dentate ligand interacts with a metal, whereby a highly reliable electron-injection layer can be formed.

Specific examples of the organic compounds used for the second organic compound and the organic compounds including any of heteroaromatic rings represented by General Formulae (G1-1) to (G4-2) above are shown below.

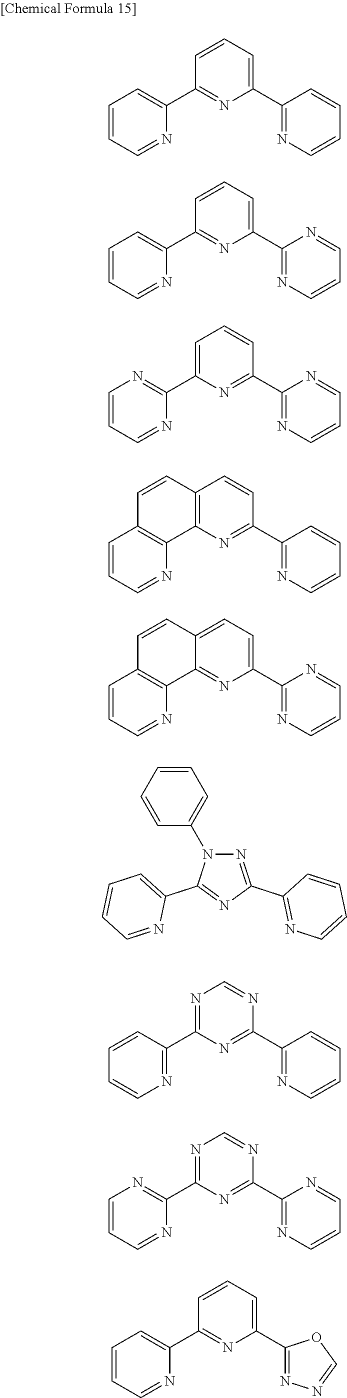

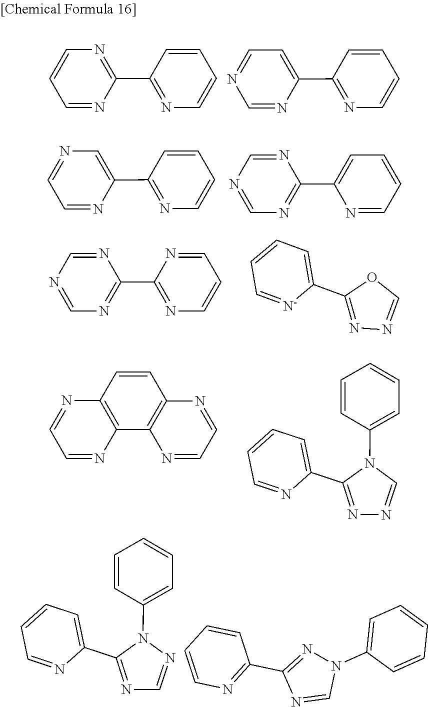

Examples of substituents that can be used in General Formulae (G1-1) to (G4-2) above include an alkyl group having 1 to 10 carbon atoms, a cycloalkyl group having 3 to 10 carbon atoms, an aryl group having 6 to 30 carbon atoms, an arylene group having 6 to 30 carbon atoms, and a heteroaryl group having 1 to 30 carbon atoms. Note that some or all of hydrogen atoms may be deuterium atoms. The groups that can be used in the above general formulae are not limited to the following specific examples.

Specific examples of the alkyl group having 1 to 10 carbon atoms include a methyl group, an ethyl group, a propyl group, an isopropyl group, a butyl group, a sec-butyl group, an isobutyl group, a tert-butyl group, a pentyl group, an isopentyl group, a sec-pentyl group, a tert-pentyl group, a neopentyl group, a hexyl group, an isohexyl group, a sec-hexyl group, a tert-hexyl group, a neohexyl group, a 3-methylpentyl group, a 2-methylpentyl group, a 2-ethylbutyl group, a 1,2-dimethylbutyl group, a 2,3-dimethylbutyl group, and a 1-ethylhexyl group.

Specific examples of a cycloalkyl group having 3 to 10 carbon atoms include a cyclopropyl group, a cyclobutyl group, a methylcyclobutyl group, a cyclopentyl group, a methylcyclopentyl group, an isopropylcyclopentyl group, a tert-butylcyclopropyl group, a cyclohexyl group, a methylcyclohexyl group, an isopropylcyclohexyl group, a tert-butylcyclohexyl group, a cycloheptyl group, a methylcycloheptyl group, an isopropylcycloheptyl group, a cyclooctyl group, a methylcyclooctyl group, an isopropylcyclohexyl group, a cyclononyl group, a methylcyclononyl group, a cyclodecyl group, and an adamantyl group.

Specific examples of the aryl group having 6 to 30 carbon atoms include a phenyl group, an o-tolyl group, an m-tolyl group, a p-tolyl group, a mesityl group, an o-biphenyl group, an m-biphenyl group, a p-biphenyl group, a 1-naphthyl group, a 2-naphthyl group, a fluorenyl group, a 9,9-dimethylfluorenyl group, a spirobifluorenyl group, a phenanthrenyl group, an anthracenyl group, and a fluoranthenyl group. In the case where the aryl group having 6 to 30 carbon atoms includes a substituent, examples of the substituent include an alkyl group having 1 to 10 carbon atoms, a cycloalkyl group having 3 to 10 carbon atoms, and a phenyl group.

Specific examples of the arylene group having 6 to 30 carbon atoms include a phenylene group, a biphenyl-diyl group, a naphthalene-diyl group, a fluorene-diyl group, an acenaphthene-diyl group, an anthracene-diyl group, a phenanthrene-diyl group, a terphenyl-diyl group, a triphenylene-diyl group, a tetracene-diyl group, a benzanthracene-diyl group, a pyrene-diyl group, and a spirobi[9H-fluorene]-diyl group. In the case where the arylene group having 6 to 30 carbon atoms includes a substituent, examples of the substituent include an alkyl group having 1 to 10 carbon atoms, a cycloalkyl group having 3 to 10 carbon atoms, and a phenyl group.

The heteroaryl group having 1 to 30 carbon atoms refers to a monovalent group obtained by eliminating one hydrogen atom from one of carbon atoms forming the ring(s) of a monocyclic or polycyclic heteroaromatic compound having 1 to 30 carbon atoms. Specific examples of the heteroaryl group having 1 to 30 carbon atoms include a 1,3,5-triazin-2-yl group, a 1,2,4-triazin-3-yl group, a pyrimidin-4-yl group, a pyrazin-2-yl group, a 2-pyridyl group, a 3-pyridyl group, a 4-pyridyl group, a carbazolyl group, a dibenzofuranyl group, a dibenzothiophenyl group, a benzonaphthofuranyl group, a benzonaphthothiophenyl group, an indolocarbazolyl group, a benzofurocarbazolyl group, a benzothienocarbazolyl group, an indenocarbazolyl group, and a dibenzocarbazolyl group. In the case where the heteroaryl group has a substituent, examples of the substituent include an alkyl group having 1 to 10 carbon atoms, a cycloalkyl group having 3 to carbon atoms, and a phenyl group.

Specific examples of the organic compounds used for the second organic compound and the organic compounds represented by General Formulae (G1-1) to (G4-2) above are shown below.

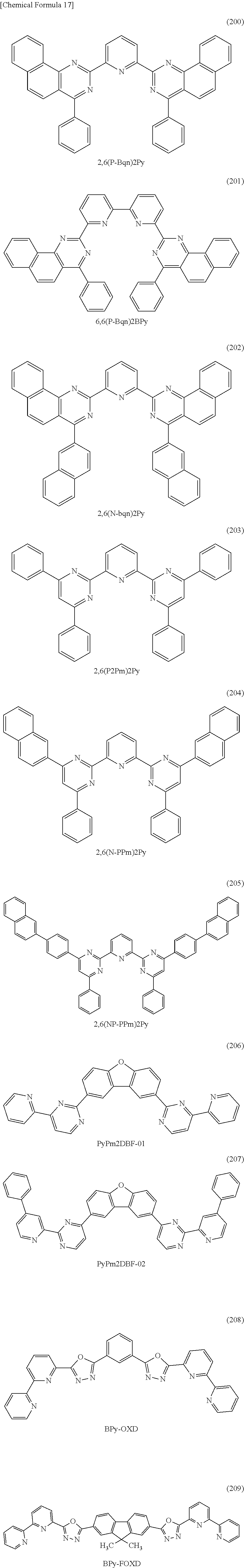

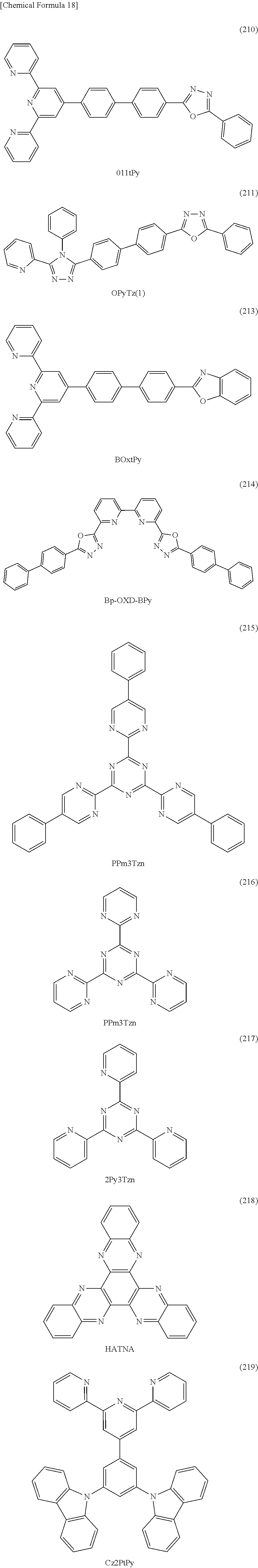

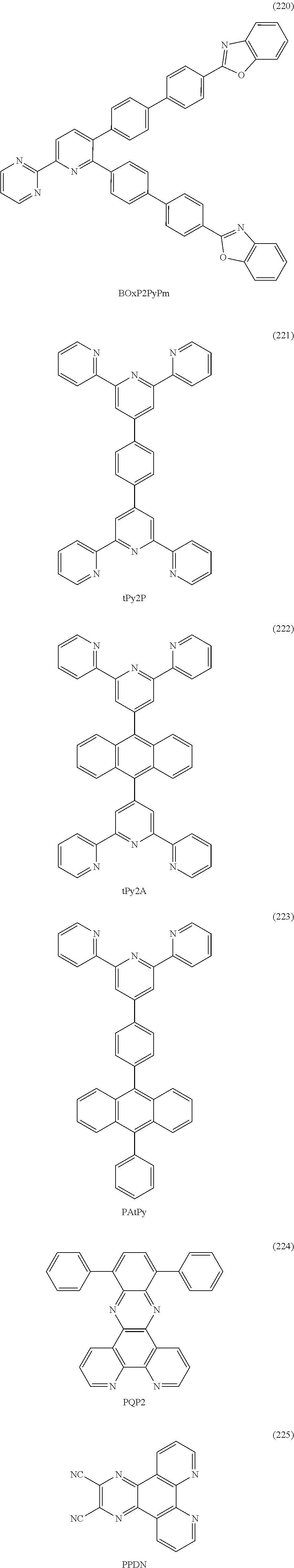

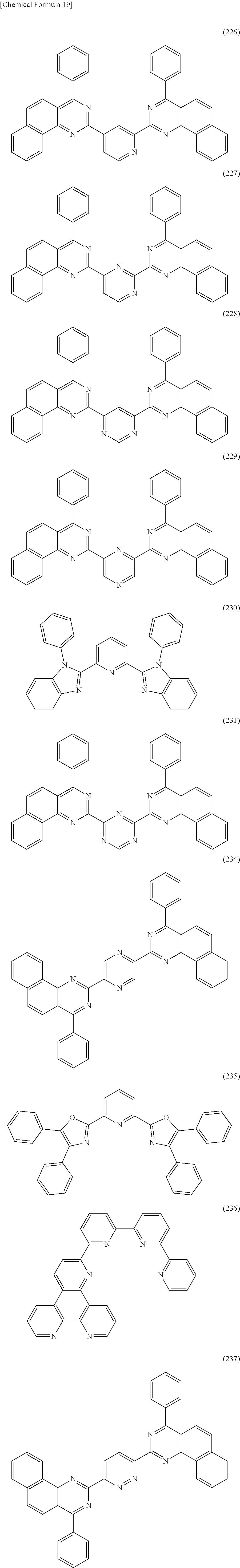

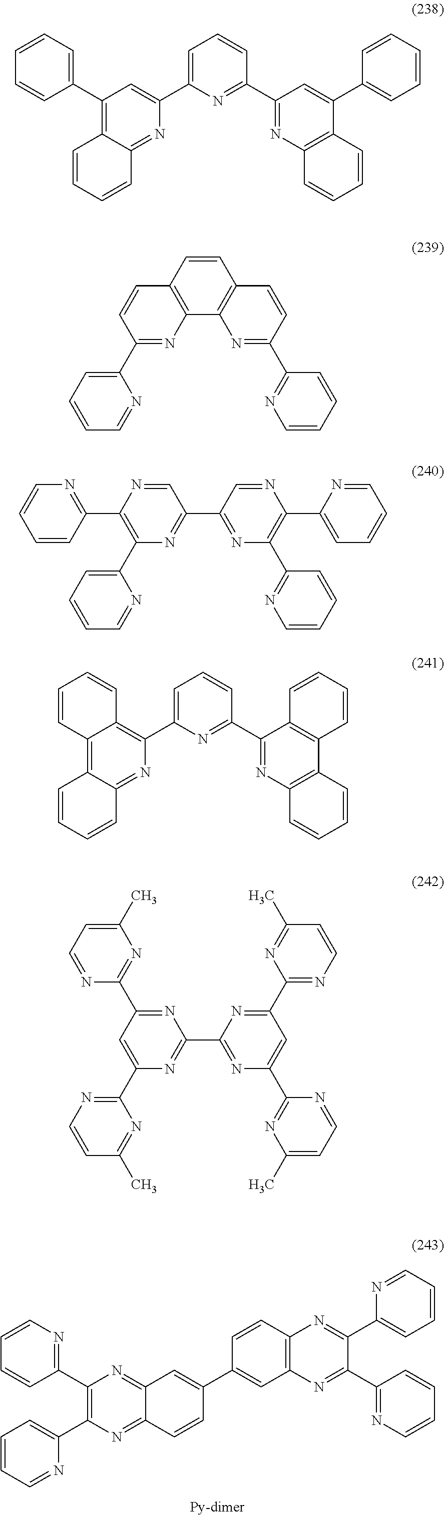

Note that the LUMO level of the second organic compound is further preferably lower than that of the first organic compound. In that case, electrons can be easily donated from the donor level formed by the first organic compound and the metal compound to the second organic compound. The LUMO level of the second organic compound is preferably lower than that of the first organic compound so that the second organic compound can have an electron-transport property.

The LUMO level of the second organic compound is preferably higher than or equal to −3.2 eV and lower than or equal to −2.0 eV, further preferably higher than or equal to −3.1 eV and lower than or equal to −2.0 eV, and still further preferably higher than or equal to −3.0 eV and lower than or equal to −2.5 eV. The LUMO level of the first organic compound is preferably higher than or equal to −3.0 eV and lower than or equal to −2.0 eV, further preferably higher than or equal to −2.7 eV and lower than or equal to −2.0 eV.

In the above case, electrons can be easily donated from the donor level formed by the first organic compound and the metal or the metal oxide to the second organic compound. This facilitates electron transport in the second organic compound.

In one embodiment of the present invention, the LUMO level of the second organic compound is preferably lower than that of the first organic compound by greater than or equal to 0.20 eV and less than or equal to 0.60 eV, preferably 0.50 eV, further preferably by greater than or equal to 0.25 eV and less than or equal to 0.50 eV, still further preferably by greater than or equal to 0.30 eV and less than or equal to 0.50 eV, yet further preferably by greater than or equal to 0.35 eV and less than or equal to 0.50 eV, and yet still further preferably by greater than or equal to 0.40 eV and less than or equal to 0.50 eV.

In other words, when the LUMO level of the first organic compound is “LUMO1 (eV)” and the LUMO level of the second organic compound is “LUMO2 (eV)”, LUMO2 preferably satisfies the following formula.

$$LUMO 1 - 0.50 \leq LUMO 2 \leq LUMO 1 - 0.2$$

Further preferably, LUMO2 satisfies the following formula.

$$LUMO 1 - 0.50 \leq LUMO 2 \leq LUMO 1 - 0.25$$

Still further preferably, LUMO2 satisfies the following formula.

$$LUMO 1 - 0.50 \leq LUMO 2 \leq LUMO 1 - 0.30$$

Yet still further preferably, LUMO2 satisfies the following formula.

$$LUMO 1 - 0.50 \leq LUMO 2 \leq LUMO 1 - 0.35$$

Yet still further preferably, LUMO2 satisfies the following formula.

$$LUMO 1 - 0.50 \leq LUMO 2 \leq LUMO 1 - 0.4$$

When the LUMO2 is in the above range, the light-emitting device of one embodiment of the present invention can have favorable characteristics with low driving voltage, with or without undergoing a photolithography process involving exposure of the EL layer to the air. In addition, the light-emitting device can have high reliability.

As the second organic compound, an organic compound with an electron-transport property can be used. The organic compound with an electron-transport property is preferably a substance having an electron mobility higher than or equal to 1×10⁻⁷ cm²/Vs, further preferably higher than or equal to 1×10⁻⁶ cm²/Vs, when the square root of electric field strength [V/cm] is 600. Note that any other substance can also be used as long as the substance has an electron-transport property higher than a hole-transport property.

The second organic compound preferably has 25 to 100 carbon atoms. When having to 100 carbon atoms, the second organic compound can have excellent sublimability, and thus, thermal decomposition of the organic compound during vacuum evaporation can be inhibited and the efficiency of use of the material can be high.

An organic compound having a glass transition temperature T_{g} higher than or equal to 100° C. is preferably used as the second organic compound. In that case, the electron-injection layer can be a layer that has high heat resistance and is not easily crystallized. Thus, the electron-injection layer is not easily crystallized even when part of the organic compound layer is processed by a lithography process.

As the second organic compound, an organic compound with an acid dissociation constant pKₐ lower than 4 can be used. Accordingly, the second organic compound can have low solubility in water and thus can be highly resistant to water and a chemical solution used in a lithography process.

An organic compound having an acid dissociation constant pKₐ smaller than 4 has lower solubility in water than an organic compound having an acid dissociation constant pKₐ larger than or equal to 4. The water resistance of the electron-injection layer including an organic compound having an acid dissociation constant pKₐ smaller than 4 as the second organic compound can be higher than that of the electro-injection layer including an organic compound having an acid dissociation constant pKₐ larger than or equal to 4 as the second organic compound. Moreover, occurrence of a problem such as peeling of the electron-injection layer from another layer in the fabrication process can be inhibited. Accordingly, occurrence of a problem that causes a defect in a light-emitting device can be inhibited.

In the case where the acid dissociation constant pKₐ of an organic compound is unknown, the acid dissociation constants pKₐ of skeletons in the organic compound are calculated and the largest acid dissociation constant pKₐ can be regarded as the acid dissociation constant pKₐ of the organic compound.

When the first layer includes the second organic compound in addition to the metal or the metal compound and the first organic compound, interaction between materials occurs efficiently. This can be confirmed by measurement of spin density by electron spin resonance (ESR).

For example, the spin density measured by ESR of a film that includes the metal or the metal compound and the first organic compound is preferably higher than that of a film that includes the metal or the metal compound and the second organic compound. The spin density measured by ESR of a film that includes the metal or the metal compound, the first organic compound, and the second organic compound is preferably higher than that of a film that includes any two of the metal or the metal compound, the first organic compound, and the second organic compound. In that case, interaction between the materials can be confirmed to occur efficiently.

Specifically, for example, by an electron spin resonance method, the density of spins attributed to a signal observed at a g-factor of approximately 2.00 in the film including the metal or the metal compound and the first organic compound is higher than or equal to 5×10¹⁶ spins/cm³, preferably higher than or equal to 1×10¹⁷ spins/cm³, further preferably higher than or equal to 1×10¹⁸ spins/cm³, still further preferably higher than or equal to 1×10¹⁹ spins/cm³, and yet still further preferably higher than or equal to 1×10²⁰ spins/cm³. In such a case, in the layer that includes a combination of the metal or the metal compound and the first organic compound, it can be confirmed that the interaction between the materials occurs efficiently. In addition, for example, in an electron spin resonance method, the density of spins attributed to a signal observed at a g-factor of approximately 2.00 in the film including the metal or the metal compound, the first organic compound, and the second organic compound is higher than or equal to 5×10¹⁶ spins/cm³, preferably higher than or equal to 1×10¹⁷ spins/cm³, further preferably higher than or equal to 1×10¹⁸ spins/cm³, still further preferably higher than or equal to 1×10¹⁹ spins/cm³, and yet still further preferably higher than or equal to 1×10²⁰ spins/cm³. In such a case, in the layer that includes the combination of the metal or the metal compound, the first organic compound, and the second organic compound, it can be confirmed that the interaction between the materials occurs more efficiently than in the layer that includes only two of the metal or the metal compound, the first organic compound, and the second organic compound. The density of spins attributed to a signal observed at a g-factor of approximately 2.00 is measured by an electron spin resonance method to be, for example, lower than or equal to 2×10¹⁶ spins/cm³ in a mixed film that includes the metal or the metal compound and the second organic compound. The density of spins attributed to a signal observed at a g-factor of approximately 2.00 is measured by an electron spin resonance method to be, for example, lower than or equal to 2×10¹⁶ spins/cm³ in a mixed film that includes the first organic compound and the second organic compound.

In the first layer, the molar ratio of the metal or the metal compound oxide to the first organic compound (or the sum of the first organic compound and the second organic compound) is preferably greater than or equal to 0.1 and less than or equal to 10, further preferably greater than or equal to 0.2 and less than or equal to 5, still further preferably greater than or equal to 0.5 and less than or equal to 2. Alternatively, the volume ratio of the metal or the metal compound to the first organic compound (or the sum of the first organic compound and the second organic compound) is preferably greater than or equal to 0.01 and less than or equal to 0.3, further preferably greater than or equal to 0.02 and less than or equal to 0.2, still further preferably greater than or equal to 0.05 and less than or equal to 0.1. The first layer including the metal or metal oxide and the first organic compound (or the first organic compound and the second organic compound) in such a ratio enables providing the electron-injection layer having a high electron-injection property. Although the second organic compound is not necessarily used, the volume ratio of the first organic compound to the second organic compound is preferably greater than or equal to 0.1 and less than or equal to 10, further preferably greater than or equal to 0.2 and less than or equal to 5, still further preferably greater than or equal to 0.5 and less than or equal to 2. Mixing the first organic compound and the second organic compound in such a ratio enables providing the electron-injection layer having a high electron-transport property. When an organic compound with favorable thermophysical properties with high T_{g} is used as the second organic compound, highly reliable organic EL device can be provided.

The thickness of the first layer is preferably greater than or equal to 2 nm and less than or equal to 20 nm, further preferably greater than or equal to 5 nm and less than or equal to 10 nm.

In the case where the first layer has a stacked-layer structure of a metal or a metal compound layer and a layer containing the first organic compound, the thickness of the metal or the metal compound layer is preferably greater than or equal to 0.1 nm and less than or equal to 5 nm, further preferably greater than or equal to 0.2 nm and less than or equal to 2 nm. In the case where the first layer has a stacked-layer structure of a metal or metal oxide layer and a layer containing the first organic compound, the thickness of the layer containing the first organic compound is preferably greater than or equal to 2 nm and less than or equal to 20 nm, further preferably greater than or equal to 5 nm and less than or equal to 10 nm.

The use of the second organic compound enables the composite material in which the metal or metal oxide, the first organic compound, and the second organic compound are mixed to favorably function, resulting in high emission efficiency of the light-emitting device.

### <Second Electrode>

The second electrode is an electrode that is opposite to the first electrode, and the light-emitting device includes a first electrode formed earlier, a second electrode, and an organic compound layer positioned between the first electrode and the second electrode. It is preferable that the organic compound layer include a light-emitting layer and an electron-injection layer, the electron-injection layer be positioned between the light-emitting layer and the second electrode, and the electron-injection layer and the second electrode be in contact with each other.

For the second electrode, a conductive metal oxide, such as indium oxide-tin oxide (ITO: indium tin oxide), indium oxide-tin oxide containing silicon or silicon oxide (ITSO: indium tin silicon oxide), indium oxide-zinc oxide, indium oxide containing tungsten oxide and zinc oxide (IWZO), is preferably used. Alternatively, for example, a metal material, such as gold (Au), platinum (Pt), nickel (Ni), tungsten (W), chromium (Cr), molybdenum (Mo), iron (Fe), cobalt (Co), copper (Cu), palladium (Pd), titanium (Ti), aluminum (Al), yttrium (Y), zirconium (Zr), tantalum (Ta), silver (Ag), or magnesium (Mg), or an alloy material containing any of the metal materials can be used. Alternatively, a nitride of a metal material (e.g., titanium nitride) can be used. These materials are less likely to deteriorate in a photolithography process; thus, a light-emitting device with favorable characteristics can be obtained even when fabricated through a photolithography process.

Note that when the second electrode has a light-transmitting property, a top-emission light-emitting device that emits light from the second electrode side can be obtained. In the case of a bottom-emission light-emitting device, the second electrode preferably has high visible light reflectance (40% to 100%, preferably 70% to 100%).

Some of these materials are difficult to use for a cathode in general because of their high work functions. However, in one embodiment of the present invention, the use of the second electrode and the electron-injection layer having the above structure can provide a light-emitting device with favorable characteristics.

The electron-injection layer includes metal or the metal compound, the first organic compound, and the second organic compound; the second organic compound includes two or more heteroaromatic rings which are bonded or condensed to each other; the two or more heteroaromatic rings includes three or more heteroatoms in total. With use of the electron-injection layer for the organic EL device of one embodiment of the present invention, the organic EL device can have favorable characteristics even when the organic compound layer is exposed to the air after the formation of the second electrode. That is, the use of the structure of one embodiment of the present invention offers an organic EL device with favorable characteristics, which is manufactured through a photolithography process involving exposure of the organic compound layer to the air. Specifically, an electron-injection layer that has resistance to oxygen and water in the air and water and a chemical solution used in the process by a lithography method can be formed. Thus, one embodiment of the present invention can provide a light-emitting device having high moisture resistance, high water resistance, high oxygen resistance, high chemical resistance, a low driving voltage, and high emission efficiency.

Thus, a display device with extremely high resolution and favorable characteristics can be provided.

One embodiment of the present invention, which is particularly suitable for a light-emitting device manufactured using a photolithography step, also contributes to cost reduction in a light-emitting device manufactured without using a photolithography step since one embodiment of the present invention enables the light-emitting device to be stable toward the air and accordingly have increased yield and eliminates the need for strict control of an atmosphere during a manufacturing process.

### Embodiment 2

In this embodiment, light-emitting devices of one embodiment of the present invention will be described in detail.

FIG. 1A is a schematic diagram of the light-emitting device of one embodiment of the present invention. The light-emitting device includes a first electrode 101 over an insulator 1000, and an organic compound layer 103 between the first electrode 101 and a second electrode 102. The organic compound layer 103 includes at least a light-emitting layer 113 and an electron-injection layer 115. The light-emitting layer 113 contains a light-emitting substance and the light-emitting device of one embodiment of the present invention emits light when voltage is applied between the first electrode 101 and the second electrode 102.

The organic compound layer 103 preferably includes, besides the light-emitting layer 113 and the electron-injection layer 115, functional layers such as the hole-injection layer 111, the hole-transport layer 112, and the electron-transport layer 114, as illustrated in FIG. 1A. The organic compound layer 103 may include functional layers other than the above functional layers, such as a hole-blocking layer, an exciton-blocking layer, and an intermediate layer. Alternatively, any of the above-described layers may be omitted.

As described in Embodiment 1, the electron-injection layer 115 includes the second organic compound having two or more heteroaromatic rings that are bonded or condensed to each other and include three or more heteroatoms in total, in addition to the metal or the metal compound and the first organic compound. The specific structure of the electron-injection layer 115 is described in detail in Embodiment 1; thus, repetitive description thereof is omitted.

The first electrode 101 and the second electrode 102 may each have a single-layer structure or a stacked-layer structure.

In the light-emitting device of one embodiment of the present invention, processing by a photolithography method is performed after the second electrode 102 is formed; thus, the light-emitting device has a feature that an end portion of the second electrode 102 in the cross section and an end portion of the organic compound layer 103 in the cross section are aligned in a direction substantially perpendicular to the surface of the insulator 1000 as illustrated in FIG. 1A. An end portion of the second electrode and an end portion of the organic compound layer may be positioned inward from an end portion of the first electrode as illustrated in FIGS. 1A and 1B, or may be positioned outward from the first electrode as illustrated in FIG. 1C.

The first electrode 101 is preferably formed using any of metals, alloys, and conductive compounds with a high work function (specifically, higher than or equal to 4.0 eV), mixtures thereof, and the like. Specific examples include indium oxide-tin oxide (ITO: indium tin oxide), indium oxide-tin oxide containing silicon or silicon oxide (ITSO: indium tin silicon oxide), indium oxide-zinc oxide, and indium oxide containing tungsten oxide and zinc oxide (IWZO). Films of such conductive metal oxides are usually formed by a sputtering method, but may be formed by application of a sol-gel method or the like. For example, a film of indium oxide-zinc oxide is formed by a sputtering method using a target in which 1 wt % to 20 wt % zinc oxide is added to indium oxide. Furthermore, a film of indium oxide containing tungsten oxide and zinc oxide (IWZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), titanium (Ti), aluminum (Al), nitride of a metal material (e.g., titanium nitride), or the like can be used for the first electrode 101. The first electrode 101 may be a stack of layers formed using any of these materials. For example, a film in which Al, Ti, and ITSO are stacked in this order over Ti is preferable because the film has high efficiency owing to high reflectivity and enables a high resolution of several thousand ppi. Graphene can also be used for the first electrode 101. When a composite material that can be included in the hole-injection layer 111 described later is used for a layer (typically, the hole-injection layer) in contact with the first electrode 101, an electrode material can be selected regardless of its work function.

The hole-injection layer 111 is provided in contact with the first electrode 101 and has a function of facilitating injection of holes into the organic compound layer 103. The hole-injection layer 111 can be formed using a phthalocyanine-based compound or complex compound such as phthalocyanine (abbreviation: H₂Pc) or copper phthalocyanine (abbreviation: CuPc), an aromatic amine compound such as 4,4′-bis[N-(4-diphenylaminophenyl)-N-phenylamino]biphenyl (abbreviation: DPAB) or 4,4′-bis(N-{4-[N-(3-methylphenyl)-N′-phenylamino]phenyl}-N-phenylamino) biphenyl (abbreviation: DNTPD), or a high molecular compound such as poly(3,4-ethylenedioxythiophene)/poly(styrenesulfonic acid) (abbreviation: PEDOT/PSS).

The hole-injection layer 111 may be formed using a substance with an electron-accepting property. Examples of the substance with an acceptor property include organic compounds having an electron-withdrawing group (a halogen group or a cyano group), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylene-1,3,4,5,6,8,9,10-octafluoro-7H-pyren-2-ylidene) malononitrile. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance with an acceptor property, specifically, a transition metal oxide such as molybdenum oxide, vanadium oxide, ruthenium oxide, tungsten oxide, or manganese oxide can be used, other than the above-described organic compounds.

The hole-injection layer 111 is preferably formed using a composite material containing any of the aforementioned materials having an acceptor property and an organic compound having a hole-transport property.

As the organic compound having a hole-transport property that is used in the composite material, any of a variety of organic compounds such as aromatic amine compounds, heteroaromatic compounds, aromatic hydrocarbons, and high molecular compounds (e.g., oligomers, dendrimers, and polymers) can be used. Note that the organic compound having a hole-transport property that is used in the composite material preferably has a hole mobility higher than or equal to 1×10⁻⁶ cm²/Vs. The organic compound having a hole-transport property that is used in the composite material preferably has a condensed aromatic hydrocarbon ring or a T-electron rich heteroaromatic ring. As the condensed aromatic hydrocarbon ring, an anthracene ring, a naphthalene ring, or the like is preferable. As the π-electron rich heteroaromatic ring, a condensed aromatic ring having at least one of a pyrrole skeleton, a furan skeleton, and a thiophene skeleton is preferable; specifically, a carbazole ring, a dibenzothiophene ring, or a ring in which an aromatic ring or a heteroaromatic ring is further condensed to the carbazole ring or the dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine including a substituent that has a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the organic compound having a hole-transport property preferably has an N,N-bis(4-biphenyl)amino group to enable fabricating a light-emitting device having a long lifetime.

Specific examples of the organic compound having a hole-transport property include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf (6)), N,N-bis(4-biphenyl)benzo[b]naphtho[1,2-d]furan-8-amine (abbreviation: BBABnf (8)), N,N-bis(4-biphenyl)benzo[b]naphtho[2,3-d]furan-4-amine (abbreviation: BBABnf (II) (4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-BnfBB1BP), N,N-bis(4-biphenyl)benzo[b]naphtho[1,2-d]furan-6-amine BBABnf (6)), N,N-bis(4-biphenyl)benzo[b]naphtho[1,2-d]furan-8-amine BBABnf (8)), N,N-bis(4-biphenyl)benzo[b]naphtho[2,3-d]furan-4-amine 2-yl)triphenylamine (abbreviation: BBAαNβNB-03), 4,4′-diphenyl-4″-(7-phenyl) naphthyl-2-yltriphenylamine (abbreviation: BBAPβNB-03), 4,4′-diphenyl-4″-(6;2′-binaphthyl-2-yl)triphenylamine (abbreviation: BBA (BN2) B), 4,4′-diphenyl-4″-(7;2′-binaphthyl-2-(abbreviation: BBA (BN2) B-03), 4,4′-diphenyl-4″-(4;2′-binaphthyl-1-yl)triphenylamine yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiABNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl) biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl) biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF (4)), N-(biphenyl-2-yl)-N-(9,9-dimethyl-9H-fluoren-2-yl)-9,9′-spirobi[9H-fluoren]-4-amine (abbreviation: OFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

Examples of the aromatic amine compounds that can be used as the material with a hole-transport property include N,N-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N′-phenylamino]phenyl}-N-phenylamino) biphenyl (abbreviation: DNTPD), and 1,3,5-tris[N-(4-diphenylaminophenyl)-N-phenylamino]benzene (abbreviation: DPA3B).

The formation of the hole-injection layer 111 can improve the hole-injection property, which allows the light-emitting device to be driven at a low voltage.

Among substances with an acceptor property, the organic compound with an acceptor property is easy to use because it is easily deposited by evaporation.

The hole-transport layer 112 is formed using an organic compound having a hole-transport property. The organic compound having a hole-transport property preferably has a hole mobility of 1×10⁻⁶ cm²/Vs or higher.

Examples of the aforementioned organic compound with a hole-transport property include the following compounds: compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine PCBANB), 4,4′-di(1-naphthyl)-4″-(9-phenyl-9H-carbazol-3-yl)triphenylamine (abbreviation: (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl) biphenyl (abbreviation: CBP), 3,6-bis(3,5-diphenylphenyl)-9-phenylcarbazole (abbreviation: CzTP), 9,9′-diphenyl-9H,9′H-3,3′-bicarbazole (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-3,3′-bi-9H-carbazole (abbreviation: βNCCP), 9-(3-biphenyl)-9′-(2-naphthyl)-3,3′-bi-9H-carbazole (abbreviation: βNCCmBP), 9-(4-biphenyl)-9′-(2-naphthyl)-3,3′-bi-9H-carbazole (abbreviation: βNCCBP), 9,9′-di-2-naphthyl-3,3′-9H,9′H-bicarbazole (abbreviation: BisβNCz), 9-(2-naphthyl)-9′-[1,1′: 4′,1″-terphenyl]-3-yl-3,3′-9H,9′H-bicarbazole, 9-(2-naphthyl)-9′-[1,1′: 3′,1″-terphenyl]-3-yl-3,3′-9H,9′H-bicarbazole, 9-(2-naphthyl)-9′-[1,1′: 3′,1″-terphenyl]-5′-yl-3,3′-9H,9′H-bicarbazole, 9-(2-naphthyl)-9′-[1,1′: 4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, and 9-(triphenylen-2-yl)-9′-[1,1′: 3′,1″-terphenyl]-4-yl-3,3′-9H,9′H-bicarbazole; compounds having a thiophene skeleton, such as 4,4′,4″-(benzene-1,3,5-triyl)tri (dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri (dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton or the compound having a carbazole skeleton is preferable because the compound is highly reliable and has a high hole-transport property to contribute to a reduction in driving voltage. Note that any of the substances given as examples of the material having a hole-transport property that is used for the composite material for the hole-injection layer 111 can also be suitably used as the material contained in the hole-transport layer 112.

The light-emitting layer 113 is a layer containing a light-emitting substance and preferably contains a light-emitting substance and a host material. The light-emitting layer may additionally contain another material. Alternatively, the light-emitting layer 113 may be a stack of two or more layers with different compositions.

As the light-emitting substance, fluorescent substances, phosphorescent substances, substances exhibiting thermally activated delayed fluorescence (TADF), or other light-emitting substances may be used.

Examples of the material that can be used as a fluorescent substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl) biphenyl-4-yl]-2,2′-bipyridine (abbreviation: PAPP2BPy), N,N′-diphenyl-N,N′-bis[4-(9-phenyl-9H-fluoren-9-yl)phenyl]pyrene-1,6-diamine (abbreviation: 1,6FLPAPrn), N,N′-bis(3-methylphenyl)-N,N′-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N″-(2-tert-butylanthracene-9,10-diyldi-4,1-phenylene)bis(N,N′,N′-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N′,N″,N″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(biphenyl-2-yl)-2-anthryl]-N,N′,N′-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene) propanedinitrile (abbreviation: DCM1), 2-{2-methyl-6-[2-(2,3,6,7-tetrahydro-1H,5H-benzo[ij]quinolizin-9-yl) ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl) acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl) ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl) ethenyl]-4H-pyran-4-ylidene}propanedinitrile (abbreviation: DCJTB), 2-(2,6-bis {2-[4-(dimethylamino)phenyl]ethenyl}-4H-pyran-4-ylidene) propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl) ethenyl]-4H-pyran-4-ylidene}propanedinitrile (abbreviation: BisDCJTM), N,N′-diphenyl-N,N′-(1,6-pyrene-diyl)bis[(6-phenylbenzo[b]naphtho[1,2-d]furan)-8-amine] (abbreviation: 1,6BnfAPrn-03), N,N-diphenyl-N,N′-bis(9-phenyl-9H-carbazol-2-yl) naphtho[2,3-b;6,7-b′]bisbenzofuran-3,10-diamine (abbreviation: 3,10PCA2Nbf (IV)-02), and 3,10-bis[N-(dibenzofuran-3-yl)-N-phenylamino]naphtho[2,3-b;6,7-b′]bisbenzofuran (abbreviation: 3,10FrA2Nbf (IV)-02). Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

A condensed heteroaromatic compound containing nitrogen and boron, especially a compound having a diaza-boranaphtho-anthracene skeleton, exhibits a narrow emission spectrum, emits blue light with high color purity, and can thus be used suitably. Examples of the compound include 5,9-diphenyl-5,9-diaza-13b-boranaphtho[3,2,1-de]anthracene (abbreviation: DABNA1), 9-(biphenyl-3-yl)-N,N,5,11-tetraphenyl-5H,9H-[1,4]benzazaborino[2,3,4-kl]phenazaborin-3-amine (abbreviation: DABNA2), 2,12-di(tert-butyl)-5,9-di(4-tert-butylphenyl)-N,N-diphenyl-5H,9H-[1,4]benzazaborino[2,3,4-k/]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H[1,4]benzazaborino[2,3,4-k/]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-kl][1,4]benzazaborino[4′,3′,2′: 4,5][1,4]benzazaborino[3,2-b]phenazaborine-7,13-diamine (abbreviation: v-DABNA), and 2-(4-tert-butylphenyl)benz[5,6]indolo[3,2,1-jk]benzo[b]carbazole (abbreviation: tBuPBibc).

Besides the above compounds, 9,10,11-tris[3,6-bis(1,1-dimethylethyl)-9H-carbazolyl-9-yl]-2,5,15,18-tetrakis(1,1-dimethylethyl) indolo[3,2,1-de]indolo[3′,2′,1′: 8,1][1,4]benzazaborino[2,3,4-kl]phenazaborine (abbreviation: BBCz-G), 9,11-bis[3,6-bis(1,1-dimethylethyl)-9H-carbazolyl-9-yl]-2,5,15,18-tetrakis(1,1-dimethylethyl) indolo[3,2,1-de]indolo[3′,2′,1′: 8,1][1,4]benzazaborino[2,3,4-k/]phenazaborine (abbreviation: BBCz-Y), or the like can be suitably used.

Examples of the material that can be used when a phosphorescent substance is used as the light-emitting substance in the light-emitting layer are as follows.

The examples include organometallic iridium complexes having a 4H-triazole skeleton, such as tris {2-[5-(2-methylphenyl)-4-(2,6-dimethylphenyl)-4H-1,2,4-triazol-3-yl-κN²]phenyl-κC}iridium (III) (abbreviation: [Ir(mpptz-dmp)₃]) and tris(5-methyl-3,4-diphenyl-4H-1,2,4-triazolato) iridium (III) (abbreviation: [Ir(Mptz)₃]); organometallic iridium complexes having a 1H-skeleton, such as tris[3-methyl-1-(2-methylphenyl)-5-phenyl-1H-1,2,4-triazole triazolato]iridium (III) (abbreviation: [Ir(Mptz1-mp)₃]) and tris(1-methyl-5-phenyl-3-propyl-1H-1,2,4-triazolato) iridium (III) (abbreviation: [Ir(Prptz1-Me)₃]); organometallic iridium complexes having an imidazole skeleton, such as fac-tris[1-(2,6-diisopropylphenyl)-2-phenyl-1H-imidazoleJiridium (III) (abbreviation: [Ir(iPrpim)₃]), tris[3-(2,6-dimethylphenyl)-7-methylimidazo[1,2-f]phenanthridinato]iridium (III) (abbreviation: [Ir(dmpimpt-Me)₃]), and tris(2-{1-[2,6-bis(1-methylethyl)phenyl]-1H-imidazol-2-yl-κN³}-4-cyanophenyl-κC) (abbreviation: CNImIr); organometallic complexes having a benzimizazolidene skeleton, such as tris[(6-tert-butyl-3-phenyl-2H-imidazo[4,5-b]pyrazin-1-yl-κC²)phenyl-C]iridium (III) (abbreviation: [Ir(cb)₃]); and organometallic iridium complexes in which a phenylpyridine derivative having an electron-withdrawing group is a ligand, such as bis[2-(4′,6′-difluorophenyl)pyridinato-N,C^{2′}]iridium(III)tetrakis(1-pyrazolyl)borate (abbreviation: FIr6), bis[2-(4′,6′-difluorophenyl)pyridinato-N,C^{2′}]iridium (III) picolinate (abbreviation: FIrpic), bis {2-[3′,5′-bis(trifluoromethyl)phenyl]pyridinato-N,C^{2′}}iridium (III) picolinate (abbreviation: [Ir(CF₃ppy)₂(pic)]), and bis[2-(4′,6′-difluorophenyl)pyridinato-N,C^{2′}]iridium (III) acetylacetonate (abbreviation: FIracac). These compounds emit blue phosphorescent light and have an emission peak in the wavelength range of 450 nm to 520 nm.

Other examples include organometallic iridium complexes having a pyrimidine skeleton, such as tris(4-methyl-6-phenylpyrimidinato) iridium (III) (abbreviation: [Ir(mppm)₃]), tris(4-t-butyl-6-phenylpyrimidinato) iridium (III) (abbreviation: [Ir(tBuppm)₃]), (acetylacetonato)bis(6-methyl-4-phenylpyrimidinato) iridium (III) (abbreviation: [Ir(mppm)₂(acac)]), (acetylacetonato)bis(6-tert-butyl-4-phenylpyrimidinato) iridium (III) (abbreviation: [Ir(tBuppm)₂(acac)]), (acetylacetonato)bis[6-(2-norbornyl)-4-phenylpyrimidinato]iridium (III) (abbreviation: [Ir(nbppm)₂(acac)]), (acetylacetonato)bis[5-methyl-6-(2-methylphenyl)-4-phenylpyrimidinato]iridium (III) (abbreviation: [Ir(mpmppm)₂(acac)]), and (acetylacetonato)bis(4,6-diphenylpyrimidinato) iridium (III) (abbreviation: [Ir(dppm)₂(acac)]); organometallic iridium complexes having a pyrazine skeleton, such as (acetylacetonato)bis(3,5-dimethyl-2-phenylpyrazinato) iridium (III) (abbreviation: [Ir(mppr-Me)₂(acac)]) and (acetylacetonato)bis(5-isopropyl-3-methyl-2-phenylpyrazinato) iridium (III) (abbreviation: [Ir(mppr-iPr)₂(acac)]); organometallic iridium complexes having a pyridine skeleton, such as tris(2-phenylpyridinato-N,C^{2′}) iridium (III) (abbreviation: [Ir(ppy)₃]), bis(2-phenylpyridinato-N,C^{2′}) iridium (III) acetylacetonate (abbreviation: [Ir(ppy)₂(acac)]), bis(benzo[h]quinolinato) iridium (III) acetylacetonate (abbreviation: [Ir(bzq)₂(acac)]), tris(benzo[h]quinolinato) iridium (III) (abbreviation: [Ir(bzq)₃]), tris(2-phenylquinolinato-N,C^{2′}) iridium (III) (abbreviation: [Ir(pq)₃]), bis(2-phenylquinolinato-N,C^{2′}) iridium (III) acetylacetonate (abbreviation: [Ir(pq)₂(acac)]), [2-d3-methyl-8-(2-pyridinyl-κN)benzofuro[2,3-b]pyridine-κC]bis[2-(5-d3-methyl-2-pyridinyl-κN²)phenyl-κC]iridium (III) (abbreviation: Ir (5mppy-d₃)₂(mbfpypy-d₃)), [2-d₃-methyl-(2-pyridinyl-κN)benzofuro[2,3-b]pyridine-κC]bis[2-(2-pyridinyl-κN)phenyl-κC]iridium (III) (abbreviation: [Ir(ppy)₂(mbfpypy-d₃)]), [2-(4-d₃-methyl-5-phenyl-2-pyridinyl-κN²)phenyl-κC]bis[2-(5-d₃-methyl-2-pyridinyl-κN²)phenyl-κC]iridium (III) (abbreviation: [Ir(5mppy-d₃)₂(mdppy-d₃)]), [2-methyl-(2-pyridinyl-κN)benzofuro[2,3-b]pyridine-KC]bis[2-(2-pyridinyl-κN)phenyl-κC]iridium (III) (abbreviation: [Ir(ppy)₂(mbfpypy)]), and [2-(4-methyl-5-phenyl-2-pyridinyl-κN)phenyl-κC]bis[2-(2-pyridinyl-κN)phenyl-κC]iridium (III) (abbreviation: [Ir(ppy)₂(mdppy)]); and a rare earth metal complex such as tris(acetylacetonato) (monophenanthroline) terbium (III) (abbreviation: [Tb(acac)₃(Phen)]). These compounds mainly emit green phosphorescent light and have an emission peak in the wavelength range of 500 nm to 600 nm. Note that organometallic iridium complexes having a pyrimidine skeleton have distinctively high reliability or emission efficiency and thus are particularly preferable.

Other examples include organometallic iridium complexes having a pyrimidine skeleton, such as (diisobutyrylmethanato)bis[4,6-bis(3-methylphenyl)pyrimidinato]iridium (III) (abbreviation: [Ir(5mdppm)₂(dibm)]), bis[4,6-bis(3-methylphenyl)pyrimidinato](dipivaloylmethanato) iridium (III) (abbreviation: [Ir(5mdppm)₂(dpm)]), and bis[4,6-di(naphthalen-1-yl)pyrimidinato](dipivaloylmethanato) iridium (III) (abbreviation: [Ir(dlnpm)₂(dpm)]); organometallic iridium complexes having a pyrazine skeleton, such as (acetylacetonato)bis(2,3,5-triphenylpyrazinato) iridium (III) (abbreviation: [Ir(tppr)₂(acac)]), bis(2,3,5-triphenylpyrazinato) (dipivaloylmethanato) iridium (III) (abbreviation: [Ir(tppr)₂(dpm)]), and (acetylacetonato)bis[2,3-bis(4-fluorophenyl) quinoxalinato]iridium (III) (abbreviation: [Ir(Fdpq)₂(acac)]); organometallic iridium complexes having a pyridine skeleton, such as tris(1-phenylisoquinolinato-N,C^{2′}) iridium (III) (abbreviation: [Ir(piq)₃]), bis(1-phenylisoquinolinato-N,C^{2′}) iridium (III) acetylacetonate (abbreviation: [Ir(piq)₂(acac)]), (3,7-diethyl-4,6-nonanedionato-κO⁴,κO⁶)bis[2,4-dimethyl-6-[7-(1-methylethyl)-1-isoquinolinyl-κN]phenyl-C]iridium (III), and (3,7-diethyl-4,6-nonanedionato-κO⁴,κO⁶)bis[2,4-dimethyl-6-[5-(1-methylethyl)-2-quinolinyl-KN]phenyl-κC]iridium (III); platinum complexes such as 2,3,7,8,12,13,17,18-octaethyl-21H,23H-porphyrinplatinum (II) (abbreviation: PtOEP); and rare earth metal complexes such as tris(1,3-diphenyl-1,3-propanedionato) (monophenanthroline) europium (III) (abbreviation: [Eu (DBM)₃(Phen)]) and tris[1-(2-thenoyl)-3,3,3-trifluoroacetonato](monophenanthroline) europium (III) (abbreviation: [Eu (TTA)₃(Phen)]). These compounds emit red phosphorescent light and have an emission peak in the wavelength range of 600 nm to 700 nm. Furthermore, the organometallic iridium complexes having a pyrazine skeleton can provide red light emission with favorable chromaticity.

Besides the above phosphorescent compounds, known phosphorescent compounds may be selected and used.

Examples of the TADF material include a fullerene, a derivative thereof, an acridine, a derivative thereof, and an eosin derivative. Furthermore, a metal-containing porphyrin, such as a porphyrin containing magnesium (Mg), zinc (Zn), cadmium (Cd), tin (Sn), platinum (Pt), indium (In), or palladium (Pd), can be given. Examples of the metal-containing porphyrin include a protoporphyrin-tin fluoride complex (SnF² (Proto IX)), a mesoporphyrin-tin fluoride complex (SnF² (Meso IX)), a hematoporphyrin-tin fluoride complex (SnF² (Hemato IX)), a coproporphyrin tetramethyl ester-tin fluoride complex (SnF² (Copro III-4Me)), an octaethylporphyrin-tin fluoride complex (SnF² (OEP)), an etioporphyrin-tin fluoride complex (SnF² (Etio I)), and an octaethylporphyrin-platinum chloride complex (PtCl₂OEP), which are represented by the following structural formulae.

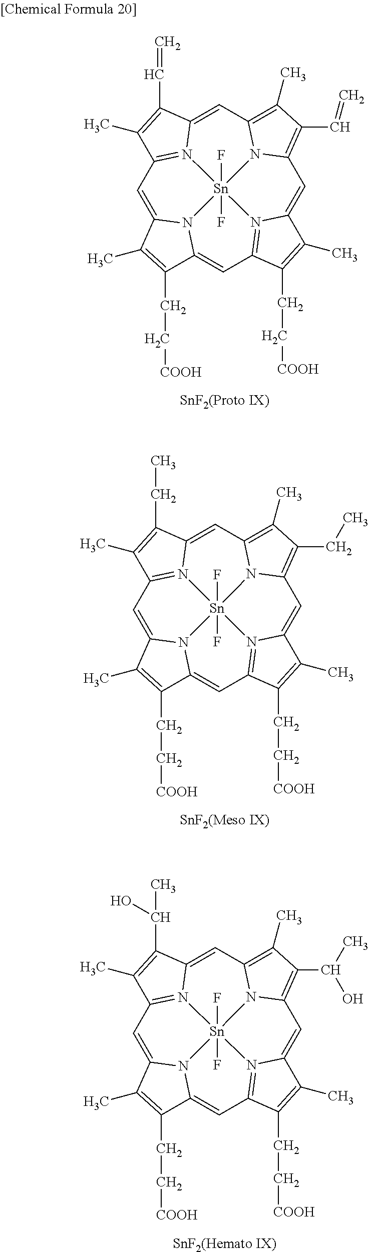

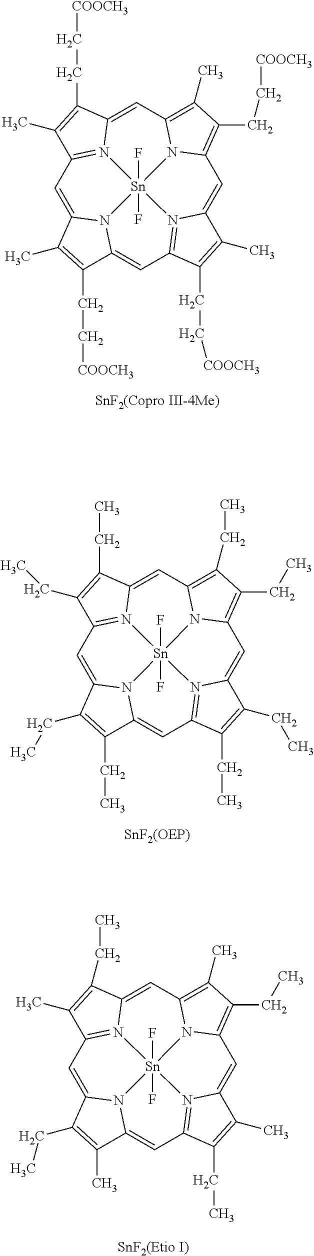

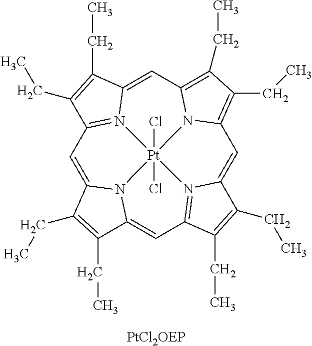

Alternatively, it is possible to use a heterocyclic compound having one or both of a T-electron rich heteroaromatic ring and a π-electron deficient heteroaromatic ring which is represented by any of the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Such a heterocyclic compound is preferable because of having high electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, or a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferable because the electron-donating property of the π-electron rich heteroaromatic ring and the electron-accepting property of the π-electron deficient heteroaromatic ring are both improved, the energy difference between the S₁ level and the T₁ level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

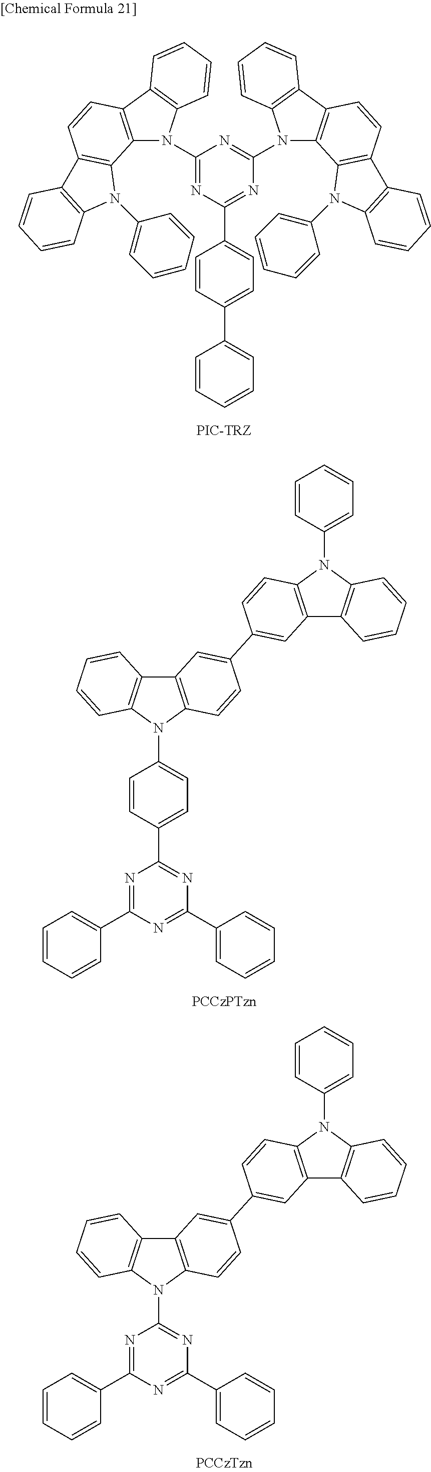 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

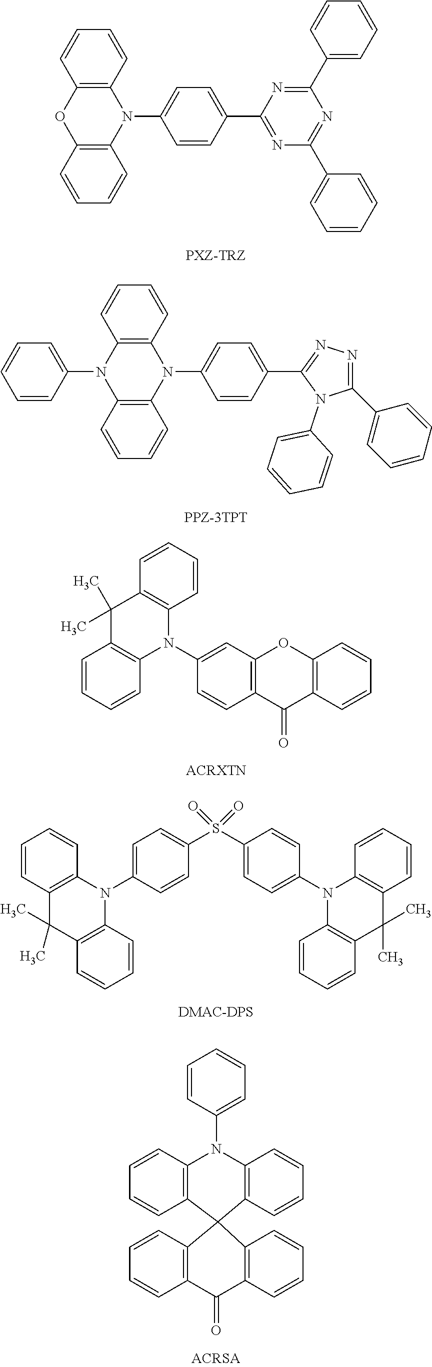 [SMILES: c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc3c(=O)c4ccccc4oc3c2)c2ccccc21 ; CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

Note that a TADF material is a material having a small difference between the S₁ level and the T₁ level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small difference between the S₁ level and the T₁ level and functions as a TADF material capable of converting triplet excitation energy into singlet excitation energy.

A phosphorescent spectrum observed at a low temperature (e.g., 77 K to 10 K) is used for an index of the T₁ level. When the level of energy with a wavelength of the line obtained by extrapolating a tangent to the fluorescent spectrum at a tail on the short wavelength side is the S₁ level and the level of energy with a wavelength of the line obtained by extrapolating a tangent to the phosphorescent spectrum at a tail on the short wavelength side is the T₁ level, the difference between the Si level and the T₁ level of the TADF material is preferably smaller than or equal to 0.3 eV, further preferably smaller than or equal to 0.2 eV.

When a TADF material is used as the light-emitting substance, the Si level of the host material is preferably higher than that of the TADF material. In addition, the T₁ level of the host material is preferably higher than that of the TADF material.

As the host material in the light-emitting layer, various carrier-transport materials such as materials having an electron-transport property and/or materials having a hole-transport property, and the TADF materials can be used.

The material having a hole-transport property is preferably an organic compound having an amine skeleton or a π-electron rich heteroaromatic ring skeleton, for example. As the T-electron rich heteroaromatic ring, a condensed aromatic ring having at least one of an acridine skeleton, a phenoxazine skeleton, a phenothiazine skeleton, a furan skeleton, a thiophene skeleton, and a pyrrole skeleton is preferable; specifically, a carbazole ring, a dibenzothiophene ring, or a ring in which an aromatic ring or a heteroaromatic ring is further condensed to a carbazole ring or a dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that has a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the organic compound having a hole-transport property preferably has an N,N-bis(4-biphenyl)amino group to enable fabricating a light-emitting device having a long lifetime.

Examples of such an organic compound include compounds having an aromatic amine skeleton, such as 4,4′-bis[N-(1-naphthyl)-N-phenylamino]biphenyl (abbreviation: NPB), N,N′-diphenyl-N,N′-bis(3-methylphenyl)-4,4′-diaminobiphenyl (abbreviation: TPD), N,N′-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl) biphenyl (abbreviation: CBP), 3,6-bis(3,5-diphenylphenyl)-9-phenylcarbazole (abbreviation: CzTP), and 9,9′-diphenyl-9H,9′H-3,3′-bicarbazole (abbreviation: PCCP); a compound having a thiophene skeleton, such as 4,4′,4″-(benzene-1,3,5-triyl)tri (dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri (dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. In addition, the organic compounds given as examples of the material having a hole-transport property that can be used for the hole-transport layer can also be used.

As the material having an electron-transport property, for example, a metal complex such as bis(10-hydroxybenzo[h]quinolinato) beryllium (II) (abbreviation: BeBq₂), bis(2-methyl-8-quinolinolato)(4-phenylphenolato)aluminum (III) (abbreviation: BAlq), bis(8-quinolinolato)zinc (II) (abbreviation: Znq), bis[2-(2-benzoxazolyl) phenolato]zinc (II) (abbreviation: ZnPBO), or bis[2-(2-benzothiazolyl) phenolato]zinc (II) (abbreviation: ZnBTZ); or an organic compound having a π-electron deficient heteroaromatic ring is preferably used. Examples of the organic compound having a π-electron deficient heteroaromatic ring skeleton include an organic compound that has a heteroaromatic ring having an azole skeleton, an organic compound that has a heteroaromatic ring having a pyridine skeleton, an organic compound that has a heteroaromatic ring having a diazine skeleton, and an organic compound that has a heteroaromatic ring having a triazine skeleton.

Among the above materials, the organic compound that has a heteroaromatic ring having a diazine skeleton (a pyrimidine skeleton, a pyrazine skeleton, or a pyridazine skeleton), the organic compound that has a heteroaromatic ring having a pyridine skeleton, and the organic compound that has a heteroaromatic ring having a triazine skeleton have high reliability and thus are preferable. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high acceptor properties and high reliability.

Examples of the organic compound having a r-electron deficient heteroaromatic ring skeleton include organic compounds having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 4,4′-bis(5-methylbenzoxazol-2-yl) stilbene (abbreviation: BzOS); organic compounds that have a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), and 2-[4-(2-triphenylenyl)phenyl]-1,10-phenanthroline (abbreviation: pTpPPhen); organic compounds having a diazine skeleton, 2-[3-(dibenzothiophen-4-yl)phenyl]dibenzo[f,h]quinoxaline (abbreviation: 2-[3′-(dibenzothiophen-4-yl) biphenyl-3-yl]dibenzo[f,h]quinoxaline 2mDBTPDBq-II), such as (abbreviation: 2mDBTBPDBq-II), 2-[3′-(9H-carbazol-9-yl) biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl) biphenyl-3-yl]naphtho[1′,2′: 4,5]furo[2,3-b]pyrazine (abbreviation: 9mDBtBPNfpr), 9-[3′-(dibenzothiophen-4-yl) biphenyl-4-yl]naphtho[1′,2′: 4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl) (biphenyl-3-yl)]naphtho[1′,2′: 4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8 (BN2)-4mDBtPBfpm), 2,2′-(pyridine-2,6-diyl)bis(4-phenylbenzo[h]quinazoline) (abbreviation: 2,6 (P-Bqn) 2Py), 2,2′-(pyridine-2,6-diyl)bis {4-[4-(2-naphthyl)phenyl]-6-phenylpyrimidine}(abbreviation: 2,6 (NP-PPm) 2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), and 7-[4-(9-phenyl-9H-carbazol-2-yl) quinazolin-2-yl]-7H-dibenzo[c,g]carbazole (abbreviation: PC-cgDBCzQz); and organic compounds that has a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl) biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc (II) PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl) biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-[4-(biphenyl-4-yl)-6-phenyl-1,3,5-triazin-2-yl]-11,12-dihydro-12-phenyl-indolo[2,3-a]carbazole (abbreviation: BP-Icz (II) Tzn), 2-[3′-(triphenylen-2-yl) biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), and 2-(biphenyl-3-yl)-4-phenyl-6-{8-[(1,1′: 4′,1″-terphenyl)-4-yl]-1-dibenzofuranyl}-1,3,5-triazine (abbreviation: mBP-TPDBfTzn). The organic compound that has a heteroaromatic ring having a diazine skeleton, the organic compound that has a heteroaromatic ring having a pyridine skeleton, and the organic compound that has a heteroaromatic ring having a triazine skeleton are preferable because of their high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the Si level of the TADF material is preferably higher than that of the fluorescent substance in order that high emission efficiency can be achieved. Furthermore, the T₁ level of the TADF material is preferably higher than the Si level of the fluorescent substance. Therefore, the T₁ level of the TADF material is preferably higher than that of the fluorescent substance.

It is also preferable to use a TADF material that emits light whose wavelength overlaps with the wavelength on the lowest-energy-side absorption band of the fluorescent substance. This enables smooth transfer of excitation energy from the TADF material to the fluorescent substance and accordingly enables efficient light emission, which is preferable.

In order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton that brings about light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no π bond are poor in carrier transport performance, whereby the TADF material and the luminophore of the fluorescent substance can be made away from each other with little influence on carrier transportation or carrier recombination. Here, the luminophore refers to an atomic group (skeleton) that brings about light emission in a fluorescent substance. The luminophore is preferably a skeleton having a π bond, further preferably has an aromatic ring, and still further preferably has a condensed aromatic ring or a condensed heteroaromatic ring. Examples of the luminophore include a phenanthrene skeleton, a stilbene skeleton, an acridone skeleton, a phenoxazine skeleton, a phenothiazine skeleton, a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene skeleton is suitably used as the host material. The use of a substance having an anthracene skeleton as the host material for the fluorescent substance makes it possible to obtain a light-emitting layer with high emission efficiency and high durability. Among the substance having an anthracene skeleton that is used as the host material, a substance having a diphenylanthracene skeleton, in particular, a substance having a 9,10-diphenylanthracene skeleton, is chemically stable and thus is preferably used as the host material. The host material preferably has a carbazole skeleton because the hole-injection and hole-transport properties are improved; further preferably, the host material has a benzocarbazole skeleton in which a benzene ring is further condensed to a carbazole skeleton because the HOMO level thereof is higher than that of the host material having a carbazole skeleton by approximately 0.1 eV and thus holes enter the host material easily. In particular, the host material preferably has a dibenzocarbazole skeleton because the HOMO level thereof is higher than that of the host material having a carbazole skeleton by approximately 0.1 eV so that holes enter the host material easily, the hole-transport property is improved, and the heat resistance is increased. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4-(9-phenyl-9H-fluoren-9-yl) biphenyl-4′-yl]anthracene (abbreviation: FLPPA), 9-(1-naphthyl)-10-[4-(2-naphthyl)phenyl]anthracene (abbreviation: aN-BNPAnth), 9-(1-naphthyl)-10-(2-naphthyl) anthracene (abbreviation: α,βADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(2-naphthyl)-10-[3-(2-naphthyl)phenyl]anthracene (abbreviation: βN-mβNPAnth), and 1-{4-[10-(biphenyl-4-yl)-9-anthracenyl]phenyl}-2-ethyl-1H-benzimidazole (abbreviation: EtBImPBPhA). In particular, CzPA, cgDBCzPA, 2mBnfPPA, and PCzPA exhibit excellent properties and thus are preferably selected.

Note that the host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property may be 1:19 to 19:1.

Note that a phosphorescent substance can be used as part of the mixed material. When a fluorescent substance is used as the light-emitting substance, a phosphorescent substance can be used as an energy donor for supplying excitation energy to the fluorescent substance.

These mixed materials may form an exciplex. These mixed materials are preferably selected so as to form an exciplex that exhibits light emission whose wavelength overlaps with the wavelength on the lowest-energy-side absorption band of the light-emitting substance, in which case energy can be transferred smoothly and light emission can be obtained efficiently. The use of such a structure is preferable because the driving voltage can also be reduced.

Note that at least one of the materials forming an exciplex may be a phosphorescent substance. In this case, triplet excitation energy can be efficiently converted into singlet excitation energy by reverse intersystem crossing.

In order to form an exciplex efficiently, a material having an electron-transport property is preferably combined with a material having a hole-transport property and a HOMO level higher than or equal to that of the material having an electron-transport property. In addition, the LUMO level of the material having a hole-transport property is preferably higher than or equal to that of the material having an electron-transport property. Note that the LUMO levels and the HOMO levels of the materials can be calculated from the electrochemical characteristics (the reduction potentials and the oxidation potentials) of the materials that are measured by cyclic voltammetry (CV).

The formation of an exciplex can be confirmed by a phenomenon in which the emission spectrum of the mixed film in which the material having a hole-transport property and the material having an electron-transport property are mixed is shifted to the longer wavelength side than the emission spectrum of each of the materials (or has another peak on the longer wavelength side) observed by comparison of the emission spectra of the material having a hole-transport property, the material having an electron-transport property, and the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed by comparison of transient PL of the material having a hole-transport property, the material having an electron-transport property, and the mixed film of these materials. The transient PL can be rephrased as transient electroluminescence (EL). That is, the formation of an exciplex can also be confirmed by a difference in transient response observed by comparison of the transient EL of the material having a hole-transport property, the material having an electron-transport property, and the mixed film of these materials.

The electron-transport layer 114 contains a substance with an electron-transport property. The material having an electron-transport property preferably has an electron mobility higher than or equal to 1×10⁻⁷ cm²/Vs, further preferably higher than or equal to 1×10⁻⁶ cm²/Vs when the square root of the electric field strength [V/cm] is 600. Note that any other substance can also be used as long as the substance has an electron-transport property higher than a hole-transport property. The above organic compound is preferably an organic compound that has a π-electron deficient heteroaromatic ring. The organic compound that has a π-electron deficient heteroaromatic ring is preferably one or more of an organic compound that has a heteroaromatic ring having a polyazole skeleton, an organic compound that has a heteroaromatic ring having a pyridine skeleton, an organic compound that has a heteroaromatic ring having a diazine skeleton, and an organic compound that has a heteroaromatic ring having a triazine skeleton.

As the organic compound having an electron-transport property that can be used in the electron-transport layer 114, any of the organic compounds that can be used as the organic compound having an electron-transport property in the light-emitting layer 113 and the second organic compound in the electron-injection layer 115 in Embodiment 1 can be similarly used. Among the above organic compounds, the organic compound that has a heteroaromatic ring having a diazine skeleton, the organic compound that has a heteroaromatic ring having a pyridine skeleton, and the organic compound that has a heteroaromatic ring having a triazine skeleton are especially preferable because of having high reliability. In particular, the organic compound that has a heteroaromatic ring having a diazine (pyrimidine or pyrazine) skeleton and the organic compound that has a heteroaromatic ring having a triazine skeleton have a high electron-transport property to contribute to a reduction in driving voltage. In particular, an organic compound having a phenanthroline skeleton, such as mTpPPhen, PnNPhen, or mPPhen2P, is preferable. An organic compound having a phenanthroline dimer structure, such as mPPhen2P, is further preferable because of its excellent stability.

The electron-transport layer preferably contains an organic compound having an electron-transport property with an acid dissociation constant pKₐ of less than 4.

Note that the electron-transport layer 114 may have a stacked-layer structure. In the case where the electron-transport layer 114 has a stacked-layer structure, the layer in contact with the light-emitting layer 113 may function as a hole-blocking layer. In the case where the electron-transport layer in contact with the light-emitting layer functions as a hole-blocking layer, the electron-transport layer is preferably formed using a material having a lower HOMO level than a material contained in the light-emitting layer by greater than or equal to 0.5 eV.

The electron-injection layer 115 is formed between the electron-transport layer 114 and the second electrode 102. Since the structure of the electron-injection layer 115 has been described in detail in Embodiment 1, the repetitive description thereof is omitted.

The second electrode 102 is preferably formed in contact with the electron-injection layer 115. Since the structure of the second electrode has been described in detail in Embodiment 1, the repetitive description thereof is omitted.

When the second electrode 102 is formed using a material that transmits visible light, the light-emitting device can emit light from the second electrode 102 side. When the first electrode 101 is formed using a material that transmits visible light, the light-emitting device can emit light from the first electrode 101 side.

Films of the conductive materials included in the second electrode 102 can be formed by a dry process such as a vacuum evaporation method or a sputtering method, an ink-jet method, a spin coating method, or the like. Alternatively, a wet process using a sol-gel method or a wet process using a paste of a metal material may be employed.

Note that in the case of a top-emission light-emitting device, forming a cap layer by evaporation of an organic compound over the second electrode can improve light extraction efficiency. The cap layer may have a single-layer structure or a stacked-layer structure. In the case of a stacked-layer structure, the use of organic compounds with different refractive indexes can further increase the light extraction efficiency.

The organic compound layer 103 can be formed by any of a variety of methods, including a dry process and a wet process. For example, a vacuum evaporation method, a gravure printing method, an offset printing method, a screen printing method, an ink-jet method, a spin coating method, or the like may be used.

Different film formation methods may be used to form the electrodes or the layers described above.

In the case where a deposition method that causes serious damage to a base, such as a sputtering method, is employed to form the second electrode 102, a p-type layer 117 may be provided as illustrated in FIG. 1B in order to protect the electron-injection layer 115. The p-type layer 117 can be formed with the composite material described above as the material that can be used for the hole-injection layer 111. A transition metal oxide such as a molybdenum oxide, a vanadium oxide, a ruthenium oxide, a tungsten oxide, or a manganese oxide is more robust than an organic compound, and thus is preferably used as the substance having an acceptor property used for the p-type layer, in which case damage at the time of forming the second electrode 102 can be prevented.

Although not illustrated, an electron-relay layer may be provided between the electron-injection layer 115 and the p-type layer 117. The electron-relay layer contains at least a substance having an electron-transport property and has a function of preventing an interaction between the electron-injection layer 115 and the p-type layer 117 and smoothly transferring electrons. The LUMO level of the substance having an electron-transport property included in the electron-relay layer is preferably between the LUMO level of the acceptor substance in the p-type layer 117 and the LUMO level of a substance included in a layer of the electron-transport layer 114 that is in contact with the electron-injection layer 115. Specifically, the LUMO level of the substance having an electron-transport property in the electron-relay layer is preferably higher than or equal to −5.0 eV, further preferably higher than or equal to −5.0 eV and lower than or equal to −3.0 eV. Note that as the substance having an electron-transport property in the electron-relay layer, a phthalocyanine-based material or a metal complex having a metal-oxygen bond and an aromatic ligand is preferably used. Specific examples of the substance having an electron-transport property used for the electron-relay layer include a perylenetetracarboxylic acid derivative such as diquinoxalino[2,3-a: 2′,3′-c]phenazine (abbreviation: HATNA), 2,3,8,9,14,15-hexafluorodiquinoxalino[2,3-a: 2′,3′-c]phenazine (abbreviation: HATNA-F6), 3,4,9,10-perylenetetracarboxylic diimide (abbreviation: PTCDI), or 3,4,9,10-perylenetetracarboxyl-bis-benzimidazole (abbreviation: PTCBI), (C₆₀—Iₕ) [5,6]fullerene (abbreviation: C₆₀), and (C₇₀-D₅ₕ) [5,6]fullerene (abbreviation: C₇₀). It is also possible to use a compound including a heterophane skeleton, which is a cyclophane skeleton having a hetero ring; for example, a phthalocyanine compound such as phthalocyanine (abbreviation: H₂Pc) can be used as the compound. Alternatively, it is possible to use a metal phthalocyanine containing copper, zinc, cobalt, iron, chromium, nickel, or the like or a derivative thereof, such as copper phthalocyanine (abbreviation: CuPc), zinc phthalocyanine (abbreviation: ZnPc), cobalt phthalocyanine (abbreviation: CoPc), iron phthalocyanine (abbreviation: FePc), tin phthalocyanine (abbreviation: SnPc), tin oxide phthalocyanine (abbreviation: SnOPc), titanium oxide phthalocyanine (abbreviation: TiOPc), or vanadium oxide phthalocyanine (abbreviation: VOPc). It is particularly preferable to use a phthalocyanine-based metal complex such as copper phthalocyanine or zinc phthalocyanine or 2,3,8,9,14,15-hexafluorodiquinoxalino[2,3-a: 2′,3′-c]phenazine.

The thickness of the electron-relay layer is preferably greater than or equal to 1 nm and less than or equal to 10 nm, further preferably greater than or equal to 2 nm and less than or equal to 5 nm.

Next, an embodiment of a light-emitting device with a structure in which a plurality of light-emitting units are stacked (this type of light-emitting device is also referred to as a stacked or tandem device) is described with reference to FIG. 1C. This light-emitting device includes a plurality of light-emitting units between the first electrode 101 and a cathode. One light-emitting unit has substantially the same structure as the organic compound layer 103 illustrated in FIG. 1A. In other words, the light-emitting device illustrated in FIG. 1C includes a plurality of light-emitting units, and the light-emitting device illustrated in FIG. 1A includes a single light-emitting unit.

In FIG. 1C, a first light-emitting unit 511 and a second light-emitting unit 512 are stacked between a first electrode 501 and a second electrode 502, and an intermediate layer 513 is provided between the first light-emitting unit 511 and the second light-emitting unit 512. The first electrode 501 and the second electrode 502 correspond to the first electrode 101 and the second electrode 102, respectively, illustrated in FIG. 1A, and can be formed using the materials given in the description for FIG. 1A. Furthermore, the first light-emitting unit 511 and the second light-emitting unit 512 may have the same layer structure or different layer structures. Materials for the layers included in the first light-emitting unit 511 and the materials for the layers included in the second light-emitting unit 512 may be the same or different from each other.

The intermediate layer 513 has a function of injecting electrons into one of the light-emitting units and injecting holes into the other of the light-emitting units when voltage is applied between the first electrode 501 and the second electrode 502. That is, in FIG. 1C, the intermediate layer 513 injects electrons into the first light-emitting unit 511 and holes into the second light-emitting unit 512 when voltage is applied such that the potential of the first electrode 101 becomes higher than the potential of the cathode.

The intermediate layer 513 includes a charge-generation layer. The charge-generation layer includes at least a p-type layer 117. The p-type layer 117 is preferably formed using any of the composite materials given above as examples of materials that can be used for the hole-injection layer 111. The p-type layer 117 may be formed by stacking a film containing the above-described acceptor material of the composite material and a film containing the above-described hole-transport material of the composite material. When a potential is applied to the p-type layer 117, electrons are injected into the electron-transport layer 114 and holes are injected into the cathode; thus, the light-emitting device operates.

Note that the intermediate layer 513 preferably includes one or both of an electron-relay layer 118 and an n-type layer 119 in addition to the p-type layer 117.

The electron-relay layer 118 has a structure similar to that of the electron-relay layer described in the description for FIG. 1B; thus, the repetitive description thereof is omitted.

The n-type layer 119 can be formed using a substance having a high electron-injection property, e.g., an alkali metal, an alkaline earth metal, a rare earth metal, or a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)).

In the case where the n-type layer 119 contains a substance having an electron-transport property and a donor substance, the donor substance can be an organic compound such as tetrathianaphthacene (abbreviation: TTN), nickelocene, or decamethylnickelocene, as well as an alkali metal, an alkaline earth metal, a rare earth metal, or a compound thereof (e.g., an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)). As the substance having an electron-transport property, a material similar to the above-described material for the electron-transport layer 114 can be used.

Instead of the n-type layer 119, a layer containing the metal compound described in Embodiment 1 as being used for the electron-injection layer and the organic compound including a phenanthroline ring having an electron-donating group may be formed in the same position as the n-type layer 119. Also in the case of such a structure, a tandem light-emitting device with favorable characteristics can be manufactured.

In the case where the first electrode 101-side surface of a light-emitting unit is in contact with the intermediate layer 513, the charge-generation layer of the intermediate layer 513 can also function as a hole-injection layer of the light-emitting unit; therefore, a hole-injection layer is not necessarily provided in the light-emitting unit. In the case where the cathode-side surface of a light-emitting unit is in contact with the intermediate layer 513, the intermediate layer 513 can also function as an electron-injection layer of the light-emitting unit; therefore, an electron-injection layer is not necessarily provided in the light-emitting unit.

The light-emitting device having two light-emitting units is described with reference to FIG. 1C; however, one embodiment of the present invention can also be applied to a light-emitting device in which three or more light-emitting units are stacked. With a plurality of light-emitting units partitioned by the intermediate layer 513 between a pair of electrodes as in the light-emitting device of this embodiment, it is possible to provide a long-life element that can emit light with high luminance at a low current density. A light-emitting apparatus that can be driven at a low voltage and has low power consumption can also be provided.

When the emission colors of the light-emitting units are different, light emission of a desired color can be obtained from the light-emitting device as a whole. For example, in a light-emitting device having two light-emitting units, the emission colors of the first light-emitting unit may be red and green and the emission color of the second light-emitting unit may be blue, so that the light-emitting device can emit white light as the whole.

The above-described layers and electrodes such as the organic compound layer 103, the first light-emitting unit 511, the second light-emitting unit 512, and the intermediate layer 513 can be formed by a method such as an evaporation method (including a vacuum evaporation method), a droplet discharge method (also referred to as an ink-jet method), a coating method, or a gravure printing method. A low molecular material, a middle molecular material (including an oligomer and a dendrimer), or a high molecular material may be included in the above components.

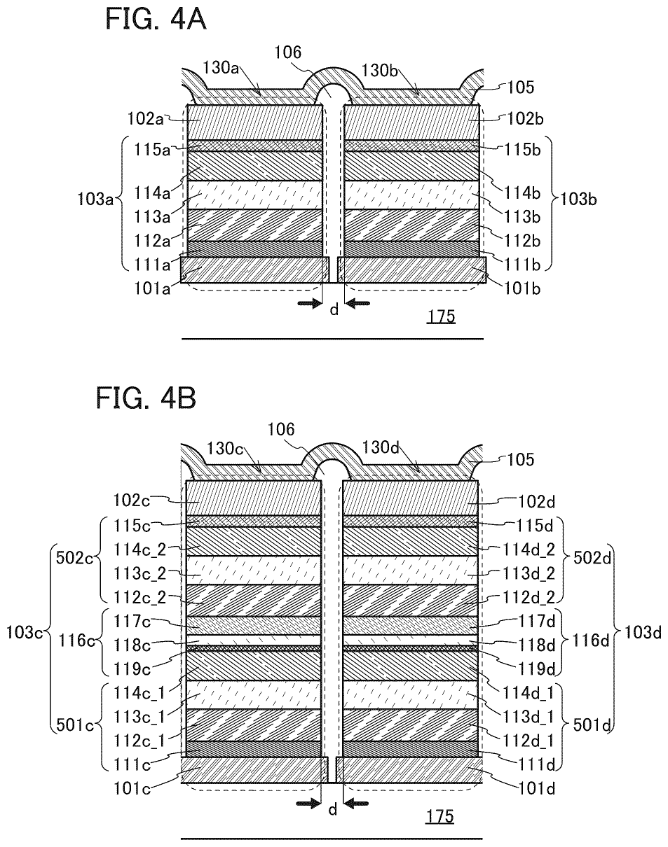

FIG. 4A illustrates two adjacent light-emitting devices (light-emitting devices 130a and 130b) included in a display device of one embodiment of the present invention.

The light-emitting device 130a includes an organic compound layer 103a between a first electrode 101a over an insulating layer 175 and a second electrode 102a facing the first electrode 101a, and the organic compound layer 103a includes an electron-injection layer 115a. The illustrated organic compound layer 103a includes a hole-injection layer 111a, a hole-transport layer 112a, a light-emitting layer 113a, an electron-transport layer 114a, and an electron-injection layer 115a, but may have a different stacked-layer structure.

The light-emitting device 130b includes an organic compound layer 103b between a first electrode 101b over the insulating layer 175 and the second electrode 102b facing the first electrode 101b, and the organic compound layer 103b includes an electron-injection layer 115b. The illustrated organic compound layer 103b includes a hole-injection layer 111b, a hole-transport layer 112b, a light-emitting layer 113b, an electron-transport layer 114b, and an electron-injection layer 115b, but may have a different stacked-layer structure.

The structures of the electron-injection layer 115a and the second electrode 102a in the light-emitting device 130a and the structures of the electron-injection layer 115b and the second electrode 102b in the light-emitting device 130b are preferably as described in Embodiment 1.

The organic compound layers 103a and 103b are independent of each other, and the second electrodes 102a and 102b are independent of each other because processing by a photolithography method is performed after a film to be the second electrodes 102a and 102b is formed. In the light-emitting device of one embodiment of the present invention, even though processing by a photolithography method is performed after the film to be the second electrodes 102a and 102b is formed, the light-emitting device can have favorable characteristics.

The end portion (outline) of the second electrode 102a and the end portion (outline) of the organic compound layer 103a are substantially aligned in the direction perpendicular to the substrate due to the processing by a photolithography method. The end portion (outline) of the second electrode 102b and the end portion (outline) of the organic compound layer 103b are substantially aligned in the direction perpendicular to the substrate due to the processing by a photolithography method.

There is a space d between the organic compound layer 103a and an organic compound layer 103d because of the processing by a photolithography method. Since the organic compound layers are processed by a photolithography method, the distance between a first electrode 101c and the first electrode 101d can be shorter than that in the case of employing mask vapor deposition; the distance can be longer than or equal to 0.5 μm and shorter than or equal to 5 μm.

FIG. 4B illustrates two adjacent tandem light-emitting devices (light-emitting devices 130c and 130d) manufactured by a photolithography method.

The light-emitting device 130c includes an organic compound layer 103c between the first electrode 101c over the insulating layer 175 and the second electrode 102c. The organic compound layer 103c has a structure where a first light-emitting unit 501c and a second light-emitting unit 502c are stacked with an intermediate layer 116c therebetween. Although FIG. 4B illustrates an example in which the two light-emitting units are stacked, three or more light-emitting units may be stacked. In the structure illustrated in FIG. 4B, the first light-emitting unit 501c includes a hole-injection layer 111c, a first hole-transport layer 112c_1, a first light-emitting layer 113c_1, and a first electron-transport layer 114c_1; the intermediate layer 116c includes a p-type layer 117c, an electron-relay layer 118c, and an n-type layer 119c; and the second light-emitting unit 502c includes a second hole-transport layer 112c_2, a second light-emitting layer 113c_2, a second electron-transport layer 114c_2, and an electron-injection layer 115c. The electron-relay layer 118c is not necessarily provided.

The light-emitting device 130d includes an organic compound layer 103d between the first electrode 101d over the insulating layer 175 and a second electrode 102d. The organic compound layer 103d has a structure in which a first light-emitting unit 501d and a second light-emitting unit 502d are stacked with an intermediate layer 116d therebetween. Although FIG. 4B illustrates an example in which the two light-emitting units are stacked, three or more light-emitting units may be stacked. In the structure illustrated in FIG. 4B, the first light-emitting unit 501d includes a hole-injection layer 111d, a first hole-transport layer 112d_1, a first light-emitting layer 113d_1, and a first electron-transport layer 114d_1; the intermediate layer 116d includes a p-type layer 117d, an electron-relay layer 118d, and an n-type layer 119d; and the second light-emitting unit 502d includes a second hole-transport layer 112d_2, a second light-emitting layer 113d_2, a second electron-transport layer 114d_2, and an electron-injection layer 115d. The electron-relay layer 118d is not necessarily provided.

In the light-emitting devices 130c and 130d, the electron-injection layers 115c and 115d and the second electrodes 102c and 102d preferably have the structures as described in Embodiment 1.

The organic compound layers 103c and 103d are independent of each other because processing by a photolithography method is performed after a film to be the second electrodes 102c and 102d is formed. In the light-emitting device of one embodiment of the present invention, even though processing by a photolithography method is performed after the film to be the second electrodes 102c and 102d is formed, the light-emitting device can have favorable characteristics.

The end portion (outline) of the second electrode 102c and the end portion (outline) of the organic compound layer 103c are substantially aligned in the direction perpendicular to the substrate due to the processing by a photolithography method. The end portion (outline) of the second electrode 102d and the end portion (outline) of the organic compound layer 103d are substantially aligned in the direction perpendicular to the substrate due to the processing by a photolithography method.

There is a space d between the organic compound layer 103c and the organic compound layer 103d because of the processing by a photolithography method. Since the organic compound layers are processed by a photolithography method, the distance between the first electrode 101c and the first electrode 101d can be shorter than that in the case of employing mask vapor deposition; the distance can be longer than or equal to 0.5 μm and shorter than or equal to 5 μm.

Since the second electrode 102a is independent of the second electrode 102b or the second electrode 102c is independent of the second electrode 102d, an auxiliary electrode 105 is preferably formed in order to apply voltage to a plurality of second electrodes included in the light-emitting apparatus. The auxiliary electrode 105 is preferably formed after an insulating layer 106 is formed between the second electrodes 102a and 102b or between the light-emitting devices 130c and 130d to prevent a short circuit between the second electrode and the organic compound layer or between the second electrode and the first electrode. The insulating layer 106 is preferably formed using an organic insulating material. For the auxiliary electrode 105, a material that can be used for the second electrode can be used.

In the light-emitting device of one embodiment of the present invention, since the organic compound layer is processed by a photolithography method, the organic compound layer can be processed with a sufficient accuracy to manufacture a high-resolution display device. Furthermore, since a photolithography process can be performed on the electron-injection layer far from the light-emitting layer without contamination by an alkali metal, the light-emitting device can have favorable characteristics. As described above, the light-emitting device of one embodiment of the present invention that has the above-described structure enables a high-resolution display device and can have favorable characteristics.

In the light-emitting device of one embodiment of the present invention, since the second electrode and the organic compound layer are processed at a time by a photolithography method after the second electrode is formed, the contours of the layers included in the organic compound layer are substantially aligned with each other when seen from the direction substantially perpendicular to the surface of the insulating layer where the first electrode is formed. An end portion of the second electrode in the cross section and an end portion of the first layer in the cross section are aligned in the direction substantially perpendicular to the surface of the insulating layer where the first electrode is formed. Here, the term “aligned with each other” or “substantially aligned with each other” in this specification means that in a layer A and a layer B in contact with each other, misalignment between a contour A of the layer A and a contour B of the layer B is within 5% of the width of the organic compound layer along a line orthogonal to the compared portions of the contours. Moreover, the term “substantially perpendicular” means an angle of 85° to 95°.

The structure of this embodiment can be used in combination with any of the other structures as appropriate.

### Embodiment 3

Described in this embodiment is a mode in which the light-emitting device of one embodiment of the present invention is used as a display element of a display device.

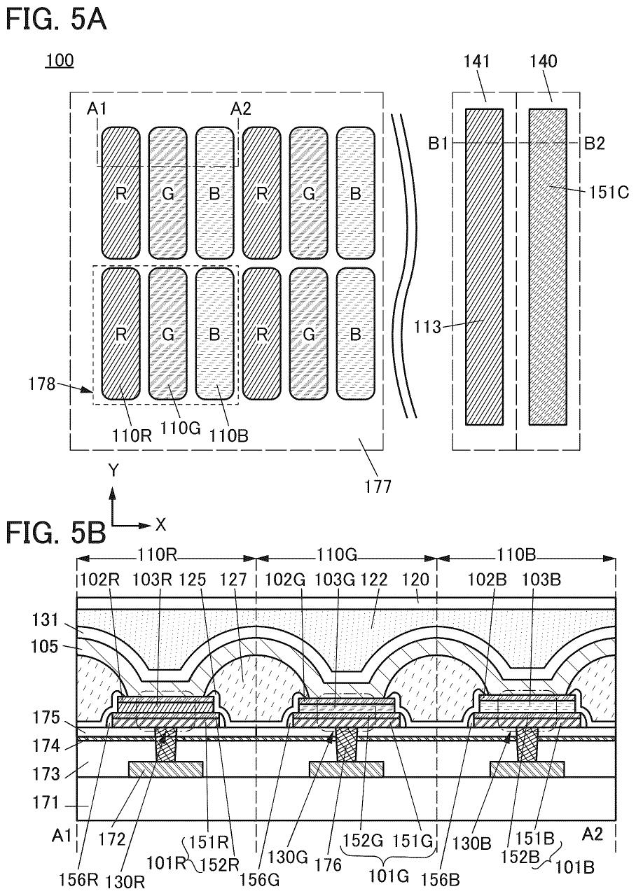

As illustrated in FIGS. 5A and 5B, a plurality of light-emitting devices 130 are formed over the insulating layer 175 to constitute a display device.

A display device includes a pixel portion 177 in which a plurality of pixels 178 are arranged in matrix. The pixel 178 includes subpixels 110R, 110G, and 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, a full-color image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and yellow (Y), and four subpixels emitting light of R, G, and B and infrared light (IR).

In this specification and the like, the row direction and the column direction are sometimes referred to as the X direction and the Y direction, respectively. The X direction and the Y direction intersect with each other and are perpendicular to each other, for example.

FIG. 5A illustrates an example where subpixels of different colors are arranged in the X direction and subpixels of the same color are arranged in the Y direction. Note that subpixels of different colors may be arranged in the Y direction, and subpixels of the same color may be arranged in the X direction.

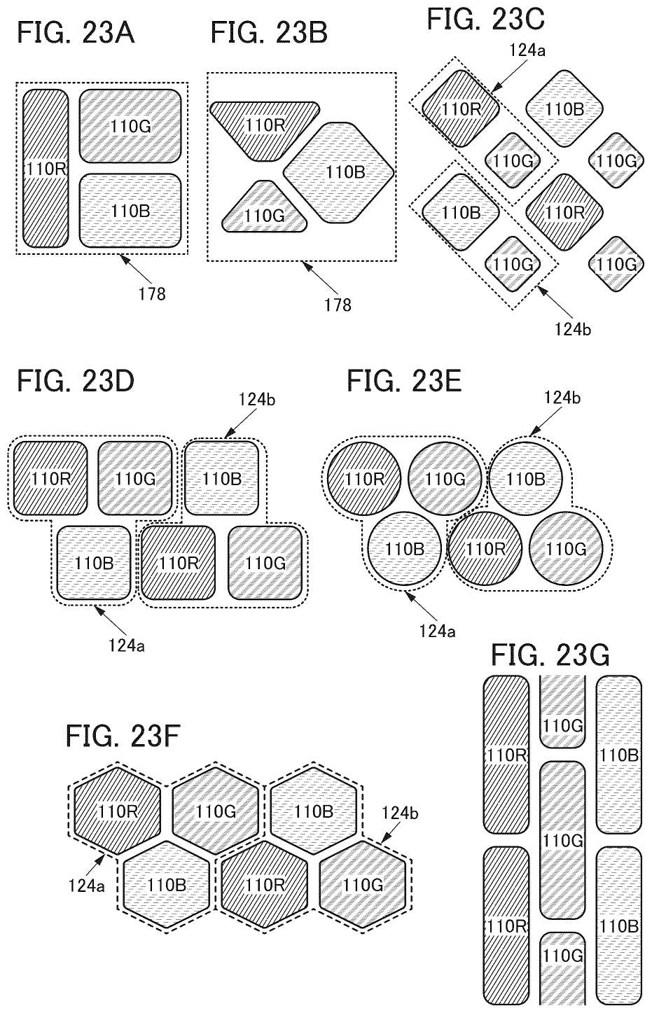

Note that the layout of the subpixels is not limited thereto, and a variety of patterns such as stripe arrangement, S-stripe arrangement, matrix arrangement, delta arrangement, Bayer arrangement, and PenTile arrangement can be employed. FIGS. 23A to 23G illustrate layout examples of the subpixels.

The pixel 178 illustrated in FIG. 23A employs S-stripe arrangement. The pixel 178 illustrated in FIG. 23A includes three subpixels, the subpixel 110R, the subpixel 110G, and the subpixel 110B.

The pixel 178 illustrated in FIG. 23B includes the subpixel 110R whose top surface has a rough trapezoidal or rough triangle shape with rounded corners, the subpixel 110G whose top surface has a rough trapezoidal or rough triangle shape with rounded corners, and the subpixel 110B whose top surface has a rough tetragonal or rough hexagonal shape with rounded corners. The subpixel 110R has a larger light-emitting area than the subpixel 110G. In this manner, the shapes and sizes of the subpixels can be determined independently. For example, the size of a subpixel including a light-emitting device with higher reliability can be smaller.

Pixels 124a and 124b illustrated in FIG. 23C employ PenTile arrangement. FIG. 23C illustrates an example in which the pixels 124a including the subpixels 110R and 110G and the pixels 124b including the subpixels 110G and 110B are alternately arranged.

The pixels 124a and 124b illustrated in FIGS. 23D to 23F employ delta arrangement. The pixel 124a includes two subpixels (the subpixels 110R and 110G) in the upper row (first row) and one subpixel (the subpixel 110B) in the lower row (second row). The pixel 124b includes one subpixel (the subpixel 110B) in the upper row (first row) and two subpixels (the subpixels 110R and 110G) in the lower row (second row).

FIG. 23D illustrates an example where the top surface of each subpixel has a rough tetragonal shape with rounded corners. FIG. 23E illustrates an example where the top surface of each subpixel is circular. FIG. 23F illustrates an example where the top surface of each subpixel has a rough hexagonal shape with rounded corners.

In FIG. 23F, subpixels are placed in respective hexagonal regions that are arranged densely. Focusing on one of the subpixels, the subpixel is placed so as to be surrounded by six subpixels. The subpixels are arranged such that subpixels that emit light of the same color are not adjacent to each other. For example, focusing on the subpixel 110R, the subpixel 110R is surrounded by three subpixels 110G and three subpixels 110B that are alternately arranged.

FIG. 23G illustrates an example where subpixels of different colors are arranged in a zigzag manner. Specifically, the positions of the top sides of two subpixels arranged in the row direction (e.g., the subpixels 110R and 110G or the subpixels 110G and 110B) are not aligned in the top view.

In the pixels illustrated in FIGS. 23A to 23G, for example, it is preferable that the subpixel 110R be a subpixel R that emits red light, the subpixel 110G be a subpixel G that emits green light, and the subpixel 110B be a subpixel B that emits blue light. Note that the structures of the subpixels are not limited thereto, and the colors and the order of the subpixels can be determined as appropriate. For example, the subpixel 110G may be the subpixel R that emits red light, and the subpixel 110R may be the subpixel G that emits green light.

In the case of what is called stripe arrangement as illustrated in FIGS. 5A and 23G, the second electrodes 102 of the light-emitting devices exhibiting the same emission color can be successively formed. In that case, even when processing by a photolithography method is performed after the components up to the second electrode 102 are formed, voltage can be applied to the light-emitting devices without the auxiliary electrode 105. In the case where processing by a photolithography method is performed and the second electrodes 102 of the light-emitting devices are independent of each other, the auxiliary electrode 105 is preferably formed.

Outside the pixel portion 177, a connection portion 140 is provided and a region 141 may also be provided. The region 141 is provided between the pixel portion 177 and the connection portion 140. The organic compound layer 103 is provided in the region 141. A conductive layer 151C is provided in the connection portion 140.

Although FIG. 5A illustrates an example where the region 141 and the connection portion 140 are positioned on the right side of the pixel portion 177, the positions of the region 141 and the connection portion 140 are not particularly limited. The number of regions 141 and the number of connection portions 140 can each be one or more.

FIG. 5B is an example of a cross-sectional view along the dashed-dotted line A¹-A² in FIG. 5A. As illustrated in FIG. 5A, the display device includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). Openings reaching the conductive layer 172 are provided in the insulating layers 175, 174, and 173, and plugs 176 are provided to fill the openings.

In the pixel portion 177, the light-emitting device 130 is provided over the insulating layer 175 and the plug 176. A protective layer 131 is provided to cover the light-emitting device 130. A substrate 120 is bonded onto the protective layer 131 with a resin layer 122. An inorganic insulating layer 125 and an insulating layer 127 over the inorganic insulating layer 125 are preferably provided between the adjacent light-emitting devices 130.

Examples of materials used for the insulating layer 127 include an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. The organic resin layer 180 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin.

A photosensitive resin can also be used for the insulating layer 127. A photoresist may be used for the photosensitive resin. As the photosensitive resin, a positive photosensitive material or a negative photosensitive material can be used.

The insulating layer 127 may contain a material absorbing visible light. For example, the insulating layer 127 itself may be made of a material absorbing visible light, or the insulating layer 127 may contain a pigment absorbing visible light. For example, the insulating layer 127 can be formed using a resin that can be used as a color filter transmitting red, blue, or green light and absorbing light of the other colors; or a resin that contains carbon black as a pigment and functions as a black matrix.

Although FIG. 5B shows cross sections of a plurality of inorganic insulating layers 125 and a plurality of insulating layers 127, the inorganic insulating layers 125 are preferably connected to each other and the insulating layers 127 are preferably connected to each other when the display device is seen from above. In other words, the inorganic insulating layers 125 and the insulating layer 127 preferably have openings over the first electrode.

In FIG. 5B, light-emitting devices 130R, 130G, and 130B are each shown as the light-emitting device 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, 130G, or 130B may emit visible light of another color or infrared light.

The display device of one embodiment of the present invention can be, for example, a top-emission display device where light is emitted in the direction opposite to a substrate over which light-emitting devices are formed. Note that the display device of one embodiment of the present invention may be of a bottom-emission type.

The light-emitting device 130R has a structure described in Embodiments 1 and 2. The light-emitting device 130R includes a first electrode 101R (pixel electrode) including conductive layers 151R and 152R, an organic compound layer 103R over the first electrode 101R, and a second electrode 102R over the organic compound layer 103R. The electron-injection layer which is the outermost surface layer of the organic compound layer 103R and the second electrode 102R have structures as described in Embodiments 1 and 2. Such a structure can reduce damage to the light-emitting layer or an active layer during a photolithography process, the light-emitting device 130R with favorable film quality and electrical characteristics can be provided.

The light-emitting device 130G has a structure described in Embodiments 1 and 2. The light-emitting device 130G includes a first electrode 101G (pixel electrode) including conductive layers 151G and 152G, an organic compound layer 103G over the first electrode 101G, and a second electrode 102G over the organic compound layer 103G. The electron-injection layer which is the outermost surface layer of the organic compound layer 103G and the second electrode 102G have structures as described in Embodiments 1 and 2. Such a structure can reduce damage to the light-emitting layer or an active layer during a photolithography process, the light-emitting device 130G with favorable film quality and electrical characteristics can be provided.

The light-emitting device 130B has a structure described in Embodiments 1 and 2. The light-emitting device 130B includes a first electrode 101B (pixel electrode) including conductive layers 151B and 152B, an organic compound layer 103B over the first electrode 101B, and a second electrode 102B over the organic compound layer 103B. The electron-injection layer which is the outermost surface layer of the organic compound layer 103B and the second electrode 102B have structures as described in Embodiments 1 and 2. Such a structure can reduce damage to the light-emitting layer or an active layer during a photolithography process, the light-emitting device 130B with favorable film quality and electrical characteristics can be provided.

The organic compound layers 103R, 103G, and 103B are island-shaped layers that are independent of each other on a light-emitting device basis or on an emission color basis. It is preferable that the organic compound layers 103R, 103G, and 103B not overlap with one another. Providing the island-shaped organic compound layer 103 in each of the light-emitting devices 130 can inhibit leakage current between the adjacent light-emitting devices 130 even in a high-resolution display device. This can prevent crosstalk, so that a display device with extremely high contrast can be obtained. Specifically, a display device having high current efficiency at low luminance can be obtained.

The second electrodes 102R, 102G, and 102B are island-shaped layers that are independent of each other on a light-emitting device basis or on an emission color basis. It is preferable that the second electrodes 102R, 102G, and 102B not overlap with one another.

Over the second electrode 102, the auxiliary electrode 105 is preferably formed after the insulating layer 127 is formed to cover side surfaces of the light-emitting device 130, so that voltage can be easily supplied to the second electrode 102. A metal material can be used for the auxiliary electrode 105, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), neodymium (Nd), or magnesium (Mg) or an alloy containing an appropriate combination of any of these metals, for example.

For the auxiliary electrode 105, an oxide containing one or more selected from indium, tin, zinc, gallium, titanium, aluminum, and silicon can also be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. Note that in the case where the light-emitting device 130 has a top-emission structure, a conductive metal oxide having a light-transmitting property is preferably used for the auxiliary electrode 105.

The island-shaped organic compound layer 103 is formed in the following manner. An organic compound film and the second electrode 102 are formed in this order, and then the organic compound film and the second electrode 102 are processed by a photolithography method. When the electron-injection layer and the second electrode in the light-emitting device of one embodiment of the present invention have the structure as described in Embodiment 1, the light-emitting device can have favorable characteristics with which an increase in driving voltage is inhibited even when processing by a photolithography method is performed after the second electrode 102 is formed. Processing by a photolithography method is performed after the second electrode 102 is formed, whereby a light-emitting device with favorable reliability can be obtained at low cost.

In the display device of one embodiment of the present invention, the first electrode 101 (pixel electrode) of the light-emitting device preferably has a stacked-layer structure. For example, in the example illustrated in FIG. 5B, the first electrode 101 of the light-emitting device 130 is a stack of the conductive layer 151 (the conductive layers 151R, 151G, and 151B) on the insulating layer 171 side and the conductive layer 152 (the conductive layers 152R, 152G, and 152B) on the organic compound layer side.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, indium tin oxide containing silicon can be suitably used for the conductive layer 152 because of having a high work function, for example, a work function higher than or equal to 4.0 eV.

The conductive layer 151 and the conductive layer 152 may each be a stack of a plurality of layers containing different materials. In that case, the conductive layer 151 may include a layer formed using a material that can be used for the conductive layer 152, such as a conductive oxide, and the conductive layer 152 may include a layer formed using a material that can be used for the conductive layer 151, such as a metal material. In the case where the conductive layer 151 is a stack of two or more layers, for example, a layer in contact with the conductive layer 152 can be formed using a material that can be used for the conductive layer 152.

In FIG. 5B, the conductive layer 151 has a tapered end portion. Specifically, the conductive layer 151 preferably has a tapered end portion with a taper angle less than 90°. In that case, the conductive layer 152 provided along the side surface of the conductive layer 151 also has a tapered shape. When the side surface of the conductive layer 152 has a tapered shape, coverage with the organic compound layer 103 provided along the side surface of the conductive layer 152 can be improved.

An end portion of each of the conductive layers 151 and 152 may have no tapered shape, that is, have substantially a vertical shape. The end portion of the organic compound layer 103 is preferably positioned inward from the first electrode 101. In this case, leakage current through the organic compound layer 103 can be reduced, so that a display device with a low driving voltage and favorable display performance can be obtained.

Since the light-emitting device 130 has the structure as described in Embodiments 1 and 2, the display device of one embodiment of the present invention can be a light-emitting device with high reliability.

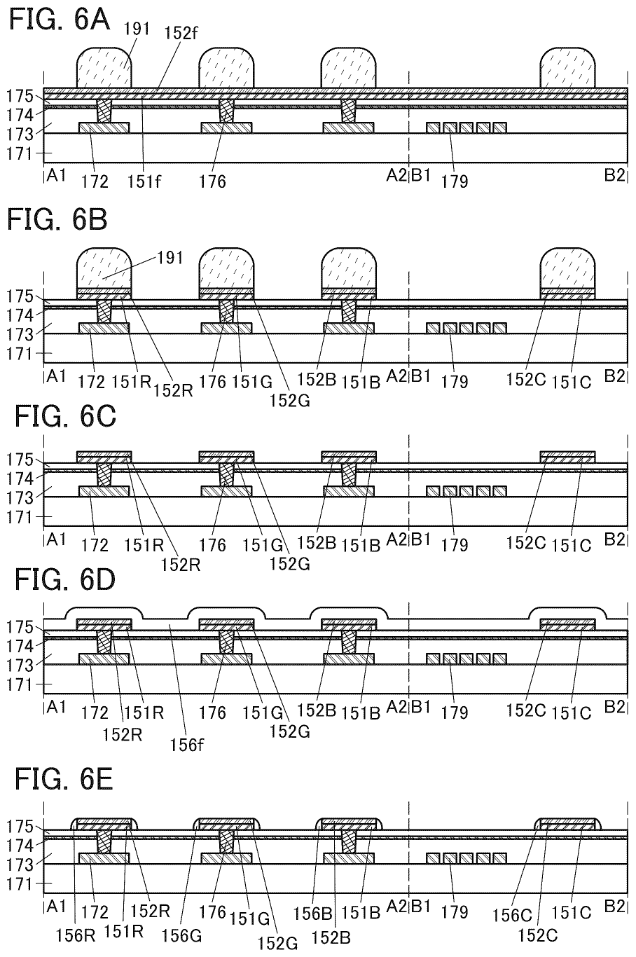

Next, a manufacturing method example of the display device having the structure illustrated in FIG. 5A is described with reference to FIGS. 6A to 6E, FIGS. 7A and 7B, FIGS. 8A to 8D, FIGS. 9A to 9C, FIGS. 10A to 10C, and FIGS. 11A and 11B.

### Manufacturing Method Example 1

Thin films included in the display device (e.g., insulating films, semiconductor films, and conductive films) can be formed by a sputtering method, a chemical vapor deposition (CVD) method, a vacuum evaporation method, a pulsed laser deposition (PLD) method, an atomic layer deposition (ALD) method, or the like.

Thin films included in the display device (e.g., insulating films, semiconductor films, and conductive films) can also be formed by a wet process such as spin coating, dipping, spray coating, ink-jetting, dispensing, screen printing, offset printing, doctor blade coating, slit coating, roll coating, curtain coating, or knife coating.

Thin films included in the display device can be processed by a photolithography method, for example.

As light used for exposure in the photolithography method, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used.

For etching of thin films, a dry etching method, a wet etching method, a sandblast method, or the like can be used.

First, as illustrated in FIG. 6A, the insulating layer 171 is formed over a substrate (not illustrated). Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate that has heat resistance high enough to withstand at least heat treatment performed later can be used. For example, it is possible to use a glass substrate; a quartz substrate; a sapphire substrate; a ceramic substrate; an organic resin substrate; or a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, as illustrated in FIG. 6A, openings reaching the conductive layer 172 are formed in the insulating layers 175, 174, and 173. Then, the plugs 176 are formed to fill the openings.

Next, as illustrated in FIG. 6A, a conductive film 151f to be the conductive layers 151R, 151G, 151B, and 151C and a conductive film 152f to be the conductive layers 152R, 152G, and 152B and a conductive layer 152C are formed over the plugs 176 and the insulating layer 175. A metal material can be used for the conductive film 151f, for example. For the conductive film 152f, an oxide containing one or more selected from indium, tin, zinc, gallium, titanium, aluminum, and silicon can be used.

Then, a resist mask 191 is formed over the conductive film 152f as illustrated in FIG. 6A. The resist mask 191 can be formed by application of a photosensitive material (photoresist), light exposure, and development.

Subsequently, as illustrated in FIG. 6B, the conductive films 151f and 152f in a region not overlapping with the resist mask 191 are removed, for example. In this manner, the conductive layers 151 and 152 are formed.

Next, the resist mask 191 is removed as illustrated in FIG. 6C. The resist mask 191 can be removed by ashing using oxygen plasma, for example.

Then, as illustrated in FIG. 6D, an insulating film 156f to be insulating layers 156R, 156G, 156B, and 156C is formed over the conductive layers 152R, 152G, 152B, and 152C and the insulating layer 175.

As the insulating film 156f, an inorganic insulating film such as an oxide insulating film, a nitride insulating film, an oxynitride insulating film, or a nitride oxide insulating film, e.g., a silicon oxynitride film, can be used.

Subsequently, as illustrated in FIG. 6E, the insulating film 156f is processed to form the insulating layers 156R, 156G, 156B, and 156C.

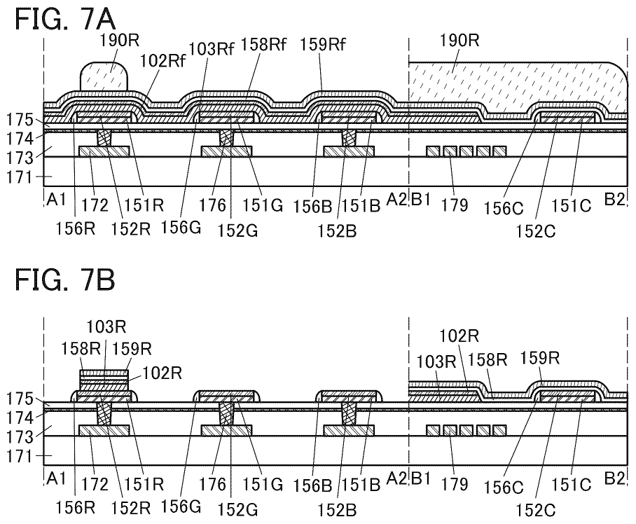

Next, as illustrated in FIG. 7A, an organic compound film 103Rf is formed over the conductive layers 152R, 152G, and 152B and the insulating layer 175. As illustrated in FIG. 7A, the organic compound film 103Rf is not formed over the conductive layer 152C.

Next, as illustrated in FIG. 7A, a conductive film 102Rf to be the second electrode is formed over the organic compound film 103Rf, and then a sacrificial film 158Rf and a mask film 159Rf are formed over the conductive film 102Rf. Forming the sacrificial film 158Rf and the mask film 159Rf over the organic compound film 103Rf through the conductive film 102Rf can reduce damage to the organic compound film 103Rf in the manufacturing process of the display device, resulting in an increase in the reliability of the light-emitting device.

In the case where the second electrode 102 is the electrode through which light is extracted, a material having a property of transmitting visible light is preferably used for the conductive film 102Rf. For example, a conductive material having a visible light reflectance higher than or equal to 20% and lower than or equal to 80%, preferably higher than or equal to 40% and lower than or equal to 70%, and a resistivity lower than or equal to 1×10⁻² Ω·cm can be used. In the case where a material with low light transmittance, such as a metal or an alloy, is used, the conductive film 102Rf may be formed to a thickness that is thin enough to transmit visible light (e.g., a thickness greater than or equal to 1 nm and less than or equal to 10 nm). Specifically, examples of the layer having the material include an oxide semiconductor layer and an organic conductive layer containing an organic substance in addition to the oxide conductive layer typified by the layer containing ITO. Examples of the organic conductive layer containing an organic substance include a layer containing a composite material in which an organic compound and an electron donor (donor) are mixed and a layer containing a composite material in which an organic compound and an electron acceptor (acceptor) are mixed. The resistivity of the transparent conductive layer is preferably lower than or equal to 1×10⁵ Ω·cm, further preferably lower than or equal to 1×10⁴ Ω·cm.

Note that the conductive film 102Rf can be deposited by a dry process such as a vacuum evaporation method or a sputtering method, an ink-jet method, a spin coating method, or the like. Alternatively, a wet process using a sol-gel method or a wet process using a paste of a metal material may be employed. The conductive film 102Rf that is formed on and in contact with the organic compound film 103Rf is particularly preferably formed by a formation method that is less likely to damage the organic compound film 103Rf. For example, the conductive film 102Rf is preferably formed by an ALD method or a vacuum evaporation method.

The sacrificial film 158Rf and the mask film 159Rf are provided as appropriate as needed. For example, in the case where the organic compound film 103Rf can be sufficiently protected by the conductive film 102Rf, the formation of the mask film 159Rf over the conductive film 102Rf makes it possible to omit the step of forming the sacrificial film 158Rf. For example, in the case where the etching selectivity between the organic compound film 103Rf and the conductive film 102Rf and the etching selectivity between the conductive film 102Rf and the sacrificial film 158Rf are sufficiently high, the step of forming the mask film 159Rf may be omitted because the sacrificial film 158Rf can be used as a mask.

As the sacrificial film 158Rf, a film that is highly resistant to the process conditions for the organic compound film 103Rf, specifically, a film having high etching selectivity with respect to the organic compound film 103Rf is used. As the mask film 159Rf, a film having high etching selectivity with respect to the sacrificial film 158Rf is used.

The conductive film 102Rf, the sacrificial film 158Rf, and the mask film 159Rf are preferably formed at a temperature lower than the upper temperature limit of the organic compound film 103Rf. The typical substrate temperatures in formation of the sacrificial film 158Rf and the mask film 159Rf are each higher than or equal to 100° C. and lower than or equal to 200° C., preferably higher than or equal to 100° C. and lower than or equal to 150° C., further preferably higher than or equal to 100° C. and lower than or equal to 120° C. Since the light-emitting device of one embodiment of the present invention contains the first compound, a display device with favorable display quality can be manufactured even through a heating step performed at higher temperatures.

The sacrificial film 158Rf and the mask film 159Rf are preferably films that can be removed by a wet etching method or a dry etching method.

Note that the sacrificial film 158Rf preferably has a denser film quality than the mask film 159Rf. For example, the sacrificial film 158Rf is preferably formed by an ALD method or a vacuum evaporation method rather than a sputtering method.

As each of the sacrificial film 158Rf and the mask film 159Rf, one or more of a metal film, an alloy film, a metal oxide film, a semiconductor film, an organic insulating film, and an inorganic insulating film can be used, for example.

For each of the sacrificial film 158Rf and the mask film 159Rf, a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials can be used, for example. It is particularly preferable to use a material containing a low-melting-point material such as aluminum or silver. It is preferable to use a metal material that can block ultraviolet rays for one or both of the sacrificial film 158Rf and the mask film 159Rf, in which case the organic compound film 103Rf can be inhibited from being irradiated with ultraviolet rays in patterning light exposure, and deterioration of the organic compound film 103Rf can be suppressed.

The sacrificial film 158Rf and the mask film 159Rf can each be formed using a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In the above metal oxide, in place of gallium, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

The sacrificial film 158Rf and the mask film 159Rf are preferably formed using a semiconductor material such as silicon or germanium for excellent compatibility with a semiconductor manufacturing process. Alternatively, a compound containing the above semiconductor material can be used.

As each of the sacrificial film 158Rf and the mask film 159Rf, any of a variety of inorganic insulating films can be used. In particular, an oxide insulating film is preferable because its adhesion to the organic compound film 103Rf is higher than that of a nitride insulating film.

Subsequently, a resist mask 190R is formed as illustrated in FIG. 7A. The resist mask 190R can be formed by application of a photosensitive material (photoresist), light exposure, and development.

The resist mask 190R is provided at a position overlapping with the conductive layer 152R. The resist mask 190R is preferably provided also at a position overlapping with the conductive layer 152C. This can inhibit the conductive layer 152C from being damaged during the process of manufacturing the display device.

Next, as illustrated in FIG. 7B, part of the mask film 159Rf is removed using the resist mask 190R, so that a mask layer 159R is formed. The mask layer 159R remains over the conductive layers 152R and 152C. After that, the resist mask 190R is removed. Then, part of the sacrificial film 158Rf and part of the conductive film 102Rf are removed using the mask layer 159R as a mask (also referred to as a hard mask), so that a sacrificial layer 158R and the second electrode 102R are formed.

The use of a wet etching method can reduce damage to the organic compound film 103Rf in processing of the conductive film 102Rf, the sacrificial film 158Rf, and the mask film 159Rf, as compared to the case of using a dry etching method. In the case of using a wet etching method, it is preferable to use a developer, an alkaline aqueous solution such as a tetramethylammonium hydroxide (TMAH) aqueous solution, or an acid aqueous solution such as dilute hydrofluoric acid, oxalic acid, phosphoric acid, acetic acid, nitric acid, or a chemical solution containing a mixed solution of any of these acids, for example.

In the case of using a dry etching method to process the sacrificial film 158Rf and the conductive film 102Rf, deterioration of the organic compound film 103Rf can be suppressed by not using a gas containing oxygen as the etching gas.

The resist mask 190R can be removed by a method similar to that for the resist mask 191.

Next, as illustrated in FIG. 7B, the organic compound film 103Rf is processed to form the organic compound layer 103R. For example, part of the conductive film 102Rf and part of the organic compound film 103Rf are removed using the mask layer 159R and the sacrificial layer 158R as a hard mask, whereby the organic compound layer 103R is formed.

Accordingly, as illustrated in FIG. 7B, the stacked-layer structure of the organic compound layer 103R, the second electrode 102R, the sacrificial layer 158R, and the mask layer 159R remains over the conductive layer 152R. The conductive layers 152G and 152B are exposed.

The organic compound film 103Rf is preferably processed by anisotropic etching. Anisotropic dry etching is particularly preferable. Alternatively, wet etching may be used.

In the case of using a dry etching method, deterioration of the organic compound film 103Rf can be suppressed by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Accordingly, damage to the organic compound film 103Rf can be reduced. Furthermore, a defect such as attachment of a reaction product generated during the etching can be inhibited.

In the case of using a dry etching method, it is preferable to use a gas containing at least one of H₂, CF₄, C₄F₈, SF₆, CHF₃, Cl₂, H₂O, BCl₃, and a Group 18 element such as He or Ar as the etching gas, for example. Alternatively, a gas containing oxygen and at least one of the above is preferably used as the etching gas. Alternatively, an oxygen gas may be used as the etching gas.

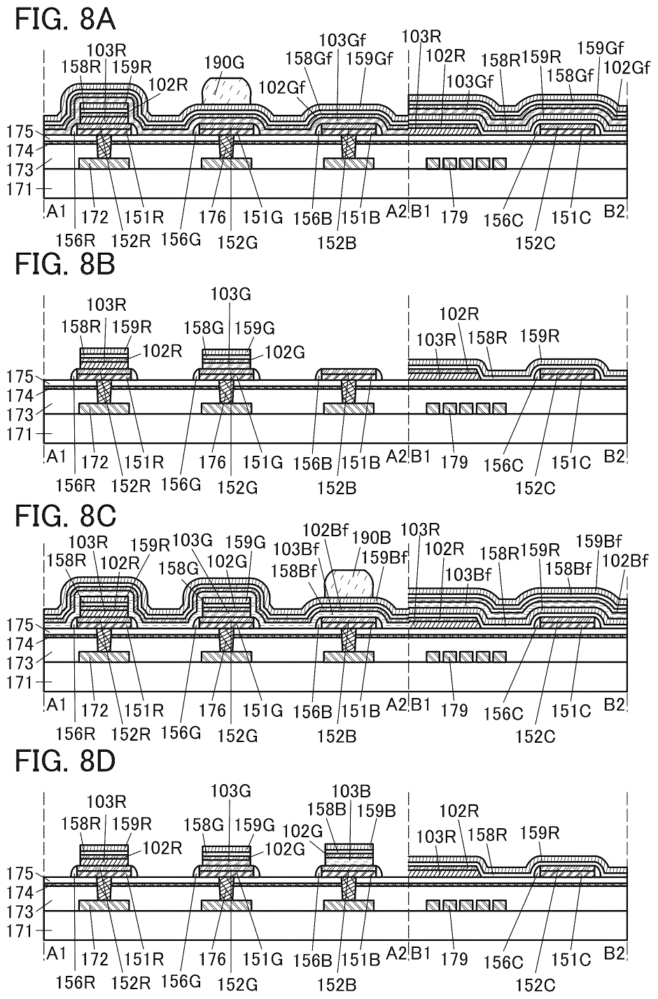

Then, as illustrated in FIG. 8A, an organic compound film 103Gf to be the organic compound layer 103G and a conductive film 102Gf to be the second electrode 102G are formed.

The organic compound film 103Gf can be formed by a method similar to that for forming the organic compound film 103Rf. The organic compound film 103Gf can have a structure similar to that of the organic compound film 103Rf. The conductive film 102Gf can be formed by a method similar to that for forming the conductive film 102Rf. The conductive film 102Gf can have a structure similar to that of the conductive film 102Rf.

Subsequently, as illustrated in FIG. 8A, a sacrificial film 158Gf and a mask film 159Gf are formed in this order. After that, a resist mask 190G is formed. The materials and the formation methods of the sacrificial film 158Gf and the mask film 159Gf are similar to those for the sacrificial film 158Rf and the mask film 159Rf. The material and the formation method of the resist mask 190G are similar to those for the resist mask 190R.

The resist mask 190G is provided at a position overlapping with the conductive layer 152G.

Subsequently, as illustrated in FIG. 8B, part of the mask film 159Gf is removed using the resist mask 190G, so that a mask layer 159G is formed. The mask layer 159G remains over the conductive layer 152G. After that, the resist mask 190G is removed. Then, part of the sacrificial film 158Gf and part of the conductive film 102Gf are removed using the mask layer 159G as a mask, so that a sacrificial layer 158G and the second electrode 102G are formed. Next, the organic compound film 103Gf is processed to form the organic compound layer 103G.

Then, an organic compound film 103Bf and a conductive film 102Bf to be the second electrode 102B are formed as illustrated in FIG. 8C.

The organic compound film 103Bf can be formed by a method similar to that for forming the organic compound film 103Rf. The organic compound film 103Bf can have a structure similar to that of the organic compound film 103Rf. The conductive film 102Bf can be formed by a method similar to that for forming the conductive film 102Rf. The conductive film 102Bf can have a structure similar to that of the conductive film 102Rf.

Subsequently, a sacrificial film 158Bf and a mask film 159Bf are formed in this order as illustrated in FIG. 8C. After that, a resist mask 190B is formed. The materials and the formation methods of the sacrificial film 158Bf and the mask film 159Bf are similar to those for the sacrificial film 158Rf and the mask film 159Rf. The material and the formation method of the resist mask 190B are similar to those for the resist mask 190R.

The resist mask 190B is provided at a position overlapping with the conductive layer 152B.

Subsequently, as illustrated in FIG. 8D, part of the mask film 159Bf is removed using the resist mask 190B, so that a mask layer 159B is formed. The mask layer 159B remains over the conductive layer 152B. After that, the resist mask 190B is removed. Then, part of the sacrificial film 158Bf and part of the conductive film 102Bf are removed using the mask layer 159B as a mask, so that the sacrificial layer 158B and the second electrode 102B are formed. Next, the organic compound film 103Bf is processed, so that the organic compound layer 103B is formed. For example, part of the organic compound film 103Bf is removed using the mask layer 159B and the sacrificial layer 158B as a hard mask to form the organic compound layer 103B.

Accordingly, the stacked-layer structure of the organic compound layer 103B, the second electrode 102B, the sacrificial layer 158B, and the mask layer 159B remains over the conductive layer 152B as illustrated in FIG. 8D. The mask layers 159R and 159G are exposed.

Note that the side surfaces of each of the stacked-layer structure of the organic compound layer 103R and the second electrode 102R, the stacked-layer structure of the organic compound layer 103G and the second electrode 102G, and the stacked-layer structure of the organic compound layer 103B and the second electrode 102B are preferably perpendicular or substantially perpendicular to each of the formation surfaces. For example, the angle between the formation surfaces and these side surfaces is preferably greater than or equal to 60° and less than or equal to 90°.

The distance between two adjacent structures among the stacked-layer structure of the organic compound layer 103R and the second electrode 102R, the stacked-layer structure of the organic compound layer 103G and the second electrode 102G, and the stacked-layer structure of the organic compound layer 103B and the second electrode 102B, which are formed by a photolithography method as described above, can be reduced to less than or equal to 8 μm, less than or equal to 5 μm, less than or equal to 3 μm, less than or equal to 2 μm, or less than or equal to 1 μm. Here, the distance can be specified, for example, by the distance between opposite end portions of two adjacent layers among the organic compound layers 103R, 103G, and 103B. Reducing the distance between the island-shaped organic compound layers makes it possible to provide a display device having high resolution and a high aperture ratio. In addition, the distance between the first electrodes of adjacent light-emitting devices can also be shortened to be, for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 μm and less than or equal to 5 μm.

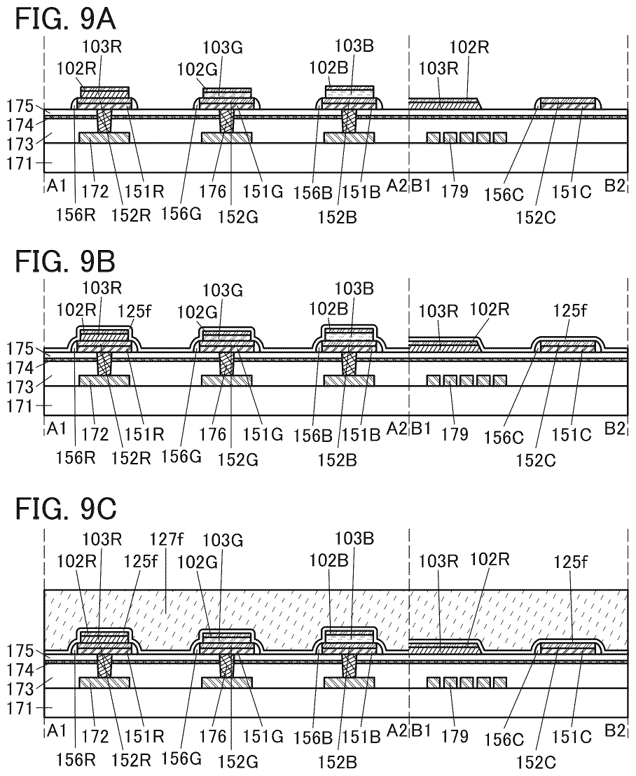

Next, the mask layers 159R, 159G, and 159B are preferably removed as illustrated in FIG. 9A.

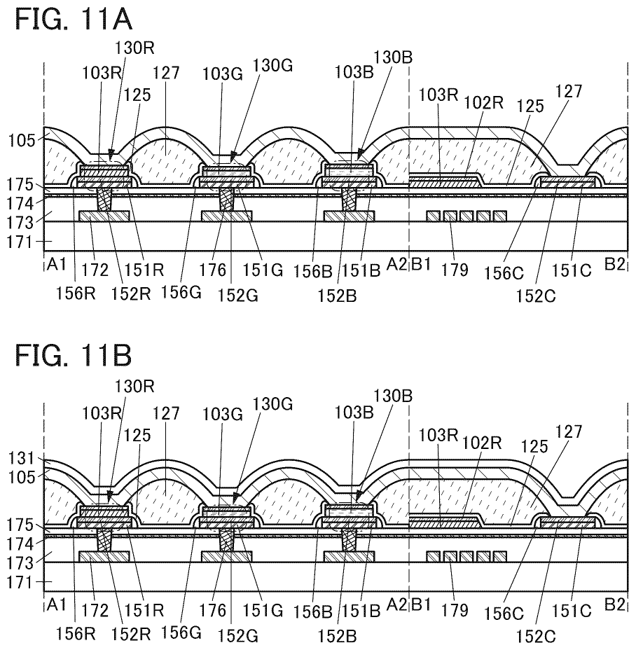

Note that in the case where the light-emitting devices are arranged in what is called a stripe pattern as illustrated in FIG. 23G, the second electrode 102 can be continuously provided over the light-emitting devices that exhibit the same emission color. In that case, since the auxiliary electrode 105 described later is not necessarily formed, the mask layer 159 is not necessarily removed in the case of a bottom-emission light-emitting device; thus, the process may proceed to the step in FIG. 11B after the step in FIG. 8D. In the case of a top-emission light-emitting device, the sacrificial layer 158 and the mask layer 159 are not necessarily removed when the layers have a light-transmitting property, and the process can proceed to the step in FIG. 11B after the step in FIG. 8D. In the case where the sacrificial layer 158 and the mask layer 159 do not have a light-transmitting property, the layers are preferably removed, and after removal of the sacrificial layer 158 and/or the mask layer 159 (after the step in FIG. 9A), the process can proceed to the step in FIG. 11B.

The step of removing the mask layer can be performed by a method similar to that for the step of processing the mask film. Specifically, by using a wet etching method, damage to the organic compound layer 103 at the time of removing the mask layers can be reduced as compared to the case of using a dry etching method.

The mask layers may be removed by being dissolved in a polar solvent such as water or an alcohol. Examples of an alcohol include ethyl alcohol, methyl alcohol, isopropyl alcohol (IPA), and glycerin.

After the mask layers are removed, drying treatment may be performed in order to remove water adsorbed on surfaces. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, an inorganic insulating film 125f is formed as illustrated in FIG. 9B.

Then, as illustrated in FIG. 9C, an insulating film 127f to be the insulating layer 127 is formed over the inorganic insulating film 125f.

The substrate temperature at the time of forming the inorganic insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the inorganic insulating film 125f, an insulating film having a thickness of 3 nm or more, 5 nm or more, or 10 nm or more and 200 nm or less, 150 nm or less, 100 nm or less, or 50 nm or less is preferably formed at a substrate temperature in the above-described range.

The inorganic insulating film 125f is preferably formed by an ALD method, for example. An ALD method is preferably used, in which case deposition damage is reduced and a film with good coverage can be formed. As the inorganic insulating film 125f, an aluminum oxide film is preferably formed by an ALD method, for example.

The insulating film 127f is preferably formed by the aforementioned wet film-formation method. For example, the insulating film 127f is preferably formed by spin coating using a photosensitive material, and specifically preferably formed using a photosensitive resin composition containing an acrylic resin.

Then, part of the insulating film 127f is exposed to visible light or ultraviolet rays. The insulating layer 127 is formed in regions that are sandwiched between any two of the conductive layers 152R, 152G, and 152B and around the conductive layer 152C.

The width of the insulating layer 127 formed later can be controlled in accordance with the exposed region of the insulating film 127f. In this embodiment, processing is performed such that the insulating layer 127 includes a portion overlapping with the top surface of the conductive layer 151.

Light used for the exposure preferably includes the i-line (wavelength: 365 nm). Furthermore, light used for the exposure may include at least one of the g-line (wavelength: 436 nm) and the h-line (wavelength: 405 nm).

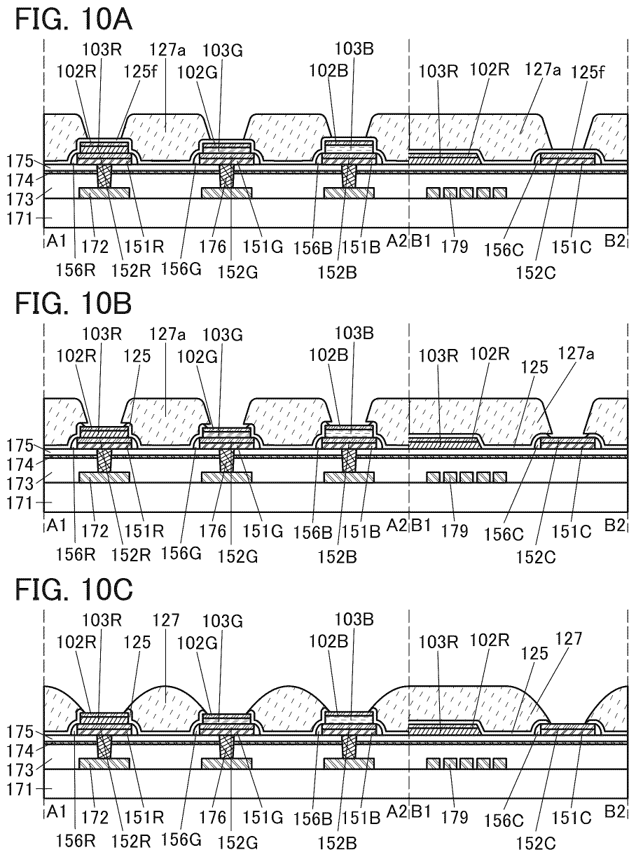

Next, the region of the insulating film 127f exposed to light is removed by development as illustrated in FIG. 10A, so that an insulating layer 127a is formed.

Next, as illustrated in FIG. 10B, etching treatment is performed with the insulating layer 127a as a mask to remove part of the inorganic insulating film 125f. Note that in the case where the sacrificial layer 158 is left, the thickness of part of the sacrificial layers 158R, 158G, and 158B is reduced. Thus, the inorganic insulating layer 125 is formed under the insulating layer 127a. Moreover, the surfaces of the thin portions in the sacrificial layers 158R, 158G, and 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that for the sacrificial layers 158R, 158G, and 158B, in which case the first etching treatment can be performed concurrently. In the case where the sacrificial layer 158 is not formed, the surfaces of the second electrodes 102R, 102B, and 102G are exposed by the first etching treatment.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. For example, in the case where the sacrificial layer 158 is left, by the dry etching, the thin regions of the sacrificial layers 158R, 158G, and 158B can be formed with favorable in-plane uniformity. As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used.

The first etching treatment is preferably performed by wet etching. The use of a wet etching method can reduce damage to the structure to be processed, as compared to the case of using a dry etching method. Wet etching can be performed using an alkaline solution, for example. For instance, TMAH, which is an alkaline solution, can be used for the wet etching of an aluminum oxide film. Alternatively, an acid solution containing fluoride can also be used. In this case, puddle wet etching can be performed. Note that the inorganic insulating film 125f is preferably formed using a material similar to that for the sacrificial layers 158R, 158G, and 158B, in which case the first etching treatment can be performed concurrently.

The sacrificial layers 158R, 158G, and 158B are not removed completely by the first etching treatment, and the etching treatment is stopped when the thicknesses of the sacrificial layers 158R, 158G, and 158B are reduced. The sacrificial layers 158R, 158B, and 158G remain over the second electrodes 102R, 102B, and 102G, respectively, in this manner, whereby the structure body including the organic compound layer 103 can be prevented from being damaged by treatment in a later step.

Next, light exposure is preferably performed on the entire substrate so that the insulating layer 127a is irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a into a tapered shape.

Here, when a barrier insulating layer against oxygen (e.g., an aluminum oxide film) exists as each of the sacrificial layers 158R, 158G, and 158B, diffusion of oxygen into the second electrodes 102R, 102G, and 102B or a reduction in conductivity due to metal oxidation can be inhibited.

Then, heat treatment (also referred to as post-baking) is performed. The heat treatment can change the insulating layer 127a into the insulating layer 127 having a tapered side surface (FIG. 10C). The heat treatment is conducted at a temperature lower than the upper temperature limit of the organic compound layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. Accordingly, adhesion between the insulating layer 127 and the inorganic insulating layer 125 can be improved, and corrosion resistance of the insulating layer 127 can be increased.

When the sacrificial layers 158R, 158G, and 158B are not completely removed by the first etching treatment and the thinned sacrificial layers 158R, 158G, and 158B are left, the structure to be processed including the organic compound layer 103 can be prevented from being damaged and deteriorating in the heat treatment. This can increase the reliability of the light-emitting device.

Next, as illustrated in FIG. 11A, etching treatment is performed with the insulating layer 127 as a mask. In the case where the sacrificial layer 158 is left, part of the sacrificial layers 158R, 158G, and 158B is removed. Thus, openings are formed in the sacrificial layers 158R, 158G, and 158B, and the top surfaces of the second electrodes 102R, 102G, and 102B and the conductive layer 152C are exposed. Note that this etching treatment may be hereinafter referred to as second etching treatment.

Note that in the case where the sacrificial layer 158 is not formed, the surfaces of the second electrodes 102R, 102B, and 102G are exposed by the first etching treatment; thus, the second etching treatment described later can be omitted.

An end portion of the inorganic insulating layer 125 is covered with the insulating layer 127. In the case where the sacrificial layer 158 is left, part of an end portion of the sacrificial layer 158G (specifically, a tapered portion formed by the first etching treatment) is covered with the insulating layer 127 and a tapered portion formed by the second etching treatment is exposed. The second etching treatment is performed by wet etching. The use of a wet etching method can reduce damage to the organic compound layers 103R, 103G, and 103B, as compared to the case of using a dry etching method. Wet etching can be performed using an alkaline solution or an acidic solution, for example. An aqueous solution is preferably used in order that the organic compound layer 103 is not dissolved.

Next, as illustrated in FIG. 11B, the auxiliary electrode 105 is formed over the second electrodes 102R, 102B, and 102G, the conductive layer 152C, and the insulating layer 127. The auxiliary electrode 105 can be formed by a sputtering method, a vacuum evaporation method, or the like.

Next, as illustrated in FIG. 11B, the protective layer 131 is formed over the auxiliary electrode 105. The protective layer 131 can be formed by a vacuum evaporation method, a sputtering method, a CVD method, an ALD method, or the like.

Then, the substrate 120 is bonded onto the protective layer 131 using the resin layer 122, so that the display device can be manufactured. In the method for manufacturing the display device of one embodiment of the present invention, the insulating layer 156 (the insulating layers 156R, 156G, and 156B) is formed to include a region overlapping with the side surface of the conductive layer 151 and the conductive layer 152 is formed to cover the conductive layer 151 and the insulating layer 156 as described above. This can increase the yield of the display device and inhibit generation of defects.

As described above, in the method for manufacturing the display device of one embodiment of the present invention, the island-shaped organic compound layers 103R, 103G, and 103B are formed not by using a fine metal mask but by processing a film formed on the entire surface; thus, the island-shaped layers can be formed to have a uniform thickness. Consequently, a high-resolution display device or a display device with a high aperture ratio can be obtained. Furthermore, even when the resolution or the aperture ratio is high and the distance between the subpixels is extremely short, the organic compound layers 103R, 103G, and 103B can be inhibited from being in contact with each other in the adjacent subpixels. As a result, generation of leakage current between the subpixels can be inhibited. This can prevent crosstalk, so that a display device with extremely high contrast can be obtained. Moreover, even a display device that includes tandem light-emitting devices manufactured by a photolithography method can have favorable characteristics.

### Embodiment 4

In this embodiment, a display device of one embodiment of the present invention will be described.

The display device in this embodiment can be a high-resolution display device. Thus, the display device in this embodiment can be used for display portions of information terminals (wearable devices) such as watch-type and bracelet-type information terminals and display portions of wearable devices capable of being worn on a head, such as a VR device like a head mounted display (HMD) and a glasses-type AR device.

The display device in this embodiment can be a high-definition display device or a large-sized display device. Accordingly, the display device in this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, desktop and laptop personal computers, a monitor of a computer and the like, digital signage, and a large game machine such as a pachinko machine.

### [Display Module]

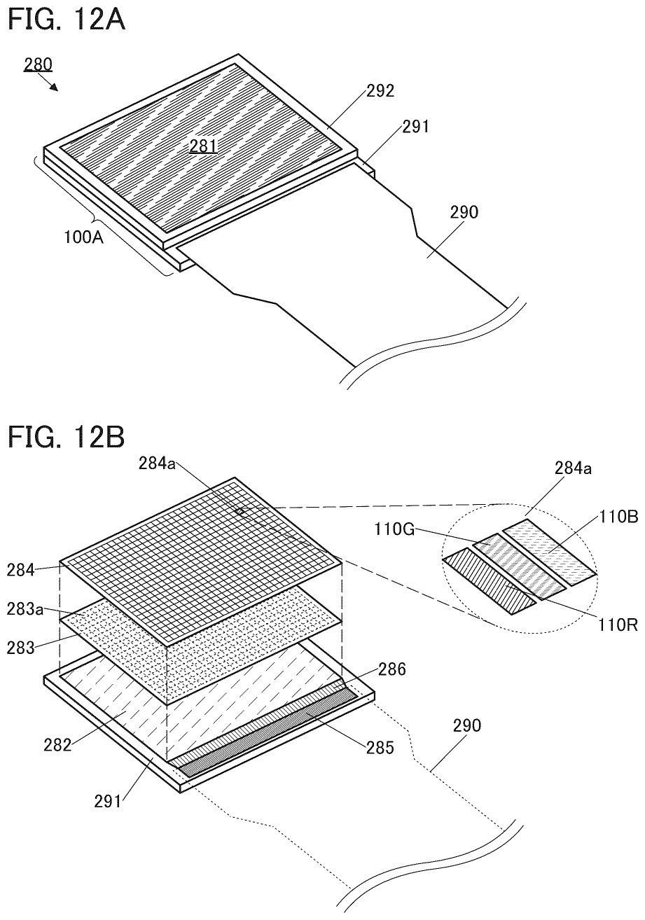

FIG. 12A is a perspective view of a display module 280. The display module 280 includes a display device 100A and an FPC 290. Note that the display device included in the display module 280 is not limited to the display device 100A and may be any of display devices 100B and 100E described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 12B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 12B. The pixels 284a can employ any of the structures described in the above embodiments. FIG. 12B illustrates an example where the pixel 284a has a structure similar to that of the pixel 178 illustrated in FIGS. 5A and 5B.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic devices including a relatively small display portion.

### [Display Device 100A]

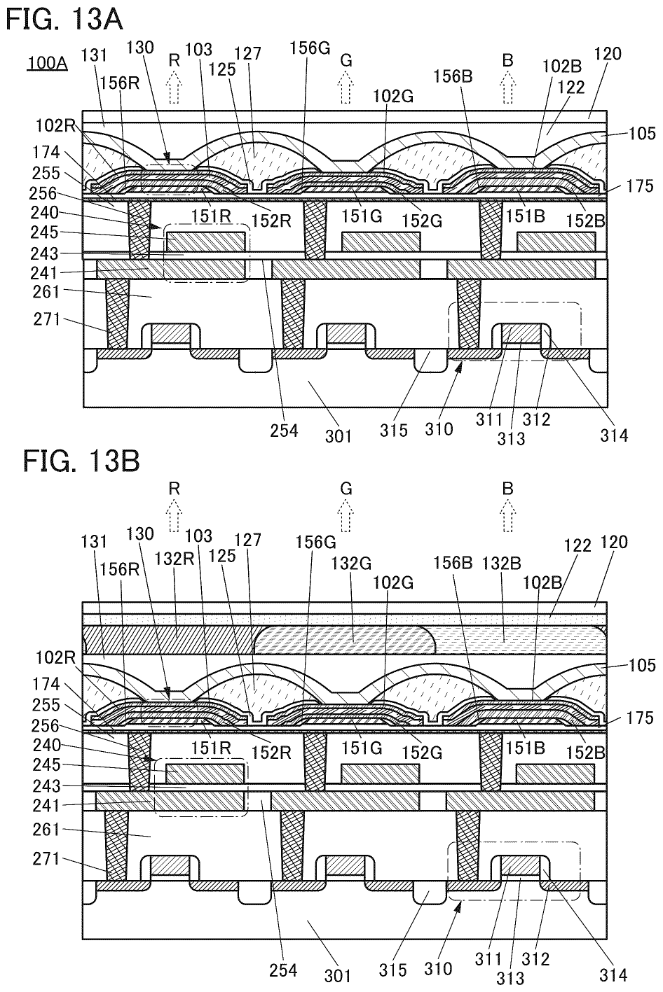

The display device 100A illustrated in FIG. 13A includes a substrate 301, the light-emitting devices 130R, 130G, and 130B, a capacitor 240, and a transistor 310.

The substrate 301 corresponds to the substrate 291 illustrated in FIGS. 12A and 12B. The transistor 310 includes a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. An insulator is provided in regions between adjacent light-emitting devices.

The insulating layer 156R is provided to include a region overlapping with the side surface of the conductive layer 151R. The insulating layer 156G is provided to include a region overlapping with the side surface of the conductive layer 151G. The insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. Note that the insulating layer 156 is not necessarily provided.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. Any of a variety of conductive materials can be used for the plugs.

The protective layer 131 is provided over the light-emitting devices 130R, 130G, and 130B with the auxiliary electrode 105 therebetween. The substrate 120 is bonded to the protective layer 131 with the resin layer 122. Embodiment 3 can be referred to for the details of the light-emitting device 130 and the components thereover up to the substrate 120. The substrate 120 corresponds to the substrate 292 in FIG. 12A.

FIG. 13B illustrates a variation example of the display device 100A illustrated in FIG. 13A. The display device illustrated in FIG. 13B includes coloring layers 132R, 132G, and 132B, and each of the light-emitting devices 130 includes a region overlapping with one of the coloring layers 132R, 132G, and 132B. In the display device illustrated in FIG. 13B, the light-emitting device 130 can emit white light, for example. The coloring layer 132R, the coloring layer 132G, and the coloring layer 132B can transmit red light, green light, and blue light, respectively, for example.

### [Display Device 100B]

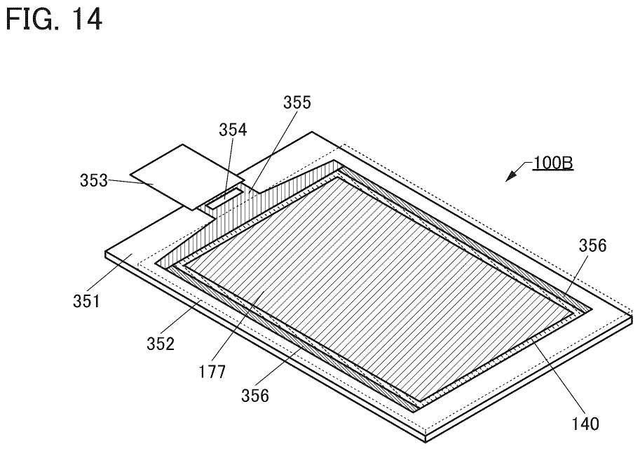

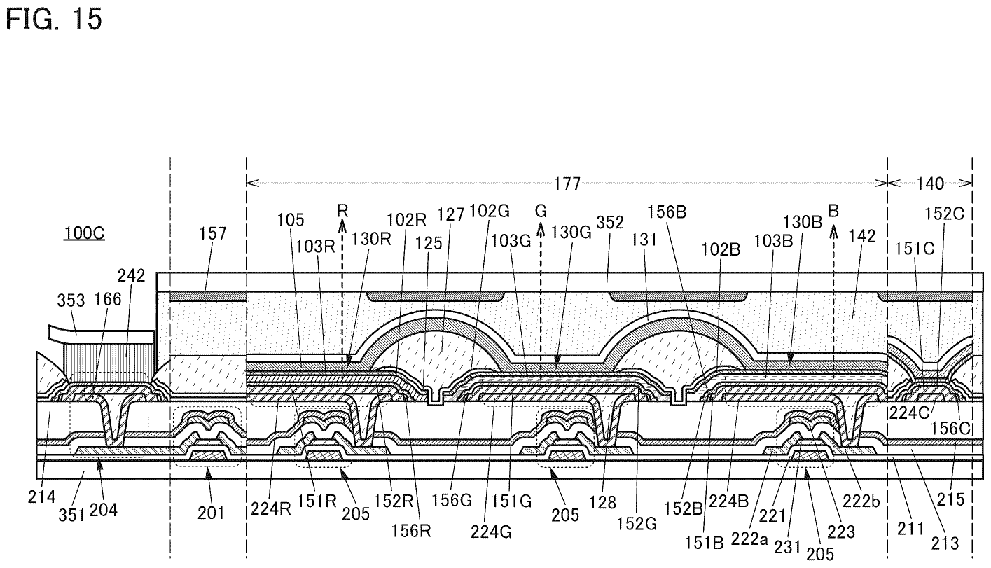

FIG. 14 is a perspective view of the display device 100B, and FIG. 15 is a cross-sectional view of the display device 100B.

In the display device 100B, a substrate 352 and a substrate 351 are bonded to each other. In FIG. 14, the substrate 352 is denoted by a dashed line.

The display device 100B includes the pixel portion 177, the connection portion 140, a circuit 356, a wiring 355, and the like. FIG. 14 illustrates an example where an IC 354 and an FPC 353 are mounted on the display device 100B. Thus, the structure illustrated in FIG. 14 can be regarded as a display module including the display device 100B, the integrated circuit (IC), and the FPC. Here, a display device in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 14 illustrates an example in which the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display device 100B and the display module are not necessarily provided with an IC. Alternatively, the IC may be mounted on the FPC by a COF method, for example.

FIG. 15 illustrates an example of cross sections of part of a region including the FPC 353, part of the circuit 356, part of the pixel portion 177, and part of the connection portion 140 of the display device 100C.

### [Display Device 100C]

The display device 100C illustrated in FIG. 15 includes a transistor 201, a transistor 205, the light-emitting device 130R that emits red light, the light-emitting device 130G that emits green light, the light-emitting device 130B that emits blue light, and the like between the substrate 351 and the substrate 352.

Embodiment 1 or 2 can be referred to for the details of the light-emitting devices 130R, 130G, and 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through an opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G and the insulating layer 156G in the light-emitting device 130G are not described in detail because they are respectively similar to the conductive layers 224R, 151R, and 152R and the insulating layer 156R in the light-emitting device 130R; the same applies to the conductive layers 224B, 151B, and 152B and the insulating layer 156B in the light-emitting device 130B.

The conductive layers 224R, 224G, and 224B each have a depressed portion covering the opening provided in the insulating layer 214. A layer 128 is embedded in the depressed portion.

The layer 128 has a function of filling the depressed portions of the conductive layers 224R, 224G, and 224B to obtain planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depressed portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting devices 130R, 130G, and 130B with the auxiliary electrode 105 therebetween. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 15, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap with the light-emitting device. Alternatively, the space may be filled with a resin other than the frame-like adhesive layer 142.

FIG. 15 illustrates an example where the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and the conductive layer 152C obtained by processing the same conductive film as the conductive layers 152R, 152G, and 152B. In the example illustrated in FIG. 15, the insulating layer 156C is provided to include a region overlapping with the side surface of the conductive layer 151C.

The display device 100C has a top-emission structure. Light from the light-emitting device is emitted toward the substrate 352. For the substrate 352, a material with a high visible-light-transmitting property is preferably used. The pixel electrode contains a material that reflects visible light, and the counter electrode (the second electrode 102) and the auxiliary electrode 105 contain a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

An inorganic insulating film is preferably used as each of the insulating layers 211, 213, and 215.

An organic insulating layer is suitable as the insulating layer 214 functioning as a planarization layer.

Each of the transistors 201 and 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate.

A connection portion 204 is provided in a region of the substrate 351 not overlapping with the substrate 352. In the connection portion 204, one of the source electrode and the drain electrode of the transistor 201 is electrically connected to the FPC 353 through a conductive layer 166 and a connection layer 242. As an example, the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided over a region between adjacent light-emitting devices, in the connection portion 140, in the circuit 356, and the like. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Display Device 100D]

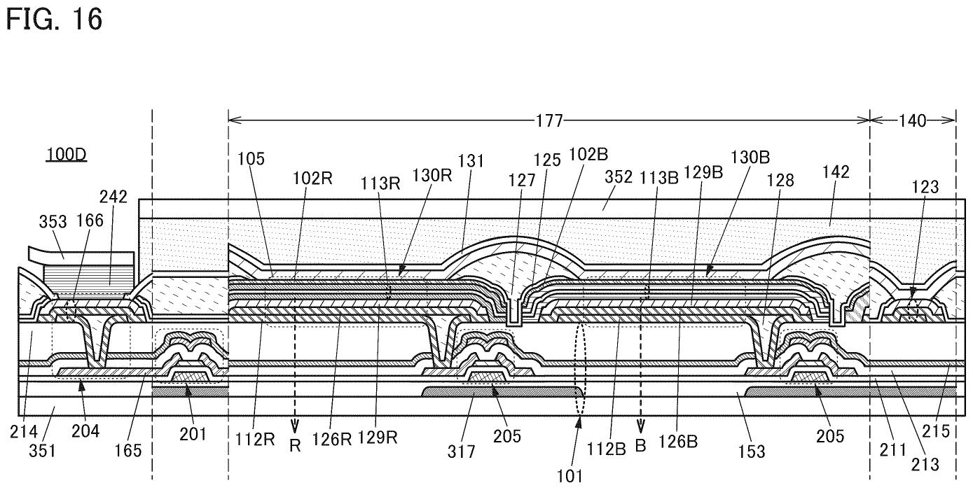

The display device 100D illustrated in FIG. 16 differs from the display device 100C illustrated in FIG. 15 mainly in having a bottom-emission structure.

Light from the light-emitting device is emitted toward the substrate 351. For the substrate 351, a material with a high visible-light-transmitting property is preferably used. By contrast, there is no limitation on the light-transmitting property of a material used for the substrate 352.

A light-blocking layer 317 is preferably formed between the substrate 351 and the transistor 201 and between the substrate 351 and the transistor 205. FIG. 16 illustrates an example where the light-blocking layer 317 is provided over the substrate 351, an insulating layer 153 is provided over the light-blocking layer 317, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material with a high visible-light-transmitting property is used for each of the conductive layers 112R, 112B, 126R, 126B, 129R, and 129B. A material that reflects visible light is preferably used for the second electrode 102.

Although not illustrated in FIG. 16, the light-emitting device 130G is also provided.

Although FIG. 16 and the like illustrate an example in which the top surface of the layer 128 includes a flat portion, the shape of the layer 128 is not particularly limited.

### [Display Device 100D2]

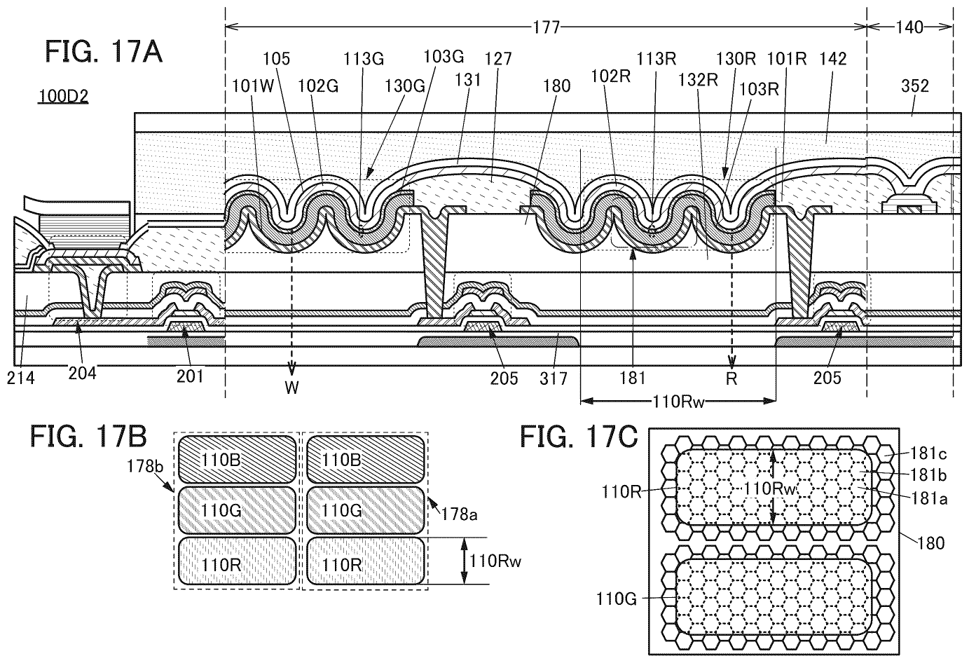

The display device 100D2 illustrated in FIG. 17A is an example of a bottom-emission display device different from the display device 100D illustrated in FIG. 16. The display device 100D2 is different from the display device 100D in including an organic resin layer 180. Note that the reference numerals of the components that are the same as those in FIG. 16 are sometimes omitted and the description for FIG. 16 can be referred to for the details of such components.

FIG. 17B is a top-view layout of the pixel 178 (pixels 178a and 178b) including the subpixel 110 (the subpixels 110R, 110G, and 110B), and FIG. 17C is a top view of the organic resin layer 180 in a region where the subpixels 110R and 110G included in the pixel 178 are formed. A region of the subpixel 110R between the light-blocking layers 317 can be represented as a width 110Rw in a light-emitting region.

As illustrated in FIG. 17A, the organic resin layer 180 is provided over the insulating layer 214. As illustrated in FIG. 17C and the region surrounded by the dashed-dotted line in FIG. 17A, the organic resin layer 180 includes a depressed portion 181 (depressed portions 181a and 181b) having a curved surface at least in a region where the subpixel is formed. Note that the depressed portion 181 may be provided outside the light-emitting region, like a depressed portion 181c. With the depressed portion 181c, light emission caused in a region overlapping with the light-blocking layer 317 or light that has progressed to the region overlapping with the light-blocking layer 317 can be refracted and extracted from the light-emitting region, whereby emission efficiency can be improved.

A plurality of depressed portions 181 may be formed in a matrix. The depressed portions 181a and 181b may be provided in contact with each other or may have a flat surface therebetween.

Although the top surface shape and the cross-sectional shape of the depressed portion are hexagonal (FIG. 17C) and semicircular (FIG. 17A), respectively, other shapes may be employed as needed. Examples of the top surface shape of the depressed portion include polygons such as a triangle, a tetragon (including a rectangle and a square), and a pentagon; these polygons with rounded corners; an ellipse; and a circle.

An insulating layer containing an organic material can be used as the organic resin layer 180. Examples of materials used for the organic resin layer 180 include an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. The organic resin layer 180 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin.

A photosensitive resin can also be used for the organic resin layer 180. A photoresist may be used for the photosensitive resin. As the photosensitive resin, a positive photosensitive material or a negative photosensitive material can be used.

The organic resin layer 180 may contain a material absorbing visible light. For example, the organic resin layer 180 itself may be made of a material absorbing visible light, or the organic resin layer 180 may contain a pigment absorbing visible light. For example, the organic resin layer 180 can be formed using a resin that can be used as a color filter transmitting red, blue, or green light and absorbing light of the other colors; or a resin that contains carbon black as a pigment and functions as a black matrix.

The first electrode 101 is over the organic resin layer 180, the organic compound layer 103 is over the first electrode 101, and the second electrode 102 is over the organic compound layer 103. End portions of the first electrode 101, the organic compound layer 103, and the second electrode 102 may be covered with the insulating layer 127.

The first electrode 101 formed over the organic resin layer 180 also has a depressed portion along the depressed portion of the organic resin layer 180. The organic compound layer 103 formed over the first electrode 101 also has a depressed portion along the depressed portion of the first electrode 101. The second electrode 102 formed over the organic compound layer 103 also has a depressed portion along the depressed portion of the organic compound layer 103. The auxiliary electrode 105 formed over the second electrode 102 also has a depressed portion along the depressed portion of the second electrode 102. That is, the depressed portions of the organic resin layer 180, the first electrode 101, the organic compound layer 103, the second electrode 102, and the auxiliary electrode 105 overlap with each other.

The second electrode 102 is over the organic compound layer 103 and the insulating layer 127, and the auxiliary electrode 105 is over the second electrode 102. The protective layer 131 is provided over the auxiliary electrode 105 and bonded to the substrate 352 with the adhesive layer 142 therebetween.

Although the light-emitting devices 130G and 130B are not illustrated in FIGS. 17A to 17C, the light-emitting devices 130G and 130B are also provided.

The light-emitting device of one embodiment of the present invention including the above-described organic resin layer 180 has a structure as described in Embodiment 1 or 2. Accordingly, an organic semiconductor device with low driving voltage and favorable characteristics can be provided.

### [Display Device 100E]

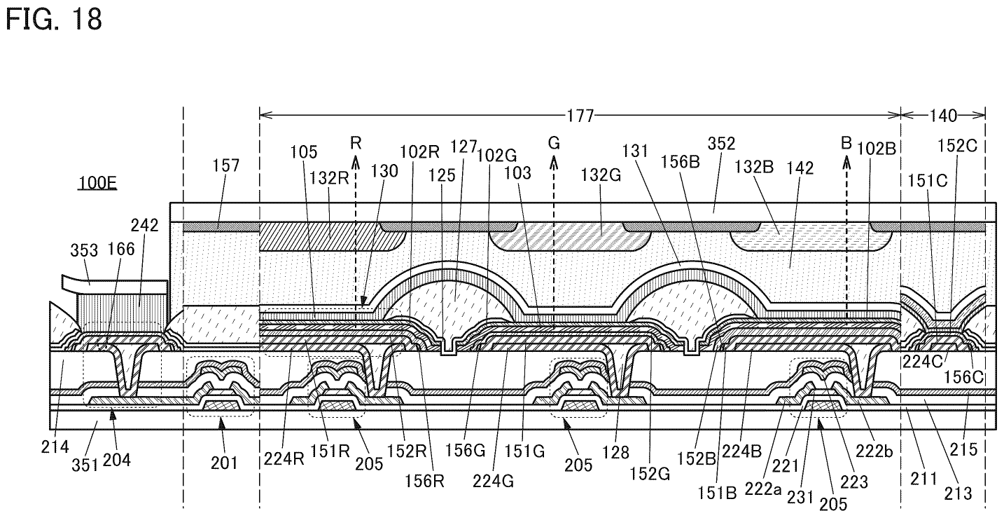

The display device 100E illustrated in FIG. 18 is a variation example of the display device 100C illustrated in FIG. 15 and differs from the display device 100C mainly in including the coloring layers 132R, 132G, and 132B.

In the display device 100E, the light-emitting device 130 includes a region overlapping with one of the coloring layers 132R, 132G, and 132B. The coloring layers 132R, 132G, and 132B can be provided on a surface of the substrate 352 on the substrate 351 side. End portions of the coloring layers 132R, 132G, and 132B can overlap with the light-blocking layer 157.

In the display device 100E, the coloring layer 132R, the coloring layer 132G, and the coloring layer 132B can transmit red light, green light, and blue light, respectively, for example. Note that in the display device 100E, the coloring layers 132R, 132G, and 132B may be provided between the protective layer 131 and the adhesive layer 142.

### [Display Device 100E2]

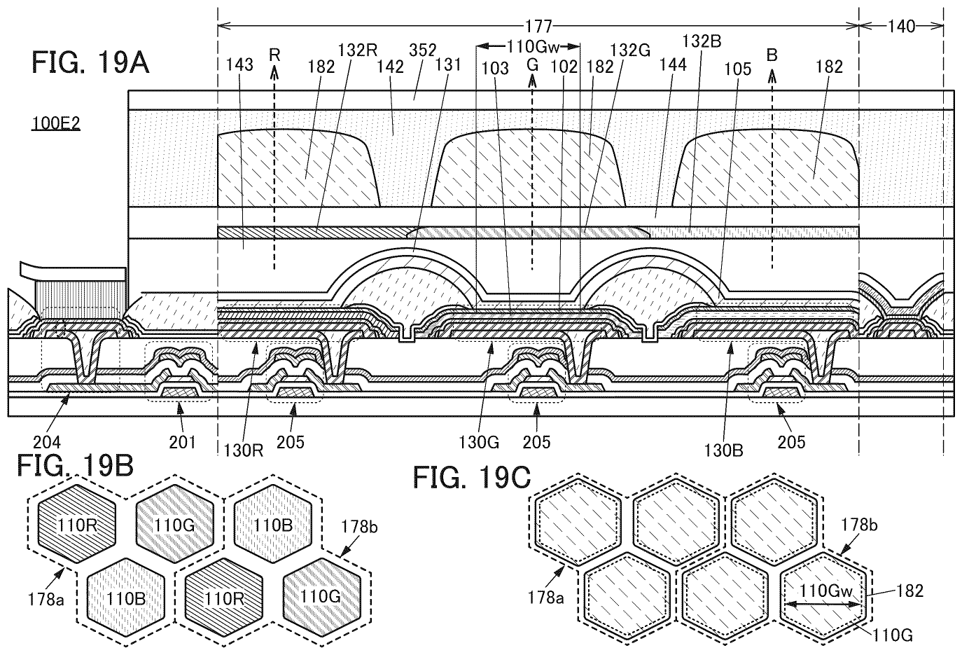

A display device 100E2 illustrated in FIGS. 19A to 19C is a variation example of the display device 100E illustrated in FIG. 18 and includes microlenses 182 over the coloring layers 132R, 132G, and 132B. Note that the reference numerals of the components that are the same as those in FIG. 18 are sometimes omitted and the description for FIG. 18 is preferably referred to for the details of such components.

FIG. 19B is a top-view layout of the pixel 178 (the pixels 178a and 178b) including the subpixel 110 (the subpixels 110R, 110G, and 110B), and FIG. 19C is a top view of the microlens 182 in a region where the subpixels 110R and 110G included in the pixel 178 are formed. A region of the subpixel 110G where the auxiliary electrode 105 and the organic compound layer 103 are in contact with each other can be represented as a width 110Gw in a light-emitting region.

In the display device 100E2 illustrated in FIG. 19A, a planarization film 143 is provided over the protective layer 131, and the coloring layers 132R, 132G, and 132B are provided over a planarization film 143. The planarization film 144 is provided to cover the coloring layers 132R, 132G, and 132B. The microlenses 182 are provided over the planarization film 144.

Note that as illustrated in FIG. 19C, the microlens 182 is preferably provided for each of the subpixels in a region where the subpixel is formed.

Although the top surface shape of the depressed portion is illustrated as a hexagon in FIG. 19C, other shapes may be employed as needed. Examples of top surface shapes of the microlens 182 include polygons such as a triangle, a tetragon (including a rectangle and a square), and a pentagon; these polygons with rounded corners; an ellipse; and a circle.

The microlens 182 can be formed using a material similar to that for the organic resin layer 180.

This embodiment can be combined as appropriate with the other embodiments or the examples. In this specification, in the case where a plurality of structure examples are shown in one embodiment, the structure examples can be combined as appropriate.

### Embodiment 5

In this embodiment, electronic appliances of embodiments of the present invention will be described.

Electronic appliances of this embodiment include the display device of one embodiment of the present invention in their display portions. The display device of one embodiment of the present invention has high display performance and can be easily increased in resolution and definition. Thus, the display device of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

In particular, the display device of one embodiment of the present invention can have high resolution, and thus can be favorably used for an electronic appliance having a relatively small display portion. Examples of such an electronic appliance include watch-type and bracelet-type information terminal devices (wearable devices) and wearable devices capable of being worn on a head, such as a VR device like a head-mounted display, a glasses-type AR device, and an MR device.

The electronic appliance in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

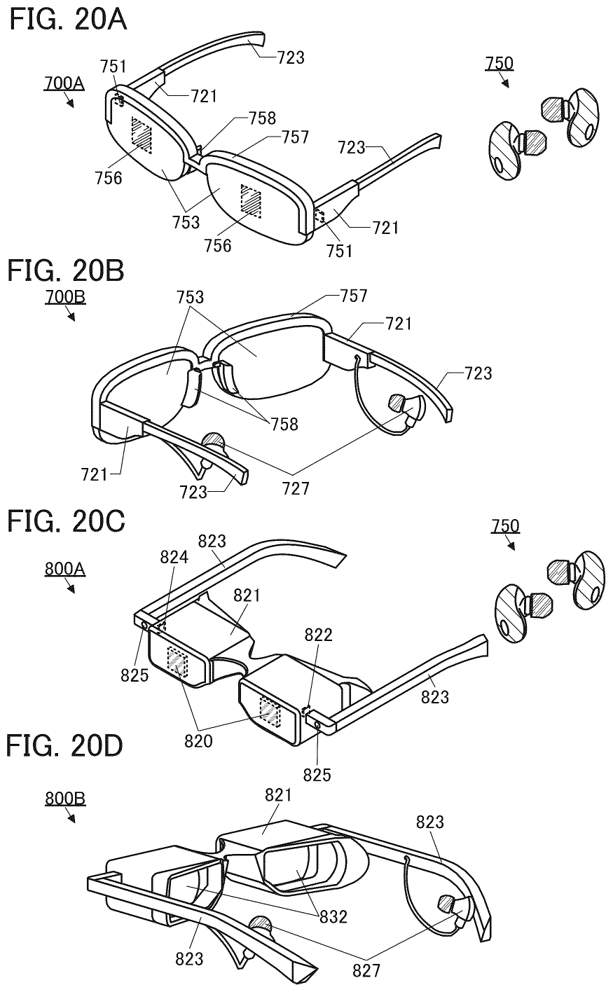

Examples of head-mounted wearable devices are described with reference to FIGS. 20A to 20D.

An electronic appliance 700A illustrated in FIG. 20A and an electronic appliance 700B illustrated in FIG. 20B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, a highly reliable electronic appliance is obtained.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic appliance 800A illustrated in FIG. 20C and an electronic appliance 800B illustrated in FIG. 20D each include a pair of display portions 820, a housing 821, a communication portion 822, a pair of wearing portions 823, a control portion 824, a pair of image capturing portions 825, and a pair of lenses 832.

The display device of one embodiment of the present invention can be used in the display portions 820. Thus, a highly reliable electronic appliance is obtained.

The display portions 820 are positioned inside the housing 821 so as to be seen through the lenses 832. When the pair of display portions 820 display different images, three-dimensional display using parallax can be performed.

The electronic appliances 800A and 800B preferably include a mechanism for adjusting the lateral positions of the lenses 832 and the display portions 820 so that the lenses 832 and the display portions 820 are positioned optimally in accordance with the positions of the user's eyes.

The electronic appliance 800A or the electronic appliance 800B can be mounted on the user's head with the wearing portions 823.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

The electronic appliance 800A may include a vibration mechanism that functions as bone-conduction earphones.

The electronic appliances 800A and 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750.

The electronic appliance may include an earphone portion. The electronic appliance 700B in FIG. 20B includes earphone portions 727. Part of a wiring that connects the earphone portion 727 and the control portion may be positioned inside the housing 721 or the wearing portion 723.

Similarly, the electronic appliance 800B in FIG. 20D includes earphone portions 827. For example, the earphone portion 827 can be connected to the control portion 824 by wire.

As described above, both the glasses-type device (e.g., the electronic appliances 700A and 700B) and the goggles-type device (e.g., the electronic appliances 800A and 800B) are preferable as the electronic appliance of one embodiment of the present invention.

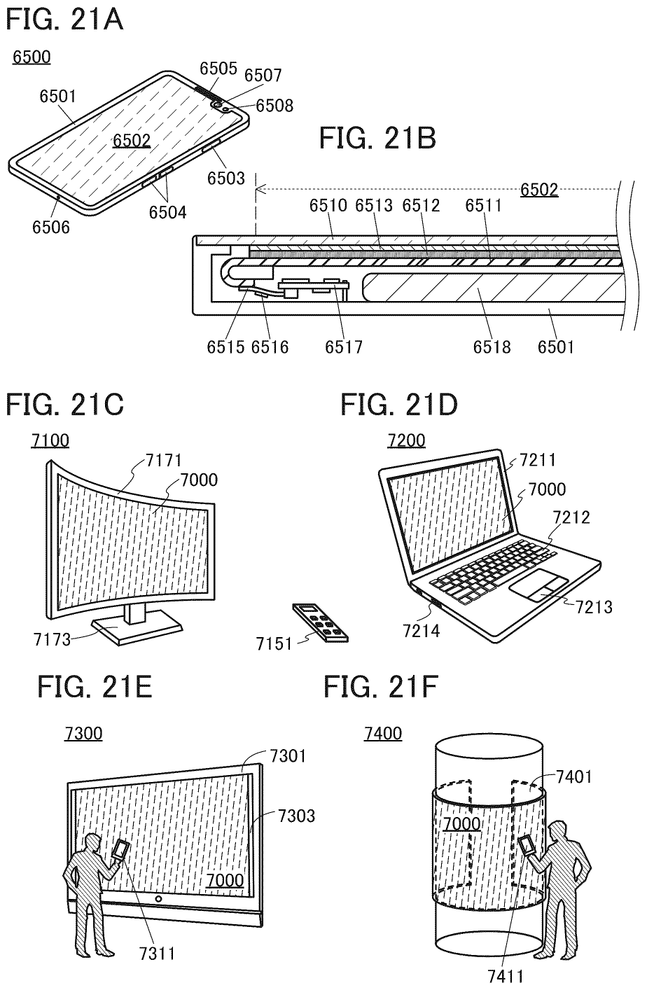

An electronic appliance 6500 illustrated in FIG. 21A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502. Thus, a highly reliable electronic appliance is obtained.

FIG. 21B is a schematic cross-sectional view including an edge portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The flexible display fabricated using one embodiment of the present invention can be used in the display panel 6511. Thus, an extremely lightweight electronic appliance can be obtained. Since the display panel 6511 is extremely thin, the battery 6518 with high capacity can be mounted without an increase in the thickness of the electronic appliance. An electronic appliance with a narrow bezel can be obtained when part of the display panel 6511 is folded back so that the portion connected to the FPC 6515 is provided on the back side of a pixel portion.

FIG. 21C illustrates an example of a television device. In a television device 7100, a display portion 7000 is incorporated in a housing 7171. Here, the housing 7171 is supported by a stand 7173.

The display device of one embodiment of the present invention can be used in the display portion 7000. Thus, a highly reliable electronic appliance is obtained.

Operation of the television device 7100 illustrated in FIG. 21C can be performed with an operation switch provided in the housing 7171 and a separate remote control 7151.

FIG. 21D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000. Thus, a highly reliable electronic appliance is obtained.

FIGS. 21E and 21F illustrate examples of digital signage.

Digital signage 7300 illustrated in FIG. 21E includes a housing 7301, the display portion 7000, a speaker 7303, and the like. The digital signage 7300 can also include an LED lamp, operation keys (including a power switch or an operation switch), a connection terminal, a variety of sensors, a microphone, and the like.

FIG. 21F shows digital signage 7400 attached to a cylindrical pillar 7401. The digital signage 7400 includes the display portion 7000 provided along a curved surface of the pillar 7401.

In FIGS. 21E and 21F, the display device of one embodiment of the present invention can be used in the display portion 7000. Thus, a highly reliable electronic appliance is obtained.

A larger area of the display portion 7000 can increase the amount of information that can be provided at a time. The display portion 7000 having a larger area attracts more attention, so that the effectiveness of the advertisement can be increased, for example.

As illustrated in FIGS. 21E and 21F, it is preferable that the digital signage 7300 or the digital signage 7400 can work with an information terminal 7311 or an information terminal 7411, such as a smartphone that a user has, through wireless communication.

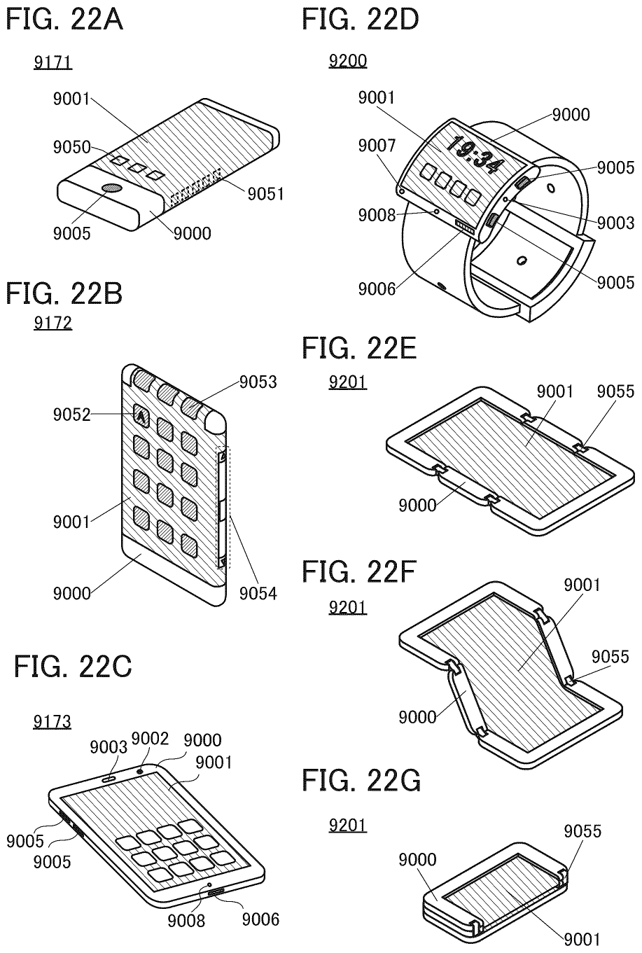

Electronic appliances illustrated in FIGS. 22A to 22G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic appliances illustrated in FIGS. 22A to 22G have a variety of functions. For example, the electronic appliances can have a function of displaying a variety of information (e.g., a still image, a moving image, and a text image) on the display portion, a touch panel function, a function of displaying a calendar, date, time, and the like, a function of controlling processing with the use of a variety of software (programs), a wireless communication function, and a function of reading out and processing a program or data stored in a recording medium.

The electronic appliances in FIGS. 22A to 22G are described in detail below.

FIG. 22A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 22A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 22B is a perspective view of a portable information terminal 9172. The portable information terminal 9172 has a function of displaying information on three or more surfaces of the display portion 9001. Here, an example in which information 9052, information 9053, and information 9054 are displayed on different surfaces is described. For example, the user of the portable information terminal 9172 can check the information 9053 displayed such that it can be seen from above the portable information terminal 9172, with the portable information terminal 9172 put in a breast pocket of his/her clothes.

FIG. 22C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 22D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 22E to 22G are perspective views of a foldable portable information terminal 9201. FIG. 22E is a perspective view showing the portable information terminal 9201 that is opened. FIG. 22G is a perspective view showing the portable information terminal 9201 that is folded. FIG. 22F is a perspective view showing the portable information terminal 9201 that is shifted from one of the states in FIGS. 22E and 22G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined as appropriate with the other embodiments or examples. In this specification, in the case where a plurality of structure examples are shown in one embodiment, the structure examples can be combined as appropriate.

### Example 1

In this example, light-emitting devices 1A to 1D each including the structure of the electron-injection layer of one embodiment of the present invention were fabricated. The light-emitting devices 1A and 1C were fabricated through exposure to the air. Meanwhile, the light-emitting devices 1B and 1D were fabricated in a continuous vacuum process.

Structural formulae of organic compounds used for the light-emitting devices 1A to 1D are shown below.

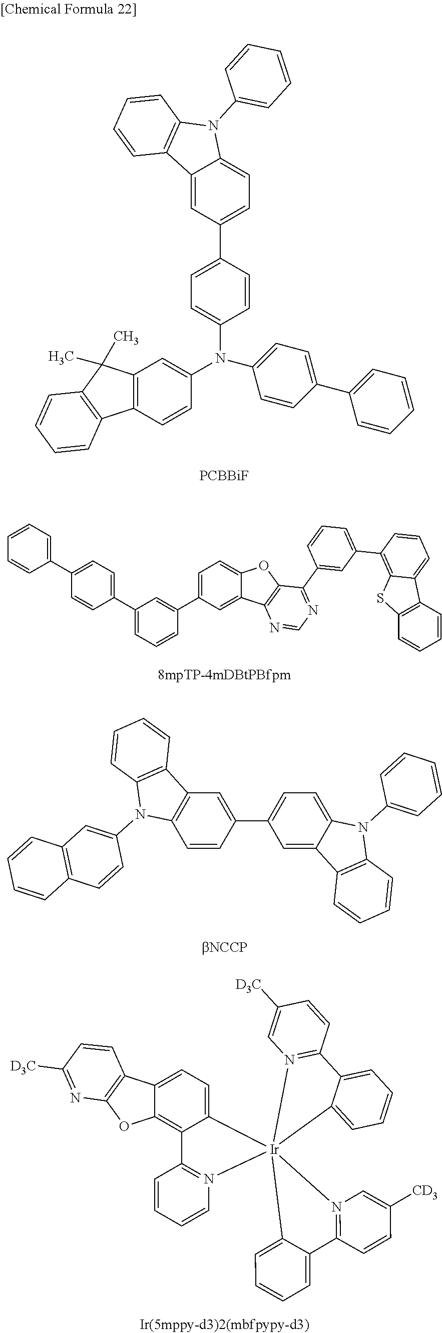

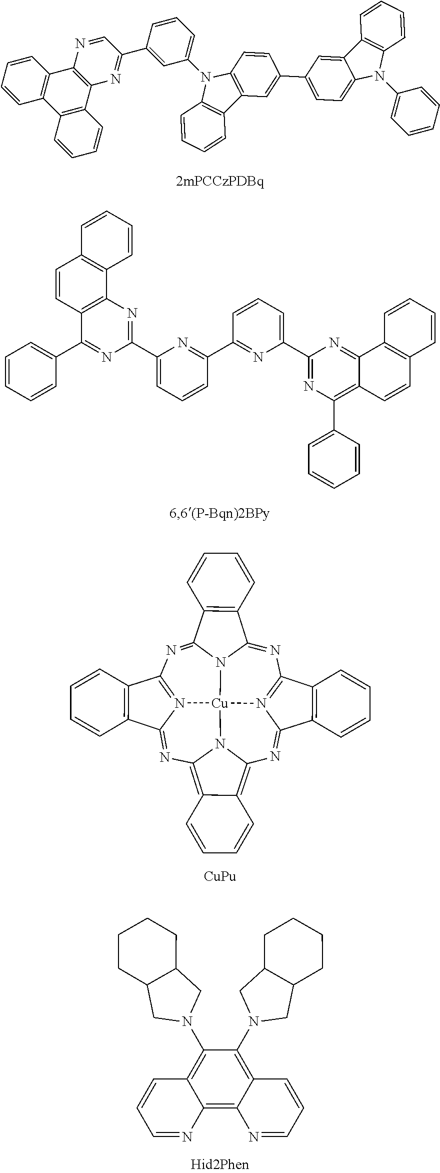

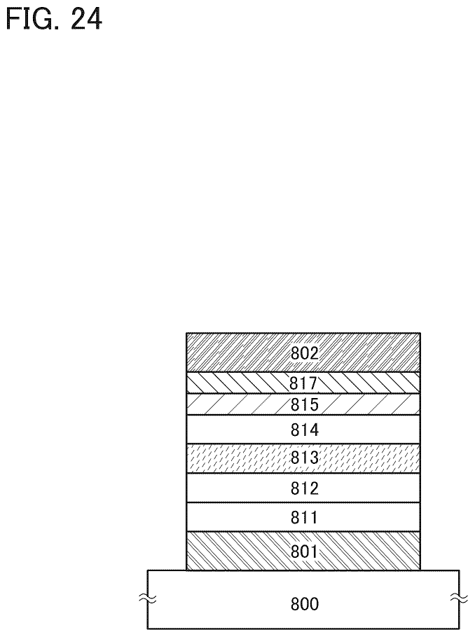

As illustrated in FIG. 24, the light-emitting devices each have a structure in which a hole-injection layer 811, a hole-transport layer 812, a light-emitting layer 813, an electron-transport layer 814, and an electron-injection layer 815 are stacked in this order over a first electrode 801 formed over a glass substrate 800, and a second electrode 802 is stacked over the electron-injection layer 815.

### <Method for Fabricating Light-Emitting Device 1A>

First, silver (Ag) was deposited to a thickness of 100 nm as a reflective electrode over the glass substrate 800 by a sputtering method, and then, indium tin oxide containing silicon oxide (ITSO) was deposited to a thickness of 85 nm as a transparent electrode by a sputtering method, whereby the first electrode 801 was formed. Note that the electrode area was set to 4 mm² (2 mm×2 mm).

Next, in pretreatment for forming the light-emitting device over the substrate, a surface of the substrate was washed with water and baking was performed at 200° C. for 1 hour. Then, the substrate was transferred into a vacuum evaporation apparatus where the internal pressure was reduced to approximately 1×10⁻⁴ Pa, and vacuum baking was performed at 170° C. for 30 minutes in a heating chamber of the vacuum evaporation apparatus. After that, natural cooling was performed for 30 minutes.

Then, the substrate provided with the first electrode 801 was fixed to a substrate holder provided in the vacuum evaporation apparatus such that the surface on which the first electrode 801 was formed faced downward. Over the first electrode, N-(biphenyl-4-yl)-N-[4-(9-phenyl-9H-carbazol-3-yl)phenyl]-9,9-dimethyl-9H-fluoren-2-amine (abbreviation: PCBBiF) and a fluorine-containing electron acceptor material with a molecular weight of 672 (OCHD-003) were deposited by co-evaporation to a thickness of 10 nm such that the weight ratio of PCBBiF to OCHD-003 was 1:0.03, whereby the hole-injection layer 811 was formed.

Next, over the hole-injection layer 811, PCBBiF was deposited by evaporation using resistance heating to a thickness of 55 nm, whereby the hole-transport layer 812 was formed.

Then, over the hole-transport layer 812, 8-(p-terphenyl-3-yl)-4-[3-(dibenzothiophen-4-yl)phenyl]-[1]benzofuro[3,2-d]pyrimidine (abbreviation: 8mpTP-4mDBtPBfpm), 9-(2-naphthyl)-9′-phenyl-3,3′-bi-9H-carbazole (abbreviation: βNCCP), and [2-d₃-methyl-8-(2-pyridinyl-κN)benzofuro[2,3-b]pyridine-κC]bis[2-(5-d₃-methyl-2-pyridinyl-κN²)phenyl-κC]iridium (III) (abbreviation: Ir (5mppy-d₃)₂(mbfpypy-d₃)) were deposited by co-evaporation using a resistance-heating method to a thickness of 40 nm such that the weight ratio of 8mpTP-4mDBtPBfpm to βNCCP to Ir (5mppy-d₃)₂(mbfpypy-d₃) was 0.5:0.5:0.1, whereby the light-emitting layer 813 was formed.

Next, over the light-emitting layer 813, 2-{3-[3-(N-phenyl-9H-carbazol-3-yl)-9H-carbazol-9-yl]phenyl}dibenzo[f,h]quinoxaline (abbreviation: 2mPCCzPDBq) was deposited to a thickness of 15 nm by evaporation, whereby the electron-transport layer 814 was formed.

Then, 2,2′-(2,2′-bipyridine-6,6′-diyl)bis(4-phenylbenzo[h]quinazoline) (abbreviation: 6,6′(P-Bqn)₂BPy), 4,7-di(2,3,3a,4,5,6,7,7a-octahydro-1H-isoindol-2-yl)-1,10-phenanthroline (abbreviation: Hid2Phen), and lithium oxide (Li₂O) were deposited by co-evaporation to a thickness of 5 nm such that the volume ratio 6,6′(P-Bqn)₂BPy:Hid2Phen:Li₂O=0.5:0.5:0.02, whereby the electron-injection layer 815 was formed.

Next, over the electron-injection layer 815, copper phthalocyanine (abbreviation: CuPc) was deposited by evaporation to a thickness of 2 nm, and then, PCBBiF and molybdenum (VI) oxide (abbreviation: MoO₃) were deposited by co-evaporation to a thickness of 15 nm such that the weight ratio PCBBiF:MoO₃₌1:0.5, whereby a p-type layer 817 was formed.

Then, over the p-type layer 817, indium tin oxide (ITO) was deposited by a sputtering method to a thickness of 40 nm, whereby part of the second electrode was formed.

Here, the substrate 800 was exposed to the air for 1 hour. After that, heat treatment was performed at 100° C. for 1 hour in a vacuum where the internal pressure was reduced to approximately 1×10⁻⁴ Pa. The heat treatment can remove moisture or the like attached by the exposure to the air or the like.

Then, indium tin oxide (ITO) was deposited by a sputtering method to a thickness of 70 nm, whereby the second electrode 802 was formed.

### <Method for Fabricating Light-Emitting Device 1B>

Next, a method for fabricating the light-emitting device 1B is described. The light-emitting device 1B is different from the light-emitting device 1A in that the light-emitting device 1B was fabricated in a continuous vacuum process.

That is, in the light-emitting device 1B, indium tin oxide (ITO) was deposited by a sputtering method to a thickness of 110 nm over the p-type layer 817, whereby the second electrode was formed.

Other components were fabricated in a manner similar to that for the light-emitting device 1A.

### <Method for Fabricating Light-Emitting Device 1C>

Next, a method for fabricating the light-emitting device 1C is described. The light-emitting device 1C is different from the light-emitting device 1A in the structure of the electron-injection layer.

That is, in the light-emitting device 1C, 2mPCCzPDBq was deposited over the light-emitting layer 813 by evaporation to a thickness of 15 nm to form the electron-transport layer 814, and then 6,6′(P-Bqn)₂BPy, Hid2Phen, and indium (In) were deposited by co-evaporation to a thickness of 5 nm such that the volume ratio 6,6′(P-Bqn)₂BPy:Hid2Phen:In=0.5:0.5:0.02 to form the electron-injection layer 815.

Other components were fabricated in a manner similar to that for the light-emitting device 1A.

### <Method for Fabricating Light-Emitting Device 1D>

Next, a method for fabricating the light-emitting device 1D is described. The light-emitting device 1D is different from the light-emitting device 1C in that the light-emitting device 1D was fabricated in a continuous vacuum process.

That is, in the light-emitting device 1D, indium tin oxide (ITO) was deposited by a sputtering method to a thickness of 110 nm over the p-type layer 817, whereby the second electrode was formed.

Other components were fabricated in a manner similar to that for the light-emitting device 1C.

The structures of the light-emitting devices 1A to 1D are listed in the following table.

TABLE 6

| | Film | Light-emitting | Light-emitting | Light-emitting | Light-emitting |
|---|---|---|---|---|---|
| | thickness | device | device | device | device |
| | [nm] | 1A | 1B | 1C | 1D |
| Second electrode | — | ITO (70 nm) | — | ITO (70 nm) | — |
| Exposure to the air | | Performed | — | Performed | — |
| Second electrode | — | ITO (40 nm) | ITO (110 nm) | ITO (40 nm) | ITO (110 nm) |

| P-type layer | 15 | PCBBiF:MoO₃ (1:0.5) | |
|---|---|---|---|
| | 2 | CuPc | |
| Electron-injection layer | 5 | 6,6′(P-Bqn)₂BPy:Hid2Phen:Li₂O | 6,6′(P-Bqn)₂BPy:Hid2Phen:In |
| | | (0.5:0.5:0.02) | (0.5:0.5:0.02) |

| | | |
|---|---|---|
| Electron-transport layer | 15 | 2mPCCzPDBq |
| Light-emitting layer | 40 | 8mpTP-4mDBtPBfpm:βNCCP:Ir(5mppy-d₃)₂(mbfpypy-d3) |
| | | (0.5:0.5:0.1) |
| Hole-transport layer | 55 | PCBBiF |
| Hole-injection layer | 10 | PCBBiF:OCHD-003 (1:0.03) |
| First electrode | 85 | ITSO |
| | 100 | Ag |

### <Characteristics of Light-Emitting Devices>

The light-emitting devices were each sealed with a glass substrate in a glove box containing a nitrogen atmosphere so as not to be exposed to the air (a sealing material was applied to surround the devices and UV treatment and heat treatment at 80° C. for 1 hour were performed at the time of sealing). Then, characteristics of the devices were measured.

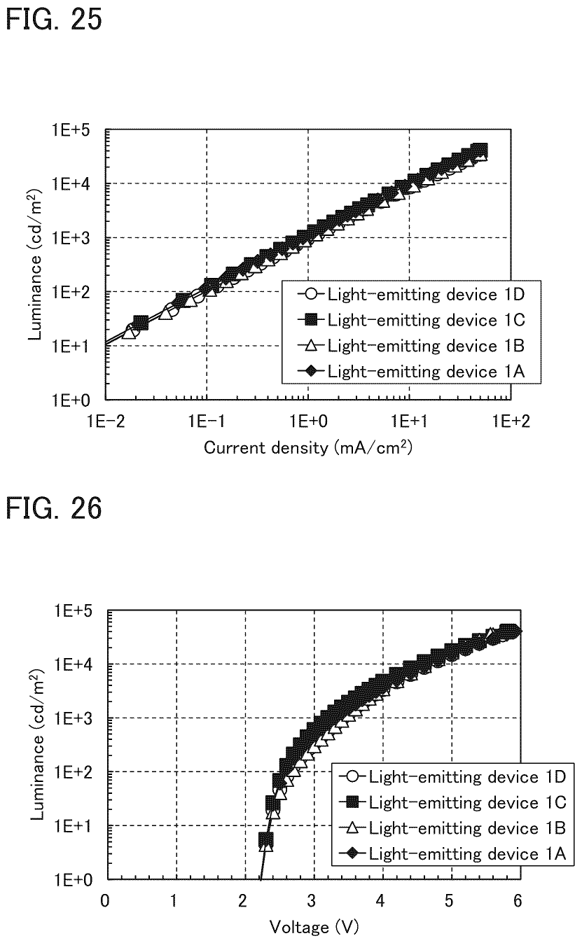

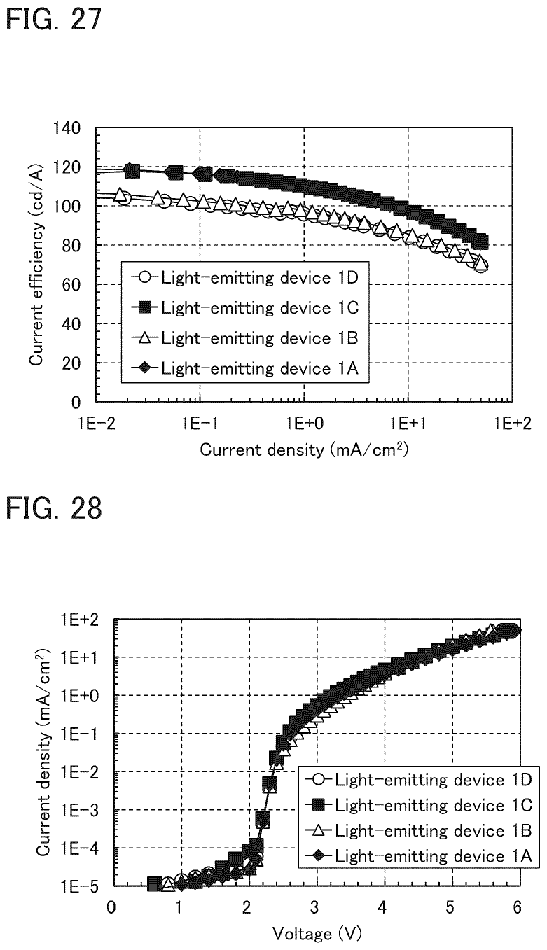

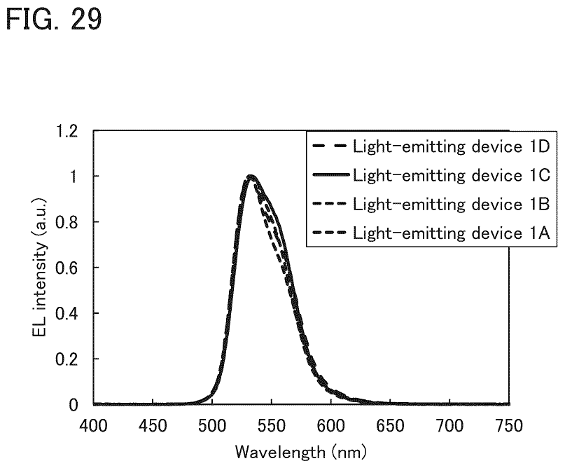

FIG. 25 shows the luminance-current density characteristics of the light-emitting devices. FIG. 26 shows the luminance-voltage characteristics of the light-emitting devices. FIG. 27 shows the current efficiency-current density characteristics of the light-emitting devices. FIG. 28 shows the current density-voltage characteristics of the light-emitting devices. FIG. 29 shows the electroluminescence spectra of the light-emitting devices.

The following table shows the main characteristics of the light-emitting devices at a luminance of approximately 1000 cd/m². Note that the luminance, CIE chromaticity, and emission spectra were measured with a spectroradiometer (SR-ULIR manufactured by TOPCON TECHNOHOUSE CORPORATION).

TABLE 7

| | | | Current density | | | Luminance | Current efficiency |
|---|---|---|---|---|---|---|---|
| | Voltage (V) | Current (mA) | (mA/cm²) | Chromaticity x | Chromaticity y | (cd/m²) | (cd/A) |
| Light-emitting | 3.30 | 0.036 | 0.89 | 0.293 | 0.680 | 984 | 110.37 |
| device 1A | | | | | | | |
| Light-emitting | 3.40 | 0.037 | 0.92 | 0.293 | 0.678 | 901 | 97.97 |
| device 1B | | | | | | | |
| Light-emitting | 3.20 | 0.037 | 0.91 | 0.300 | 0.674 | 1009 | 110.28 |
| device 1C | | | | | | | |
| Light-emitting | 3.40 | 0.040 | 0.99 | 0.302 | 0.670 | 947 | 95.85 |
| device 1D | | | | | | | |

Table 7 and FIG. 25 to FIG. 29 show that the light-emitting devices 1A and 1C each having the structure of the electron-injection layer of one embodiment of the present invention exhibit characteristics equivalent to or higher than those of the light-emitting device 1B or the light-emitting device 1D fabricated in a continuous vacuum process even though the light-emitting devices 1A and 1C have been exposed to the air. In particular, the light-emitting devices 1A and 1C were found to emit light with low driving voltage and high efficiency.

Therefore, one embodiment of the present invention can provide a light-emitting device with high emission efficiency while deterioration due to exposure to the air in the process is inhibited.

This application is based on Japanese Patent Application Serial No. 2024-022291 filed with Japan Patent Office on Feb. 16, 2024, the entire contents of which are hereby incorporated by reference.

What is claimed is:

1. A light-emitting device comprising:
a first electrode over a first insulating layer;
a second electrode over the first insulating layer; and
an organic compound layer over the first insulating layer,
wherein the first electrode is in contact with the first insulating layer,
wherein the organic compound layer is between the first electrode and the second electrode,
wherein the second electrode and the organic compound layer are separated from a second electrode and an organic compound layer of at least one of a plurality of light-emitting devices adjacent to the light-emitting device,
wherein an outline of the second electrode and an outline of the organic compound layer are aligned or substantially aligned with each other when seen from a direction perpendicular to the first insulating layer on which the first electrode is formed,
wherein the organic compound layer comprises a light-emitting layer and an electron-injection layer,
wherein the electron-injection layer comprises metal or a metal compound, a first organic compound, and a second organic compound,
wherein the first organic compound comprises a π-electron deficient heteroaromatic ring,
wherein the second organic compound comprises two or more heteroaromatic rings,
wherein the two or more heteroaromatic rings are bonded or condensed to each other and comprise three or more heteroatoms in total, and
wherein the second organic compound interacts with the metal or the metal compound by two or more of the three or more heteroatoms as a multidentate ligand.

2. The light-emitting device according to claim 1,
wherein the organic compound layer comprises a p-type layer between the electron-injection layer and the second electrode, and
wherein the p-type layer comprises a third organic compound having a hole-transport property and a metal oxide or a fourth organic compound comprising at least one of a halogen group and a cyano group.

3. A light-emitting device,
wherein the light-emitting device is one of a plurality of light-emitting devices included in a group of light-emitting devices, the group of light-emitting devices comprising:
a group of first electrodes over the same insulating surface;
a group of second electrodes facing the group of first electrodes; and
a group of first layers between the group of first electrodes and the group of second electrodes,
wherein the light-emitting device comprises a first electrode, a second electrode, and a first layer,
wherein the first electrode is one of the group of first electrodes,
wherein the first electrode is independent of first electrodes of the plurality of light-emitting devices,
wherein the first layer is one of the group of first layers,
wherein the first layer is independent of first layers of the plurality of light-emitting devices,
wherein the second electrode is one of the group of second electrodes,
wherein the second electrode is independent of second electrodes of the plurality of light-emitting devices,
wherein the second electrode and the first layer overlap with the first electrode,
wherein the first layer comprises a light-emitting layer and an electron-injection layer,
wherein the electron-injection layer comprises metal or a metal compound, a first organic compound, and a second organic compound,
wherein the first organic compound comprises π-electron deficient heteroaromatic ring,
wherein the second organic compound comprises two or more heteroaromatic rings,
wherein the two or more heteroaromatic rings are bonded or condensed to each other and comprise three or more heteroatoms in total,
wherein the second organic compound interacts with the metal or the metal compound by two or more of the three or more heteroatoms as a multidentate ligand, and
wherein a distance between the first layer included in the light-emitting device and a first layer included in another light-emitting device adjacent to the light-emitting device is greater than or equal to 0.5 μm and less than or equal to 5 μm.

4. The light-emitting device according to claim 3,
wherein the first layer comprises a p-type layer between the electron-injection layer and the second electrode, and
wherein the p-type layer comprises a third organic compound having a hole-transport property and a metal oxide or a fourth organic compound comprising at least one of a halogen group and a cyano group.

5. The light-emitting device according to claim 3, wherein an outline of the second electrode and an outline of the first layer are aligned or substantially aligned with each other when seen from a direction perpendicular to the insulating surface.

6. The light-emitting device according to claim 3,
wherein in a cross-sectional view, an end portion of the second electrode and an end portion of the first layer are aligned with each other in a direction perpendicular or substantially perpendicular to the insulating surface.

7. The light-emitting device according to claim 1,
wherein the second organic compound is represented by General Formula (G1-1): 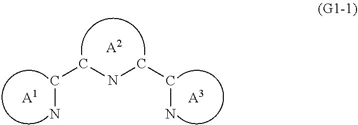
, and
wherein in General Formula (G1-1), each of A¹, A², and A³ independently represents a substituted or unsubstituted heteroaromatic ring having 1 to 30 carbon atoms.

8. The light-emitting device according to claim 1,
wherein the second organic compound is represented by General Formula (G1-2): 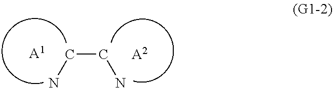
, and
wherein in General Formula (G1-2), each of A¹ and A² independently represents a substituted or unsubstituted heteroaromatic ring having 1 to 30 carbon atoms and A¹ comprises two or more nitrogen atoms.

9. The light-emitting device according to claim 1,
wherein the heteroaromatic rings each are a π-electron deficient heteroaromatic ring.

10. The light-emitting device according to claim 1,
wherein the heteroaromatic rings comprise at least one of a pyridine ring, a pyrazine ring, a pyrimidine ring, a pyridazine ring, a triazine ring, an imidazole ring, a pyrazole ring, an oxazole ring, a thiazole ring, and a triazole ring.

11. The light-emitting device according to claim 1,
wherein at least one of the heteroaromatic rings included in the second organic compound comprises a diazine ring or a triazine ring, and
wherein the diazine ring is one of a pyrazine ring, a pyrimidine ring, and a pyridazine ring.

12. The light-emitting device according to claim 1,
wherein the heteroaromatic rings included in the second organic compound comprise three or more pyridine rings in total.

13. The light-emitting device according to claim 1,
wherein the first organic compound comprises an electron-donating group.

14. The light-emitting device according to claim 13,
wherein the electron-donating group is at least one of an alkyl group, an alkoxy group, an aryloxy group, an alkylamino group, an arylamino group, and a heterocyclic amino group.

15. The light-emitting device according to claim 1,
wherein the first organic compound has an acid dissociation constant pKₐ of 8 or more.

16. The light-emitting device according to claim 1,
wherein the first organic compound comprises a phenanthroline ring.

17. The light-emitting device according to claim 1,
wherein the second organic compound has a glass transition temperature T_{g} of 100° C. or higher.

18. The light-emitting device according to claim 1,
wherein a LUMO level of the second organic compound is lower than a LUMO level of the first organic compound.

19. The light-emitting device according to claim 1,
wherein the metal belongs to Group 1, Group 3, Group 11, or Group 13 of the periodic table.

20. The light-emitting device according to claim 1,
wherein the electron-injection layer is a mixture of the metal, the second organic compound, and the first organic compound.
